(19) United States
(12) Patent Application Publication
(10) Pub. No.: US 2023/0099277 A1
(43) Pub. Date: Mar. 30, 2023

(54) COLORING COMPOSITION, FILM, OPTICAL FILTER, SOLID-STATE IMAGING ELEMENT, AND IMAGE DISPLAY DEVICE

(71) Applicant: FUJIFILM Corporation, Tokyo (JP)

(72) Inventor: Takashi KAWASHIMA, Haibara-gun (JP)

(73) Assignee: FUJIFILM Corporation, Tokyo (JP)

(21) Appl. No.: 18/054,379

(22) Filed: Nov. 10, 2022

Related U.S. Application Data
(63) Continuation of application No. PCT/JP2021/017327, filed on May 6, 2021.

(30) Foreign Application Priority Data
May 12, 2020 (JP) 2020083771

(51) Int. Cl. C08K 5/3415; C09B 67/20; G02B 5/20; C08J 5/18; H01L 27/146

(52) U.S. Cl. CPC C08K 5/3415; C09B 67/006; G02B 5/208; C08J 5/18; H01L 27/14625; C08J 2379/08

(57) ABSTRACT

Provided are a coloring composition including a colorant and a resin, in which the colorant includes a pigment A having a structure represented by Formula (X1), and the resin includes at least one selected from a polyimide resin, a polyimide precursor, a polybenzoxazole resin, a polybenzoxazole precursor, or a polysiloxane resin; a film obtained from the coloring composition; and an optical filter, a solid-state imaging element, and an image display device including the film.

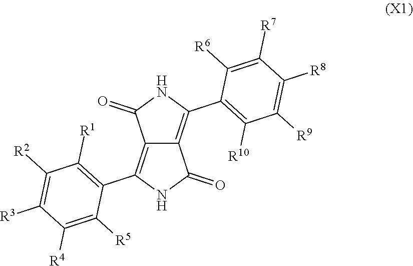

### CROSS-REFERENCE TO RELATED APPLICATIONS

This application is a Continuation of PCT International Application No. PCT/JP2021/017327 filed on May 6, 2021, which claims priority under 35 U.S.C § 119(a) to Japanese Patent Application No. 2020-083771 filed on May 12, 2020. Each of the above application(s) is hereby expressly incorporated by reference, in its entirety, into the present application.

### BACKGROUND OF THE INVENTION

### 1. Field of the Invention

The present invention relates to a coloring composition. The present invention further relates to a film formed of the coloring composition, an optical filter, a solid-state imaging element, and an image display device.

### 2. Description of the Related Art

In recent years, as a digital camera, a mobile phone with a camera, and the like have been further spreading, there has been a greatly increasing demand for a solid-state imaging element such as a charge coupled device (CCD) image sensor. A color filter has been used as a key device in a display or an optical element.

The color filter is manufactured by using a coloring composition including a colorant. For example, in a coloring composition for forming a red pixel, a diketopyrrolopyrrole pigment or the like is used. JP1998-300920A (JP-H10-300920A) and WO2016/024497A disclose that a red pixel of a color filter is formed by using a coloring composition including Color Index Pigment Red 264.

### SUMMARY OF THE INVENTION

In recent years, in the manufacturing process of a solid-state imaging element, it has been also studied to manufacture a film such as a color filter using a coloring composition, and then subject the film to a step requiring a heating treatment at a high temperature (for example, 300° C. or higher).

From intensive studies with regard to the coloring composition disclosed in JP1998-300920A (JP-H10-300920A), the present inventor has found that a film obtained by this coloring composition has room for improvement in heat resistance.

Therefore, an object of the present invention is to provide a coloring composition with which a film having excellent heat resistance can be formed. Another object of the present invention is to provide a film formed of the coloring composition, an optical filter, a solid-state imaging element, and an image display device.

According to the studies conducted by the present inventor, it has been found that the above-described object can be achieved by adopting the following configuration, thereby leading to the completion of the present invention. Therefore, an aspect of the present invention provides the following.

<1> A coloring composition comprising:

a colorant; and

a resin,

in which the colorant includes a pigment A having a structure represented by Formula (X1), and

the resin includes at least one selected from a polyimide resin, a polyimide precursor, a polybenzoxazole resin, a polybenzoxazole precursor, or a polysiloxane resin,

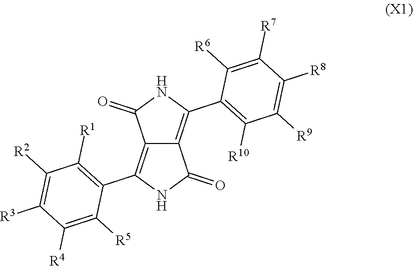

in Formula (X1), R¹ to R¹⁰ each independently represent a hydrogen atom or a group represented by Formula (X2), where at least one of R¹, . . . , or R¹⁰ is the group represented by Formula (X2),

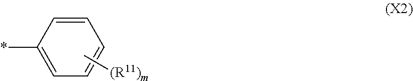

in Formula (X2), R¹¹ represents a substituent, m represents an integer of 0 to 5, and * represents a bonding position in Formula (X1).

<2> The coloring composition according to <1>,

in which R³ and R⁸ of Formula (X1) are the groups represented by Formula (X2).

<3> The coloring composition according to <1>or <2>,

in which R¹, R², R⁴, R⁵, R⁶, R⁷, R⁹, and R¹⁰ of Formula (X1) are hydrogen atoms.

<4> The coloring composition according to any one of <1>to <3>,

in which the coloring composition includes the pigment A in an amount of 10 to 1500 parts by mass with respect to 100 parts by mass of a total of the polyimide resin, the polyimide precursor, the polybenzoxazole resin, the polybenzoxazole precursor, and the polysiloxane resin.

<5> The coloring composition according to any one of <1>to <4>,

in which the coloring composition includes the polyimide resin, the polyimide precursor, the polybenzoxazole resin, the polybenzoxazole precursor, and the polysiloxane resin in a total amount of 5% to 80% by mass in a total solid content of the coloring composition.

<6> The coloring composition according to any one of <1>to <5>,

in which the colorant includes a colorant other than the pigment A, and

the colorant other than the pigment A is at least one selected from a chromatic colorant or a black colorant.

<7> The coloring composition according to <6>,

in which the coloring composition includes the colorant other than the pigment A in an amount of 10 to 1000 parts by mass with respect to 100 parts by mass of the pigment A.

<8> The coloring composition according to any one of <1>to <7>, further comprising: an infrared absorber.

<9> The coloring composition according to any one of <1>to <8>,

in which the resin includes at least one selected from a polyimide resin or a polyimide precursor.

<10> The coloring composition according to any one of <1>to <9>, further comprising:

a polymerizable monomer; and

a polymerization initiator.

<11> The coloring composition according to <10>,

in which the polymerization initiator is a photopolymerization initiator.

<12> The coloring composition according to any one of <1>to <11>,

in which the coloring composition is used for a red color filter.

<13> The coloring composition according to any one of <1>to <11>,

in which the coloring composition is used for an infrared transmitting filter.

<14> A film obtained from the coloring composition according to any one of <1>to <13>.

<15> An optical filter comprising:

the film according to <14>.

<16> A solid-state imaging element comprising:

the film according to <14>.

<17> An image display device comprising:

the film according to <14>.

According to the present invention, it is possible to provide a coloring composition with which a film having excellent heat resistance can be formed. It is also possible to provide a film formed of the coloring composition, an optical filter, a solid-state imaging element, and an image display device.

### DESCRIPTION OF THE PREFERRED EMBODIMENTS

Hereinafter, the details of the present invention will be described.

In the present specification, “to” is used to refer to a meaning including numerical values denoted before and after “to” as a lower limit value and an upper limit value.

In the present specification, unless specified as a substituted group or as an unsubstituted group, a group (atomic group) denotes not only a group (atomic group) having no substituent but also a group (atomic group) having a substituent. For example, an “alkyl group” includes not only an alkyl group having no substituent (unsubstituted alkyl group), but also an alkyl group having a substituent (substituted alkyl group).

In the present specification, unless specified otherwise, “exposure” denotes not only exposure using light but also drawing using a corpuscular beam such as an electron beam or an ion beam. In addition, examples of light used for the exposure include actinic rays or radiation such as a bright line spectrum of a mercury lamp, far ultraviolet rays typified by an excimer laser, extreme ultraviolet rays (EUV light), X-rays, or electron beams.

In the present specification, “(meth)acrylate” denotes either or both of acrylate and methacrylate, “(meth)acryl” denotes either or both of acryl and methacryl, and “(meth)acryloyl” denotes either or both of acryloyl and methacryloyl.

In the present specification, in a structural formula, Me represents a methyl group, Et represents an ethyl group, Bu represents a butyl group, Pr represents a propyl group, and Ph represents a phenyl group.

In the present specification, a weight-average molecular weight and a number-average molecular weight are values in terms of polystyrene through measurement by a gel permeation chromatography (GPC) method.

In the present specification, a total solid content denotes the total mass of all the components of the composition excluding a solvent.

In the present specification, a pigment means a compound which is hardly dissolved in a solvent. For example, as the pigment, both of the solubility in 100 g of water at 23° C. and 100 g of propylene glycol monomethyl ether acetate at 23° C. is preferably 0.1 g or less and more preferably 0.01 g or less.

In the present specification, the term “step” is not only an independent step, but also includes a step which is not clearly distinguished from other steps in a case where an intended action of the step is obtained.

<Coloring Composition>

A coloring composition according to an embodiment of the present invention includes a colorant and a resin, in which the colorant includes a pigment A having a structure represented by Formula (X1), and the resin includes at least one selected from a polyimide resin, a polyimide precursor, a polybenzoxazole resin, a polybenzoxazole precursor, or a polysiloxane resin.

With the coloring composition according to the embodiment of the present invention, it is possible to form a film having excellent heat resistance in which film shrinkage is unlikely to occur even after a heating treatment at a high temperature. In addition, even in a case where, after forming other films such as an inorganic film on a surface of the film formed of the coloring composition according to the embodiment of the present invention, the heating treatment at a high temperature (for example, 300° C. or higher) is performed, it is possible to suppress occurrence of cracks in the other films. Therefore, with the coloring composition according to the embodiment of the present invention, a process window of the process after manufacturing the film can be expanded.

In addition, with the coloring composition according to the embodiment of the present invention, it is possible to form a film in which variation in spectral characteristics is suppressed even after a heating treatment at a high temperature.

In addition, in general, in a case where a film formed of a coloring composition including a pigment is heated to a high temperature, pigment-derived crystals tend to precipitate as foreign matter in the film due to thermal diffusion of the pigment, but since the coloring composition according to the embodiment of the present invention includes the pigment A having a structure represented by Formula (X1) and the above-described resin, with the coloring composition according to the embodiment of the present invention, it is possible to form a film in which precipitation of foreign matter is suppressed even after the heating treatment. In particular, in a case where at least one selected from a polyimide resin, a polyimide precursor, a polybenzoxazole resin, or a polybenzoxazole precursor is used as the resin, it is presumed that these resins tend to interact with the pigment A, and that aggregation of the pigment A can be effectively suppressed by suppressing the thermal diffusion of the pigment A in the film. Therefore, even in a case where the film formed of the coloring composition is subjected to a heating treatment at a high temperature (for example, 300° C. or higher), it is possible to effectively suppress the precipitation of foreign matter.

In a case where a film having a thickness of 0.60 μm is formed by heating the coloring composition according to the embodiment of the present invention at 200° C. for 30 minutes, a thickness of the film after performing a heating treatment of the film at 300° C. for 5 hours in a nitrogen atmosphere is preferably 70% or more of a thickness of the film before the heating treatment, more preferably 80% or more thereof, still more preferably 90% or more, even more preferably 95% or more, and particularly preferably 99% or more.

In addition, in a case where the coloring composition according to the embodiment of the present invention is heated at 200° C. for 30 minutes to form a film having a thickness of 0.60 μm, the absolute value (|Tr1-Tr2|) of a light transmittance Tr1 of the film with a light having a wavelength of 450 nm and a light transmittance Tr2 of the film after a heating treatment at 300° C. for 5 hours in a nitrogen atmosphere with a light having a wavelength of 450 nm is preferably 5% or less, more preferably 1% or less, still more preferably 0.5% or less, and particularly preferably 0.1% or less.

The above-described physical properties can be achieved by a method such as adjusting the type and content of the resin to be used.

The coloring composition according to the embodiment of the present invention is preferably used as a coloring composition for an optical filter. The coloring composition according to the embodiment of the present invention is more preferably a coloring composition for an optical filter used in a solid-state imaging element. Examples of the optical filter include a color filter and an infrared transmitting filter.

Examples of the color filter include a filter having a colored pixel which transmits light having a specific wavelength, and a filter having at least one colored pixel selected from a red pixel, a blue pixel, a green pixel, a yellow pixel, a cyan pixel, or a magenta pixel is preferable. The coloring composition according to the embodiment of the present invention can be preferably used as a coloring composition for forming a colored pixel of a color filter. In addition, the coloring composition according to the embodiment of the present invention can be preferably used as a coloring composition for a red color filter.

In addition, the coloring composition according to the embodiment of the present invention can also be used as a coloring composition for an infrared transmitting filter. The infrared transmitting filter is a filter which transmits at least a part of infrared rays. As the infrared transmitting filter, a filter which shields at least a part of visible light and transmits at least a part of infrared rays is preferably.

In a case where the coloring composition according to the embodiment of the present invention is used for an infrared transmitting filter, examples of one aspect of the spectral characteristics of the coloring composition include an aspect of spectral characteristics in which Amin/B, which is a ratio of the minimum value Amin of an absorbance in a wavelength range of 400 to 640 nm to an absorbance B at a wavelength of 1500 nm, is 5 or more. With a coloring composition satisfying such spectral characteristics, it is possible to form a film which shields visible light and transmits infrared light. The value of Amin/B, which is the above-described absorbance ratio, is preferably 7.5 or more, more preferably 15 or more, and still more preferably 30 or more. The value of Amin/B described above is designed by adjusting the type of the colorant and the content of the colorant.

Here, the absorbance Aλ at the wavelength λ is defined by the following expression (λ1).

Aλ=−log (Tλ/100) (λ1)

Aλ is an absorbance at the wavelength λ and Tλ is a transmittance (%) at the wavelength λ.

In the present invention, the value of the absorbance may be a value measured in the form of a solution, or may be a value measured in the form of a film formed using a coloring composition. In a case where the absorbance is measured in a form of the film, it is preferable that the absorbance is measured using a film prepared by applying the composition to a glass substrate using a method such as spin coating such that a thickness of the film after drying is a predetermined value, and drying the applied composition using a hot plate at 100° C. for 120 seconds. The thickness of the film can be measured using a stylus type surface shape measuring device (DEKTAK 150, manufactured by ULVAC Inc.) on the substrate including the film.

It is preferable that the coloring composition satisfies any of the following spectral characteristics (1A) to (5A).

(1A): value of A1/B1, which is a ratio of the minimum value A1 of an absorbance in a wavelength range of 400 to 640 nm to the maximum value B1 of an absorbance in a wavelength range of 800 to 1500 nm, is 4.5 or more, preferably 7.5 or more, more preferably 15 or more, and still more preferably 30 or more. According to this aspect, it is possible to form a film capable of shielding light in a wavelength range of 400 to 640 nm and transmitting light having a wavelength of more than 750 nm.

(2A): value of A2/B2, which is a ratio of the minimum value A2 of an absorbance in a wavelength range of 400 to 750 nm to the maximum value B2 of an absorbance in a wavelength range of 900 to 1500 nm, is 4.5 or more, preferably 7.5 or more, more preferably 15 or more, and still more preferably 30 or more. According to this aspect, it is possible to form a film capable of shielding light in a wavelength range of 400 to 750 nm and transmitting light having a wavelength of more than 850 nm.

(3A): value of A3/B3, which is a ratio of the minimum value A3 of an absorbance in a wavelength range of 400 to 830 nm to the maximum value B3 of an absorbance in a wavelength range of 1000 to 1500 nm, is 4.5 or more, preferably 7.5 or more, more preferably 15 or more, and still more preferably 30 or more. According to this aspect, it is possible to form a film capable of shielding light in a wavelength range of 400 to 830 nm and transmitting light having a wavelength of more than 950 nm.

(4A): value of A4/B4, which is a ratio of the minimum value A4 of an absorbance in a wavelength range of 400 to 950 nm to the maximum value B4 of an absorbance in a wavelength range of 1100 to 1500 nm, is 4.5 or more, preferably 7.5 or more, more preferably 15 or more, and still more preferably 30 or more. According to this aspect, it is possible to form a film capable of shielding light in a wavelength range of 400 to 950 nm and transmitting light having a wavelength of more than 1050 nm.

(5A): value of A5/B5, which is a ratio of the minimum value A5 of an absorbance in a wavelength range of 400 to 1050 nm to the maximum value B5 of an absorbance in a wavelength range of 1200 to 1500 nm, is 4.5 or more, preferably 7.5 or more, more preferably 15 or more, and still more preferably 30 or more. According to this aspect, it is possible to form a film capable of shielding light in a wavelength range of 400 to 1050 nm and transmitting light having a wavelength of more than 1150 nm.

In addition, in the coloring composition, in a case of forming a film having a film thickness of 1 μm after drying, it is preferable that the film satisfies spectral characteristics that the maximum value of light transmittance in the wavelength range of 400 to 640 nm in a thickness direction of the film is 20% or less, and a value of light transmittance at the wavelength of 1500 nm in the thickness direction of the film is 70% or more. The maximum value in the wavelength range of 400 to 640 nm is more preferably 15% or less and still more preferably 10% or less. The lower limit thereof is not particularly limited, and it is sufficient to be 0% or more. The value at the wavelength of 1500 nm is more preferably 75% or more and still more preferably 80% or more. The upper limit thereof is not particularly limited, and it is sufficient to be 100% or less.

In addition, it is preferable that the coloring composition satisfies any of the following spectral characteristics (1B) to (5B).

(1B): aspect in which, in a case of forming a film having a film thickness of 1 μm, 2 μm, 3 μm, 4 μm, or 5 μm after drying, the maximum value of light transmittance in a wavelength range of 400 to 640 nm in a thickness direction of the film is 20% or less (preferably 15% or less and more preferably 10% or less), and the minimum value of light transmittance in a wavelength range of 800 to 1500 nm in the thickness direction of the film is 70% or more (preferably 75% or more and more preferably 80% or more)

(2B): aspect in which, in a case of forming a film having a film thickness of 1 μm, 2 μm, 3 μm, 4 μm, or 5 μm after drying, the maximum value of light transmittance in a wavelength range of 400 to 750 nm in a thickness direction of the film is 20% or less (preferably 15% or less and more preferably 10% or less), and the minimum value of light transmittance in a wavelength range of 900 to 1500 nm in the thickness direction of the film is 70% or more (preferably 75% or more and more preferably 80% or more)

(3B): aspect in which, in a case of forming a film having a film thickness of 1 μm, 2 μm, 3 μm, 4 μm, or 5 μm after drying, the maximum value of light transmittance in a wavelength range of 400 to 830 nm in a thickness direction of the film is 20% or less (preferably 15% or less and more preferably 10% or less), and the minimum value of light transmittance in a wavelength range of 1000 to 1500 nm in the thickness direction of the film is 70% or more (preferably 75% or more and more preferably 80% or more)

(4B): aspect in which, in a case of forming a film having a film thickness of 1 μm, 2 μm, 3 μm, 4 μm, or 5 μm after drying, the maximum value of light transmittance in a wavelength range of 400 to 950 nm in a thickness direction of the film is 20% or less (preferably 15% or less and more preferably 10% or less), and the minimum value of light transmittance in a wavelength range of 1100 to 1500 nm in the thickness direction of the film is 70% or more (preferably 75% or more and more preferably 80% or more)

(5B): aspect in which, in a case of forming a film having a film thickness of 1 μm, 2 μm, 3 μm, 4 μm or 5 μm after drying, the maximum value of light transmittance in a wavelength range of 400 to 1050 nm in a thickness direction of the film is 20% or less (preferably 15% or less and more preferably 10% or less), and the minimum value of light transmittance in a wavelength range of 1200 to 1500 nm in the thickness direction of the film is 70% or more (preferably 75% or more and more preferably 80% or more)

The coloring composition according to the embodiment of the present invention is also preferably a coloring composition used for forming a pixel by a photolithography method. According to this aspect, finely sized pixels can be easily formed. For example, a coloring composition containing a polymerizable monomer and a photopolymerization initiator can be preferably used as a coloring composition for forming a pixel by a photolithography method.

The concentration of solid contents of the coloring composition according to the embodiment of the present invention is preferably 5% to 30% by mass. The lower limit is preferably 7.5% by mass or more and more preferably 10% by mass or more. The upper limit is preferably 25% by mass or less, more preferably 20% by mass or less, and still more preferably 15% by mass or less.

Hereinafter, the respective components used in the coloring composition according to the embodiment of the present invention will be described.

<<Colorant>>

The coloring composition according to the embodiment of the present invention contains a colorant. The colorant includes a pigment A having a structure represented by Formula (X1) (hereinafter, also referred to as a pigment A). The pigment A is a diketopyrrolopyrrole pigment (pigment having a diketopyrrolopyrrole skeleton). The pigment A is preferably used as a red colorant (red pigment).

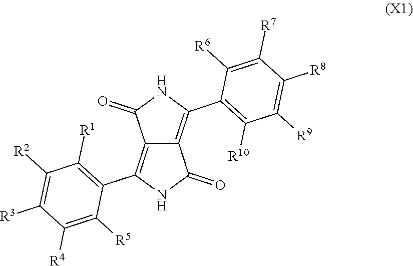

In Formula (X1), R¹ to R¹⁰ each independently represent a hydrogen atom or a group represented by Formula (X2), where at least one of R¹, . . . , or R¹⁰ is the group represented by Formula (X2).

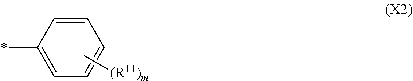

In Formula (X2), R¹¹ represents a substituent, m represents an integer of 0 to 5, and * represents a bonding position in Formula (X1).

Examples of the substituent represented by R¹¹ of Formula (X2) include a substituent T described later, and a halogen atom, an alkyl group, an alkoxy group, an aryloxy group, a cyano group, an alkylthio group, an arylthio group, a nitro group, an amino group, a hydroxy group, a carboxyl group, an acyl group, an acyloxy group, an alkoxycarbonyl group, an aryloxycarbonyl group, an alkylsulfonyl group, an arylsulfonyl group, or a sulfonamide group is preferable.

m of Formula (X2) represents an integer of 0 to 5, preferably an integer of 0 to 2, more preferably 0 or 1, and still more preferably 0. In a case where m is 0, the group represented by Formula (X2) is a phenyl group.

At least one of R¹, . . . , or R¹⁰ of Formula (X1) is the group represented by Formula (X2), and it is preferable that at least one of R¹, . . . , or R⁵ and at least one of R⁶, R¹⁰ of Formula (X1) each are the group represented by Formula (X2).

In addition, it is preferable that R³ and R⁸ of Formula (X1) are the groups represented by Formula (X2). In addition, it is preferable that R¹, R², R⁴, R⁵, R⁶, R⁷, R⁹, and R¹⁰ of Formula (X1) are hydrogen atoms.

The pigment A is preferably a compound having a structure represented by Formula (X1A).

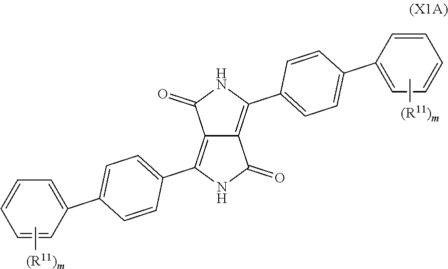

In Formula (X1A), R¹¹ represents a substituent and m represents an integer of 0 to 5. R¹¹ and m in Formula (X1a) have the same meanings as R¹¹ and m in Formula (X1), and preferred ranges thereof are also the same.

Examples of the substituent T include the following groups: a halogen atom (for example, a fluorine atom, a chlorine atom, a bromine atom, and an iodine atom), an alkyl group (preferably an alkyl group having 1 to 30 carbon atoms), an alkenyl group (preferably an alkenyl group having 2 to 30 carbon atoms), an alkynyl group (preferably an alkynyl group having 2 to 30 carbon atoms), an aryl group (preferably an aryl group having 6 to 30 carbon atoms), an amino group (preferably an amino group having 0 to 30 carbon atoms), an alkoxy group (preferably an alkoxy group having 1 to 30 carbon atoms), an aryloxy group (preferably an aryloxy group having 6 to 30 carbon atoms), a heteroaryloxy group, an acyl group (preferably an acyl group having 2 to 30 carbon atoms), an alkoxycarbonyl group (preferably an alkoxycarbonyl group having 2 to 30 carbon atoms), an aryloxycarbonyl group (preferably an aryloxycarbonyl group having 7 to 30 carbon atoms), a heteroaryloxycarbonyl group, an acyloxy group (preferably an acyloxy group having 2 to 30 carbon atoms), an acylamino group (preferably an acylamino group having 2 to 30 carbon atoms), an alkoxycarbonylamino group (preferably an alkoxycarbonylamino group having 2 to 30 carbon atoms), an aryloxycarbonylamino group (preferably an aryloxycarbonylamino group having 7 to 30 carbon atoms), a sulfamoyl group (preferably a sulfamoyl group having 0 to 30 carbon atoms), a carbamoyl group (preferably a carbamoyl group having 1 to 30 carbon atoms), an alkylthio group (preferably an alkylthio group having 1 to 30 carbon atoms), an arylthio group (preferably an arylthio group having 6 to 30 carbon atoms), a heteroarylthio group (preferably having 1 to 30 carbon atoms), an alkylsulfonyl group (preferably having 1 to 30 carbon atoms), an arylsulfonyl group (preferably having 6 to 30 carbon atoms), a heteroarylsulfonyl group (preferably having 1 to 30 carbon atoms), an alkylsulfinyl group (preferably having 1 to 30 carbon atoms), an arylsulfinyl group (preferably having 6 to 30 carbon atoms), a heteroarylsulfinyl group (preferably having 1 to 30 carbon atoms), a ureide group (preferably having 1 to 30 carbon atoms), a hydroxy group, a carboxyl group, a sulfo group, a phosphoric acid group, a carboxylic acid amide group, a sulfonic acid amide group, an imide acid group, a mercapto group, a cyano group, an alkylsulfino group, an arylsulfino group, a hydrazino group, an imino group, a heteroaryl group (preferably having 1 to 30 carbon atoms), a nitro group, and a sulfonamide group. In a case where the above-described groups can be further substituted, the groups may further have a substituent. Examples of the substituent include the groups described regarding the substituent T.

Specific examples of the pigment A include compounds having the following structures. The compound having a structure represented by Formula (X1) is Color Index (C. I.) Pigment Red 264. The pigment A preferably includes C. I. Pigment Red 264. An average primary particle diameter of the pigment A is preferably 5 to 200 nm, more preferably 10 to 150 nm, and still more preferably 15 to 100 nm. For the average primary particle diameter, particle diameters of 100 particles are measured with a transmission electron microscope, and an average value thereof is defined as the average primary particle diameter. A specific surface area of the pigment A is preferably 10 to 300 m²/g.

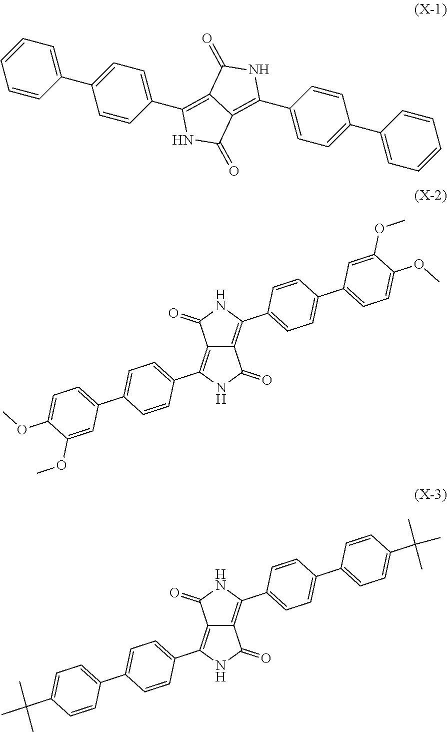

The colorant used in the coloring composition according to the embodiment of the present invention can further contain a colorant other than the above-described pigment A (hereinafter, also referred to as other colorants). Examples of the other colorants include a chromatic colorant and a black colorant. The other colorants may be either a pigment or a dye. The pigment and the dye may be used in combination. The other colorants preferably include a pigment. In addition, the pigment may be an organic pigment or an inorganic pigment. In addition, as the pigment, a material in which a part of an inorganic pigment or an organic-inorganic pigment is substituted with an organic chromophore can also be used. By substituting an inorganic pigment or an organic-inorganic pigment with an organic chromophore, hue design can be easily performed.

In a case where the colorant used in the coloring composition according to the embodiment of the present invention includes other colorants, a content of the other colorants is preferably 10 to 1000 parts by mass with respect to 100 parts by mass of the pigment A. The lower limit is preferably 20 parts by mass or more and more preferably 30 parts by mass or more. The upper limit is preferably 500 parts by mass or less and more preferably 300 parts by mass or less.

(Chromatic Colorant)

Examples of the chromatic colorant used as the other colorants include a colorant having a maximal absorption wavelength in a wavelength range of 400 to 700 nm. Examples thereof include red colorants, yellow colorants, blue colorants, green colorants, violet colorants, and orange colorants. From the viewpoint of heat resistance, the chromatic colorant is preferably a pigment (chromatic pigment). Specific examples of the chromatic pigment include the following.

red pigments such as C. I. Pigment Red 1, 2, 3, 4, 5, 6, 7, 9, 10, 14, 17, 22, 23, 31, 38, 41, 48:1, 48:2, 48:3, 48:4, 49, 49:1, 49:2, 52:1, 52:2, 53:1, 57:1, 60:1, 63:1, 66, 67, 81:1, 81:2, 81:3, 83, 88, 90, 105, 112, 119, 122, 123, 144, 146, 149, 150, 155, 166, 168, 169, 170, 171, 172, 175, 176, 177, 178, 179, 184, 185, 187, 188, 190, 200, 202, 206, 207, 208, 209, 210, 216, 220, 224, 226, 242, 246, 254, 255, 269, 270, 272, 279, 291, 294 (xanthene-based, Organo Ultramarine, Bluish Red), 295 (monoazo-based), 296 (diazo-based), and 297 (aminoketone-based);

yellow pigments such as C. I. Pigment Yellow 1, 2, 3, 4, 5, 6, 10, 11, 12, 13, 14, 15, 16, 17, 18, 20, 24, 31, 32, 34, 35, 35:1, 36, 36:1, 37, 37:1, 40, 42, 43, 53, 55, 60, 61, 62, 63, 65, 73, 74, 77, 81, 83, 86, 93, 94, 95, 97, 98, 100, 101, 104, 106, 108, 109, 110, 113, 114, 115, 116, 117, 118, 119, 120, 123, 125, 126, 127, 128, 129, 137, 138, 139, 147, 148, 150, 151, 152, 153, 154, 155, 156, 161, 162, 164, 166, 167, 168, 169, 170, 171, 172, 173, 174, 175, 176, 177, 179, 180, 181, 182, 185, 187, 188, 193, 194, 199, 213, 214, 215, 228, 231, 232 (methine-based), 233 (quinoline-based), 234 (aminoketone-based), 235 (aminoketone-based), and 236 (aminoketone-based);

blue pigments such as C. I. Pigment Blue 1, 2, 15, 15:1, 15:2, 15:3, 15:4, 15:6, 16, 22, 29, 60, 64, 66, 79, 80, 87 (monoazo-based), and 88 (methine-based);

green pigments such as C. I. Pigment Green 7, 10, 36, 37, 58, 59, 62, 63, 64 (phthalocyanine-based), 65 (phthalocyanine-based), and 66 (phthalocyanine-based);

violet pigments such as C. I. Pigment Violet 1, 19, 23, 27, 32, 37, 42, 60 (triarylmethane-based), and 61 (xanthene-based); and

orange pigments such as C. I. Pigment Orange 2, 5, 13, 16, 17:1, 31, 34, 36, 38, 43, 46, 48, 49, 51, 52, 55, 59, 60, 61, 62, 64, 71, and 73.

In addition, a halogenated zinc phthalocyanine pigment having an average number of halogen atoms in one molecule of 10 to 14, an average number of bromine atoms in one molecule of 8 to 12, and an average number of chlorine atoms in one molecule of 2 to 5 can also be used as the green colorant. Specific examples thereof include the compounds described in WO2015/118720A. In addition, as the green colorant, a compound described in CN2010-6909027A, a phthalocyanine compound described in WO2012/102395A, which has phosphoric acid ester as a ligand, a phthalocyanine compound described in JP2019-008014A, a phthalocyanine compound described in JP2018-180023A, a compound described in JP2019-038958A, and the like can also be used.

In addition, as the blue colorant, an aluminum phthalocyanine compound having a phosphorus atom can also be used. Specific examples thereof include the compounds described in paragraph Nos. 0022 to 0030 of JP2012-247591A and paragraph No. 0047 of JP2011-157478A.

In addition, as the yellow colorant, compounds described in JP2017-201003A, compounds described in JP2017-197719A, compounds described in paragraph Nos. 0011 to 0062 and 0137 to 0276 of JP2017-171912A, compounds described in paragraph Nos. 0010 to 0062 and 0138 to 0295 of JP2017-171913A, compounds described in paragraph Nos. 0011 to 0062 and 0139 to 0190 of JP2017-171914A, compounds described in paragraph Nos. 0010 to 0065 and 0142 to 0222 of JP2017-171915A, quinophthalone compounds described in paragraph Nos. 0011 to 0034 of JP2013-054339A, quinophthalone compounds described in paragraph Nos. 0013 to 0058 of JP2014-026228A, isoindoline compounds described JP2018-062644A, quinophthalone compounds described in JP2018-203798A, quinophthalone compounds described in JP2018-062578A, quinophthalone compounds described in JP6432076B, quinophthalone compounds described in JP2018-155881A, quinophthalone compounds described in JP2018-111757A, quinophthalone compounds described in JP2018-040835A, quinophthalone compounds described in JP2017-197640A, quinophthalone compounds described in JP2016-145282A, quinophthalone compounds described in JP2014-085565A, quinophthalone compounds described in JP2014-021139A, quinophthalone compounds described in JP2013-209614A, quinophthalone compounds described in JP2013-209435A, quinophthalone compounds described in JP2013-181015A, quinophthalone compounds described in JP2013-061622A, quinophthalone compounds described in JP2013-032486A, quinophthalone compounds described in JP2012-226110A, quinophthalone compounds described in JP2008-074987A, quinophthalone compounds described in JP2008-081565A, quinophthalone compounds described in JP2008-074986A, quinophthalone compounds described in JP2008-074985A, quinophthalone compounds described in JP2008-050420A, quinophthalone compounds described in JP2008-031281A, quinophthalone compounds described in JP1973-032765B (JP-S48-032765B), quinophthalone compounds described in JP2019-008014A, quinophthalone compounds described in JP6607427B, methine dyes described in JP2019-073695A, methine dyes described in JP2019-073696A, methine dyes described in JP2019-073697A, methine dyes described in JP2019-073698A, a compound represented by Formula (QP1), a compound represented by Formula (QP2), compounds described in KR10-2014-0034963A, compounds described in JP2017-095706A, compounds described in TW2019-20495A, and compounds described in JP6607427B can also be used. In addition, from the viewpoint of improving a color value, a multimerized compound of these compounds is also preferably used.

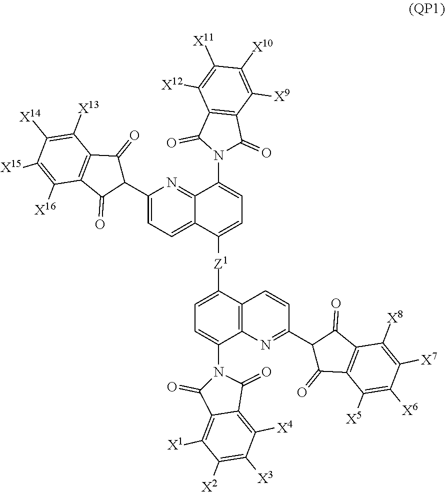

In Formula (QP1), X¹ to X¹⁶ each independently represent a hydrogen atom or a halogen atom, and Z¹ represents an alkylene group having 1 to 3 carbon atoms. Specific examples of the compound represented by Formula (QP1) include compounds described in paragraph No. 0016 of JP6443711B.

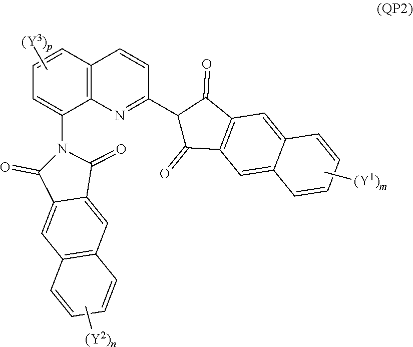

In Formula (QP2), Y¹ to Y³ each independently represent a halogen atom. n and m represent an integer of 0 to 6, and p represents an integer of 0 to 5. (n+m) is 1 or more. Specific examples of the compound represented by Formula (QP2) include compounds described in paragraph Nos. 0047 and 0048 of JP6432077B.

As the red colorant, diketopyrrolopyrrole compounds described in JP2017-201384A, in which the structure has at least one substituted bromine atom, diketopyrrolopyrrole compounds described in paragraph Nos. 0016 to 0022 of JP6248838B, diketopyrrolopyrrole compounds described in WO2012/102399A, diketopyrrolopyrrole compounds described in WO2012/117965A, naphtholazo compounds described in JP2012-229344, red colorants described in JP6516119B, red colorant described in JP6525101B, and the like can also be used.

Examples of the chromatic dye include a pyrazoleazo compound, an anilinoazo compound, a triarylmethane compound, an anthraquinone compound, an anthrapyridone compound, a benzylidene compound, an oxonol compound, a pyrazolotriazoleazo compound, a pyridoneazo compound, a cyanine compound, a phenothiazine compound, a pyrrolopyrazoleazomethine compound, a xanthene compound, a phthalocyanine compound, a benzopyran compound, an indigo compound, and a pyrromethene compound.

(Black Colorant)

The black colorant used as the other colorants is not particularly limited, and a known black colorant can be used. Examples of an inorganic black colorant include carbon black, titanium black, and graphite, and carbon black or titanium black is preferable and titanium black is more preferable. The titanium black is black particles containing a titanium atom, and is preferably lower titanium oxide or titanium oxynitride. The surface of the titanium black can be modified, as necessary, according to the purpose of improving dispersibility, suppressing aggregating properties, and the like. For example, the surface of the titanium black can be coated with silicon oxide, titanium oxide, germanium oxide, aluminum oxide, magnesium oxide, or zirconium oxide. In addition, a treatment with a water-repellent substance as described in JP2007-302836A can be performed. Examples of the black colorant include Color Index (C. I.) Pigment Black 1 and 7. It is preferable that the titanium black has a small primary particle diameter of the individual particles and has a small average primary particle diameter. Specifically, an average primary particle diameter thereof is preferably 10 to 45 nm. The titanium black can be used as a dispersion. Examples thereof include a dispersion which includes titanium black particles and silica particles and in which the content ratio of Si atoms to Ti atoms is adjusted to a range of 0.20 to 0.50. With regard to the dispersion, reference can be made to the description in paragraphs 0020 to 0105 of JP2012-169556A, the contents of which are incorporated herein by reference. Examples of a commercially available product of the titanium black include Titanium black 10S, 12S, 13R, 13M, 13M-C, 13R-N, 13M-T (trade name; manufactured by Mitsubishi Materials Corporation) and Tilack D (trade name; manufactured by Akokasei Co., Ltd.). Examples of the organic black colorant include a bisbenzofuranone compound, an azomethine compound, a perylene compound, and an azo compound. Among these, a bisbenzofuranone compound or a perylene compound is preferable. Examples of the bisbenzofuranone compound include compounds described in JP2010-534726A, JP2012-515233A, JP2012-515234A, WO2014/208348A, JP2015-525260A, and the like, and the bisbenzofuranone compound is available, for example, as “Irgaphor Black” manufactured by BASF SE. Examples of the perylene compound include C. I. Pigment Black 31 and 32. Examples of the azomethine compound include the compounds described in JP1989-170601A (JP-H01-170601A) and JP1990-034664A (JP-H02-034664A), and the azomethine compound is available, for example, “CHROMOFINE BLACK A1103” manufactured by Dainichiseika Color & Chemicals Mfg. Co., Ltd. In addition, as the organic black colorant, perylene black (Lumogen Black FK4280 and the like) described in paragraphs 0016 to 0020 of JP2017-226821A may be used.

A content of the colorant in the total solid content of the coloring composition is preferably 30% to 70% by mass. The lower limit is preferably 35% by mass or more and more preferably 40% by mass or more. The upper limit is preferably 65% by mass or less and more preferably 60% by mass or less.

In addition, a content of the pigment A in the total solid content of the coloring composition is preferably 5% by mass or more, more preferably 7% by mass or more, and still more preferably 10% by mass or more. The upper limit is preferably 70% by mass or less, more preferably 65% by mass or less, and still more preferably 60% by mass or less.

In addition, the content of the pigment A in the colorant is preferably 2% by mass or more, more preferably 5% by mass or more, and still more preferably 7% by mass or more. The upper limit may be 100% by mass or less, 90% by mass or less, or 80% by mass or less.

In a case where the colorant included in the coloring composition includes a red colorant other than the pigment A, a content of the red colorant other than the pigment A is preferably 10 to 1000 parts by mass, more preferably 20 to 800 parts by mass, and still more preferably 30 to 500 parts by mass with respect to 100 parts by mass of the pigment A.

In a case where the coloring composition according to the embodiment of the present invention is used as a coloring composition for forming a red color filter, the content of the pigment A in the colorant is preferably 2% by mass or more, more preferably 5% by mass or more, and still more preferably 7% by mass or more. The upper limit may be 100% by mass or less, 90% by mass or less, or 80% by mass or less. In addition, the content of the red colorant in the colorant is preferably 2% by mass or more, more preferably 5% by mass or more, and still more preferably 7% by mass or more. The upper limit may be 100% by mass or less, 90% by mass or less, or 80% by mass or less. In addition, the content of the pigment A in the red colorant is preferably 5% to 100% by mass, more preferably 10% to 100% by mass, and still more preferably 20% to 100% by mass.

In a case where the coloring composition according to the embodiment of the present invention is used as a coloring composition for forming a red color filter, it is preferable that the colorant further includes a yellow colorant in addition to the red colorant. In addition, a content of the yellow colorant in the colorant is preferably 2 to 100 parts by mass, more preferably 5 to 80 parts by mass, and still more preferably 10 to 50 parts by mass with respect to 100 parts by mass of the red colorant. In addition, a content of an orange colorant in the colorant is preferably 2 to 200 parts by mass, more preferably 5 to 100 parts by mass, and still more preferably 10 to 50 parts by mass with respect to 100 parts by mass of the red colorant.

In a case where the coloring composition according to the embodiment of the present invention is used as a coloring composition for an infrared transmitting filter, a colorant including the pigment A and a colorant other than the pigment A is used as the colorant, and it is preferable to satisfy at least one of the following requirement (A) or (B).

(A): colorant includes two or more chromatic colorants, and a combination of the two or more chromatic colorants forms black.

(B): as other colorants, a colorant including a black colorant is used.

In a case where a combination of the two or more chromatic colorants forms black, examples of the combination of the chromatic colorants include the following aspects (1) to (8). As the red colorant, a colorant including the above-described pigment A is used. A content of the pigment A in the red colorant is preferably 2% to 100% by mass, more preferably 5% to 100% by mass, and still more preferably 10% to 100% by mass.

(1) aspect in which the colorant contains a red colorant and a blue colorant

(2) aspect in which the colorant contains a red colorant, a blue colorant, and a yellow colorant

(3) aspect in which the colorant contains a red colorant, a blue colorant, a yellow colorant, and a violet colorant

(4) aspect in which the colorant contains a red colorant, a blue colorant, a yellow colorant, a violet colorant, and a green colorant

(5) aspect in which the colorant contains a red colorant, a blue colorant, a yellow colorant, and a green colorant

(6) aspect in which the colorant contains a red colorant, a blue colorant, and a green colorant

(7) aspect in which the colorant contains a red colorant, a green colorant, and a yellow colorant

(8) aspect in which the colorant contains a red colorant and a green colorant

In the aspect (B) described above, it is preferable to further use a chromatic colorant (also referred to as a chromatic colorant A) as the other colorants. The chromatic colorant A is preferably a colorant having a hue different from that of the pigment A, and more preferably at least one selected from a blue colorant, a yellow colorant, a green colorant, or a violet colorant. In addition, the black colorant is preferably an organic black colorant, more preferably a bisbenzofuranone compound, an azomethine compound, a perylene compound, or an azo compound, and still more preferably a bisbenzofuranone compound or a perylene compound. By using the black colorant and the chromatic colorant A in combination as the other colorants, excellent spectral characteristics are easily obtained. A mixing proportion of the pigment A, the chromatic colorant A, and the black colorant is preferably such that the total amount of the pigment A and the chromatic colorant A is 10 to 200 parts by mass with respect to 100 parts by mass of the black colorant, and more preferably so as to be 15 to 150 parts by mass.

<<Infrared Absorber>>

The coloring composition according to the embodiment of the present invention can include an infrared absorber.

The infrared absorber is preferably a pigment, and more preferably an organic pigment. In addition, the infrared absorber preferably has a maximal absorption wavelength in a wavelength range of more than 700 nm and 1400 nm or less. In addition, the maximal absorption wavelength of the infrared absorber is preferably 1200 nm or less, more preferably 1000 nm or less, and still more preferably 950 nm or less. In addition, in the infrared absorber, A₅₅₀/Aₘₐₓ, which is a ratio of an absorbance Asso at a wavelength of 550 nm to an absorbance Aₘₐₓ at the maximal absorption wavelength, is preferably 0.1 or less, more preferably 0.05 or less, still more preferably 0.03 or less, and particularly preferably 0.02 or less. The lower limit is not particularly limited, but for example, may be 0.0001 or more or may be 0.0005 or more. In a case where the ratio of the above-described absorbance is within the above-described range, an infrared absorber excellent in visible light transparency and near-infrared shielding properties can be obtained. In the present invention, the maximal absorption wavelength of the infrared absorber and values of absorbance at each wavelength are values obtained from an absorption spectrum of a film formed of a composition including the infrared absorber.

The infrared absorber is not particularly limited, and examples thereof include a pyrrolopyrrole compound, a cyanine compound, a squarylium compound, a phthalocyanine compound, a naphthalocyanine compound, a quaterrylene compound, a merocyanine compound, a croconium compound, an oxonol compound, an iminium compound, a dithiol compound, a triarylmethane compound, a pyrromethene compound, an azomethine compound, an anthraquinone compound, a dibenzofuranone compound, and a dithiolene metal complex. Examples of the pyrrolopyrrole compound include compounds described in paragraph Nos. 0016 to 0058 of JP2009-263614A, compounds described in paragraph Nos. 0037 to 0052 of JP2011-068731A, and compounds described in paragraph Nos. 0010 to 0033 of WO2015/166873A. Examples of the squarylium compound include compounds described in paragraph Nos. 0044 to 0049 of JP2011-208101A, compounds described in paragraph Nos. 0060 and 0061 of JP6065169B, compounds described in paragraph No. 0040 of WO2016/181987A, compounds described in JP2015-176046A, compounds described in paragraph No. 0072 of WO2016/190162A, compounds described in paragraph Nos. 0196 to 0228 of JP2016-074649A, compounds described in paragraph No. 0124 of JP2017-067963A, compounds described in WO2017/135359A, compounds described in JP2017-114956A, compounds described in JP6197940B, and compounds described in WO2016/120166A. Examples of the cyanine compound include compounds described in paragraph Nos. 0044 and 0045 of JP2009-108267A, compounds described in paragraph Nos. 0026 to 0030 of JP2002-194040A, compounds described in JP2015-172004A, compounds described in JP2015-172102A, compounds described in JP2008-088426A, compounds described in paragraph No. 0090 of WO2016/190162A, and compounds described in JP2017-031394A. Examples of the croconium compound include compounds described in JP2017-082029A. Examples of the iminium compound include compounds described in JP2008-528706A, compounds described in JP2012-012399A, compounds described in JP2007-092060A, and compounds described in paragraph Nos. 0048 to 0063 of WO2018/043564A. Examples of the phthalocyanine compound include compounds described in paragraph No. 0093 of JP2012-077153A, oxytitanium phthalocyanine described in JP2006-343631A, compounds described in paragraph Nos. 0013 to 0029 of JP2013-195480A, and vanadium phthalocyanine compounds described in JP6081771B. Examples of the naphthalocyanine compound include compounds described in paragraph No. 0093 of JP2012-077153A. Examples of the dithiolene metal complex include compounds described in JP5733804B.

In addition, as the infrared absorber, squarylium compounds described in JP2017-197437A, squarylium compounds described in JP2017-025311A, squarylium compounds described in WO2016/154782A, squarylium compounds described in JP5884953B, squarylium compounds described in JP6036689B, squarylium compounds described in JP5810604B, squarylium compounds described in paragraph Nos. 0090 to 0107 of WO2017/213047A, pyrrole ring-containing compounds described in paragraph Nos. 0019 to 0075 of JP2018-054760A, pyrrole ring-containing compounds described in paragraph Nos. 0078 to 0082 of JP2018-040955A, pyrrole ring-containing compounds described in paragraph Nos. 0043 to 0069 of JP2018-002773A, squarylium compounds having an aromatic ring at the α-amide position described in paragraph Nos. 0024 to 0086 of JP2018-041047A, amide-linked squarylium compounds described in JP2017-179131A, compounds having a pyrrole bis-type squarylium skeleton or a croconium skeleton described in JP2017-141215A, dihydrocarbazole bis-type squarylium compounds described in JP2017-082029, asymmetric compounds described in paragraph Nos. 0027 to 0114 of JP2017-068120A, pyrrole ring-containing compounds (carbazole type) described in JP2017-067963A, phthalocyanine compounds described in JP6251530B, compounds described in JP2013-077009, JP2014-130338A, or WO2015/166779A, and the like can also be used.

A content of the infrared absorber in the total solid content of the coloring composition is preferably 0.1% to 50% by mass. The lower limit is preferably 1% by mass or more and more preferably 5% by mass or more. The upper limit is preferably 40% by mass or less and more preferably 30% by mass or less.

In addition, the total content of the colorant and the infrared absorber in the total solid content is preferably 30% to 90% by mass. The lower limit is preferably 35% by mass or more, more preferably 40% by mass or more, and still more preferably 50% by mass or more. The upper limit is preferably 80% by mass or less and more preferably 70% by mass or less.

<<Pigment Derivative>>

The coloring composition according to the embodiment of the present invention can contain a pigment derivative. Examples of the pigment derivative include a compound having a structure in which a part of a chromophore is substituted with an acid group or a basic group. Examples of the chromophore constituting the pigment derivative include a quinoline skeleton, a benzoimidazolone skeleton, a diketopyrrolopyrrole skeleton, an azo skeleton, a phthalocyanine skeleton, an anthraquinone skeleton, a quinacridone skeleton, a dioxazine skeleton, a perinone skeleton, a perylene skeleton, a thioindigo skeleton, an isoindoline skeleton, an isoindolinone skeleton, a quinophthalone skeleton, a threne skeleton, and a metal complex-based skeleton. Among these, a quinoline skeleton, a benzoimidazolone skeleton, a diketopyrrolopyrrole skeleton, an azo skeleton, a quinophthalone skeleton, an isoindoline skeleton, or a phthalocyanine skeleton is preferable, and an azo skeleton or a benzoimidazolone skeleton is more preferable. Examples of the acid group include a sulfo group, a carboxyl group, a phosphoric acid group, and a salt thereof. Examples of an atom or atomic group constituting the salts include alkali metal ions (Li⁺, Na⁺, K⁺, and the like), alkaline earth metal ions (Ca²⁺, Mg²⁺, and the like), an ammonium ion, an imidazolium ion, a pyridinium ion, and a phosphonium ion. Examples of the basic group included in the pigment derivative include an amino group, a pyridinyl group, or a salt thereof, a salt of an ammonium group, and a phthalimidomethyl group. Examples of an atom or atomic group constituting the salts include a hydroxide ion, a halogen ion, a carboxylate ion, a sulfonate ion, and a phenoxide ion.

In the present invention, as the pigment derivative, a pigment derivative having excellent visible transparency (hereinafter, also referred to as a transparent pigment derivative) can be contained. The maximum value (εmax) of a molar absorption coefficient of the transparent pigment derivative in a wavelength range of 400 to 700 nm is preferably 3000 L·mol⁻¹·cm⁻¹ or less, more preferably 1000 L·mol⁻¹·cm⁻¹ or less, and still more preferably 100 L·mol⁻¹·cm⁻¹ or less. The lower limit of cmax is, for example, 1 L·mol⁻¹·cm⁻¹ or more and may be 10 L·mol⁻¹·cm⁻¹ or more.

Specific examples of the pigment derivative include compounds described in JP1981-118462A (JP-556-118462A), JP1988-264674A (JP-563-264674A), JP1989-217077A (JP-H01-217077A), JP1991-009961A (JP-H03-009961A), JP1991-026767A (JP-H03-026767A), JP1991-153780A (JP-H03-153780A), JP1991-045662A (JP-H03-045662A), JP1992-285669A (JP-H04-285669A), JP1994-145546A (JP-H06-145546A), JP1994-212088A (JP-H06-212088A), JP1994-240158A (JP-H06-240158A), JP1998-030063A (JP-H10-030063A), JP1998-195326A (JP-H10-195326A), paragraph Nos. 0086 to 0098 of WO2011/024896A, paragraph Nos. 0063 to 0094 of WO2012/102399A, paragraph No. 0082 of WO2017/038252A, paragraph No. 0171 of JP2015-151530A, paragraph Nos. 0162 to 0183 of JP2011-252065A, JP2003-081972A, JP5299151B, JP2015-172732A, JP2014-199308A, JP2014-085562A, JP2014-035351A, JP2008-081565A, and JP2019-109512A.

A content of the pigment derivative is preferably 1 to 30 parts by mass and still more preferably 3 to 20 parts by mass with respect to 100 parts by mass of the colorant. In addition, the content of the pigment derivative is preferably 1 to 30 parts by mass and still more preferably 3 to 20 parts by mass with respect to 100 parts by mass of the pigment. The pigment derivative may be used singly or in a combination of two or more kinds thereof. In a case where two or more kinds thereof are used in combination, the total amount thereof is preferably within the above-described range.

<<Resin>>

The coloring composition according to the embodiment of the present invention includes a resin. The resin included in the coloring composition according to the embodiment of the present invention includes at least one selected from a polyimide resin, a polyimide precursor, a polybenzoxazole resin, a polybenzoxazole precursor, or a polysiloxane resin. Hereinafter, the polyimide resin, the polyimide precursor, the polybenzoxazole resin, the polybenzoxazole precursor, and the polysiloxane resin are collectively referred to as a specific resin.

(Specific Resin)

The coloring composition according to the embodiment of the present invention preferably includes at least one selected from a polyimide resin, a polyimide precursor, a polybenzoxazole resin, or a polybenzoxazole precursor, more preferably includes at least one selected from a polyimide resin or a polyimide precursor, and still more preferably includes a polyimide precursor. According to this aspect, it is possible to form a film in which film shrinkage is unlikely to occur even after a heating treatment at a high temperature. In addition, even in a case where, after forming other films such as an inorganic film on a surface of the film formed of the coloring composition, a heating treatment at a high temperature (for example, 300° C. or higher) is performed, it is also possible to more effectively suppress occurrence of cracks in the other films. Furthermore, it is also possible to further suppress variation in spectral characteristics after a heating treatment. In addition, it is presumed that the polyimide resin, the polyimide precursor, the polybenzoxazole resin, and the polybenzoxazole precursor tend to interact with the pigment A, and that aggregation of the pigment A can be effectively suppressed by suppressing the thermal diffusion of the pigment A in the film. Therefore, even in a case where the film formed of the coloring composition is subjected to a heating treatment at a high temperature (for example, 300° C. or higher), it is also possible to effectively suppress the precipitation of foreign matter.

[Polyimide Precursor]

The polyimide precursor is preferably a polyimide precursor having a crosslinkable group. According to this aspect, it is possible to form a film in which film shrinkage is unlikely to occur even after a heating treatment at a high temperature. In addition, even in a case where, after forming other films such as an inorganic film on a surface of the film formed of the coloring composition, a heating treatment at a high temperature (for example, 300° C. or higher) is performed, it is also possible to more effectively suppress occurrence of cracks in the other films. Furthermore, it is also possible to further suppress variation in spectral characteristics after a heating treatment.

Examples of the crosslinkable group include an ethylenically unsaturated bond-containing group and a cyclic ether group, and an ethylenically unsaturated bond-containing group is preferable. In a case where a polyimide precursor having an ethylenically unsaturated bond-containing group is used as the polyimide precursor, it is also possible to obtain a coloring composition having excellent pattern forming properties by a photolithography method. Examples of the ethylenically unsaturated bond-containing group include a vinyl group, a vinylphenyl group, a (meth)allyl group, a (meth)acryloyl group, a (meth)acryloyloxy group, and a (meth)acryloylamide group. Among these, a (meth)allyl group, a (meth)acryloyl group, or a (meth)acryloyloxy group is preferable, and a (meth)acryloyloxy group is more preferable. Examples of the cyclic ether group include an epoxy group and an oxetanyl group.

In addition, the polyimide precursor preferably includes a silicon atom. According to this aspect, it is possible to form a film having excellent effects described above. The polyimide precursor including a silicon atom is preferably a polyimide precursor including a siloxane bond. It is also preferable that the polyimide precursor including a silicon atom further has a crosslinkable group.

Examples of the polyimide precursor include precursors including a constitutional unit represented by Formula (PI-1).

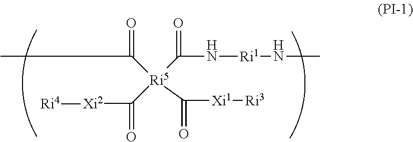

In the formula, Ri¹ represents a divalent organic group, Ri⁵ represents a tetravalent organic group, Ri³ and Ri² each independently represent a hydrogen atom or a monovalent organic group, Xi¹ and Xi² each independently represent O or NRxi, and Rxi represents a hydrogen atom or a substituent.

Examples of the divalent organic group represented by Ri¹ include a group including an aliphatic hydrocarbon group, a group including an aromatic hydrocarbon group, and a group including a heterocyclic group. The divalent organic group represented by Ri¹ is preferably a group including a linear aliphatic hydrocarbon group having 2 to 20 carbon atoms, a branched aliphatic hydrocarbon group having 3 to 20 carbon atoms, a cyclic aliphatic hydrocarbon group having 3 to 20 carbon atoms, or an aromatic hydrocarbon group having 6 to 20 carbon atoms.

Ri¹ is preferably a group derived from diamine. The diamine is preferably a compound including a linear aliphatic hydrocarbon group having 2 to 20 carbon atoms, a branched aliphatic hydrocarbon group having 3 to 20 carbon atoms, a cyclic aliphatic hydrocarbon group having 3 to 20 carbon atoms, or an aromatic hydrocarbon group having 6 to 20 carbon atoms, and more preferably a compound including an aromatic hydrocarbon group having 6 to 20 carbon atoms. In addition, it is also preferable that the diamine is a compound including a silicon atom. The diamine including a silicon atom is more preferably a diamine including a siloxane bond. Specific examples of the diamine include compounds described in paragraph Nos. 0024 to 0029 of WO2017/209177A, the contents of which are incorporated herein by reference.

Ri¹ is preferably a group represented by -Ar¹-L¹-Ar²-. Ar¹ and Ar² are each independently preferably an aromatic hydrocarbon group (preferably an aromatic hydrocarbon group having 6 to 22 carbon atoms, more preferably an aromatic hydrocarbon group having 6 to 18 carbon atoms, and particularly preferably an aromatic hydrocarbon group having 6 to 10 carbon atoms). The aromatic hydrocarbon group may have a substituent. Examples of the substituent include an alkyl group, a halogen atom, and a hydroxy group, and a hydroxy group is preferable. L¹ represents a single bond or a divalent linking group. As the divalent linking group, an aliphatic hydrocarbon group having 1 to 10 carbon atoms, which may be substituted with a fluorine atom, or a group selected from —O—, —C(═O)—, —C(═O)O—, —S—, —S(═O)₂—, —NHCO—, and a combination thereof is preferable, an alkylene group having 1 to 3 carbon atoms, which may be substituted with a fluorine atom, or a group selected from —O—, —C(═O)—, —S—, —SO₂—, and —NHCO— is more preferable, and —CH₂—, —O—, —S—, —SO₂—, —C(CF₃)₂—, —C(CH₃)₂—, or —NHCO-— is still more preferable.

In addition, from the reason that it is possible to form a film having excellent adhesiveness to a base, Ri¹ is also preferably a group represented by Formula (SR).

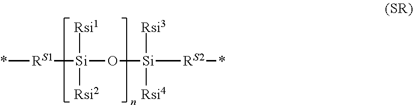

In the formula, R^{S1} and R^{S2} each independently represent a group including an aliphatic hydrocarbon group, a group including an aromatic hydrocarbon group, or a group including a heterocyclic group, Rsi¹ to Rsi⁴ each independently represent a hydrogen atom, an alkyl group, or an aryl group, and n represents an integer of 1 to 10.

R^{S1} and R^{S2} are each independently preferably a group including an aliphatic hydrocarbon group or a group including an aromatic hydrocarbon group, more preferably a group including an aliphatic hydrocarbon group, and still more preferably an aliphatic hydrocarbon group.

Rsi ¹ to Rsi⁴ are each independently preferably an alkyl group or an aryl group, and more preferably an alkyl group.

The alkyl group represented by Rsi¹ to Rsi⁴ preferably has 1 to 10 carbon atoms, more preferably has 1 to 5 carbon atoms, and still more preferably 1 to 3 carbon atoms.

The aryl group represented by Rsi¹ to Rsi⁴ preferably has 6 to 22 carbon atoms, more preferably has 6 to 18 carbon atoms, and still more preferably 6 to 10 carbon atoms.

n represents an integer of 1 to 10, and is preferably an integer of 1 to 5, more preferably 1 or 2, and still more preferably 1.

As the tetravalent organic group represented by Ri⁵, a group including an aromatic ring is preferable, and a group represented by Formula (Ri⁵-1) or Formula (Ri⁵-2) is more preferable.

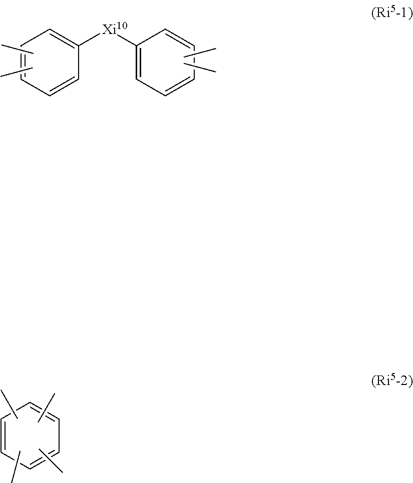

Xi¹⁰ represents a single bond or a divalent linking group. As the divalent linking group, an aliphatic hydrocarbon group having 1 to 10 carbon atoms, which may be substituted with a fluorine atom, or a group selected from —O—, —C(═O)—, —C(═O)O—, —S—, —S(═O)₂—, —NHCO—, and a combination thereof is preferable, an alkylene group having 1 to 3 carbon atoms, which may be substituted with a fluorine atom, or a group selected from —O—, —C(═O)—, —S—, and —SO₂— is more preferable, and —CH₂—, —O—, —S—, —SO₂—, —C(CF₃)₂—, or —C(CH₃)₂— is still more preferable.

Specific examples of the tetravalent organic group represented by Ri⁵ include a tetracarboxylic acid residue remaining after removing an acid dianhydride group from a tetracarboxylic acid dianhydride. The tetracarboxylic acid dianhydride may be used singly or two or more kinds thereof may be used. Specific examples of the tetracarboxylic acid dianhydride include compounds described in paragraphs 0035 to 0037 of WO2017/209177A, the contents of which are incorporated herein by reference.

Ri³ and Ri⁴ each independently represent a hydrogen atom or a monovalent organic group. Examples of the monovalent organic group include a group including a crosslinkable group, an acid-decomposable group, a hydrocarbon group, and a heterocyclic group. It is preferable that at least one of Ri³ or Ri⁴ is a group including a crosslinkable group, and it is more preferable that both are groups including a crosslinkable group. Examples of the crosslinkable group include an ethylenically unsaturated bond-containing group and a cyclic ether group, and an ethylenically unsaturated bond-containing group is preferable. In a case of using a polyimide precursor including an ethylenically unsaturated bond-containing group, a film having more excellent characteristics can be easily obtained. In addition, in a case where the coloring composition according to the embodiment of the present invention includes a photopolymerization initiator, the coloring composition according to the embodiment of the present invention can be a coloring composition having excellent pattern forming properties by a photolithography method. Examples of the ethylenically unsaturated bond-containing group include a vinyl group, a vinylphenyl group, a (meth)allyl group, a (meth)acryloyl group, a (meth)acryloyloxy group, and a (meth)acryloylamide group. Among these, a (meth)allyl group, a (meth)acryloyl group, or a (meth)acryloyloxy group is preferable, and a (meth)acryloyloxy group is more preferable. Examples of the cyclic ether group include an epoxy group and an oxetanyl group.

Examples of the group including a crosslinkable group, represented by Ri³ and Ri⁴, include a group represented by -Rc¹-Rc². Rc¹ represents a single bond or a divalent linking group and Rc² represents a crosslinkable group. Examples of the divalent linking group represented by Rd include an aliphatic hydrocarbon group, an aromatic hydrocarbon group, a heterocyclic group, and a group selected from a combination of these groups and at least one selected from —O—, —C(═O)—, —C(═O)O—, —S—, —S(═O)₂—, or —NHCO—. Examples of the crosslinkable group represented by Rc² include the above-described groups.

Examples of the acid-decomposable group represented by Ri³ and Ri⁴ include a tertiary alkyl group and an acetal-type acid-decomposable group. Examples of the above-described tertiary alkyl group include a t-butyl group. Examples of the above-described acetal-type acid-decomposable group include a 1-alkoxyalkyl group, a 2-tetrahydrofuranyl group, and a 2-tetrahydropyranyl group.

Examples of the hydrocarbon group represented by Ri³ and Ri⁴ include an alkyl group, an aryl group, and an arylalkyl group. The alkyl group preferably has 1 to 30 carbon atoms, more preferably has 1 to 15 carbon atoms, and still more preferably has 1 to 8 carbon atoms. The alkyl group may be linear, branched, or cyclic, and is preferably linear or branched. The aryl group preferably has 6 to 30 carbon atoms, more preferably has 6 to 25 carbon atoms, and still more preferably has 6 to 12 carbon atoms. The arylalkyl group preferably has 7 to 30 carbon atoms, more preferably has 7 to 25 carbon atoms, and still more preferably 7 to 12 carbon atoms.

The heterocyclic group represented by Ri³ and Ri⁴ may be a single ring or a fused ring. The heterocyclic group is preferably a single ring or a fused ring having 2 to 4 fused numbers. The number of heteroatoms constituting a ring of the heterocyclic group is preferably 1 to 3. The heteroatom constituting the ring of the heterocyclic group is preferably a nitrogen atom, an oxygen atom, or a sulfur atom. The number of carbon atoms constituting the ring of the heterocyclic group is preferably 3 to 30, more preferably 3 to 18, and more preferably 3 to 12.

The hydrocarbon group and heterocyclic group represented by Ri³ and Ri⁴ may have a substituent or may be unsubstituted. Examples of the substituent include acid groups such as a hydroxy group, a carboxyl group, a sulfo group, a phosphoric acid group, and a phosphonic acid group; groups in which these acid groups are protected by an acid-decomposable group; and crosslinkable groups.

Xi¹ and Xi² each independently represent O or NRxi, in which Rxi represents a hydrogen atom or a substituent. Examples of the substituent represented by Rxi include an alkyl group, an aryl group, an alkoxy group, an aryloxy group, and an acyl group. Rxi is preferably a hydrogen atom. Xi¹ and Xi² are preferably O.

In the polyimide precursor, the constitutional unit represented by Formula (PI-1) may be one kind or two or more kinds. In addition, the polyimide precursor may include a structural isomer of the constitutional unit represented by Formula (PI-1). In addition, the polyimide precursor may include other types of constitutional units in addition to the constitutional unit represented by Formula (PI-1).

As one embodiment of the polyimide precursor, a polyimide precursor in which 50 mol % or more, still 70 mol % or more, particularly 90 mol % or more of all constitutional units are the constitutional unit represented by Formula (PI-1) is mentioned.

As the polyimide precursor, polyimide precursors described in paragraph Nos. 0015 to 0029 of JP2017-186530A, paragraph Nos. 0030 to 0036 of JP2019-023728A, and paragraph Nos. 0029 to 0035 of JP2019-045865A can also be used, the contents of which are incorporated herein by reference.

A weight-average molecular weight (Mw) of the polyimide precursor is preferably 2000 to 500000, more preferably 5000 to 100000, and still more preferably 10000 to 50000. In addition, a number-average molecular weight (Mn) thereof is preferably 800 to 250000, more preferably 2000 to 50000, and still more preferably 4000 to 25000.

A degree of dispersion of the molecular weight of the polyimide precursor is preferably 1.5 to 3.5 and more preferably 2.0 to 3.0.

[Polyimide Resin]

Examples of the polyimide resin include a resin having a polyimide ring. Examples thereof include a resin obtained by cyclizing a polyimide precursor. Examples of the polyimide precursor include those described above.

The polyimide resin preferably has a crosslinkable group. According to this aspect, it is easy to form a film having excellent effects described above. Examples of the crosslinkable group are as described above.

In addition, the polyimide resin preferably includes a silicon atom, and more preferably includes a siloxane bond. According to this aspect, it is easy to form a film having excellent effects described above.

In addition, it is also preferable that the polyimide resin has at least one group selected from a carboxyl group, a sulfo group, a phosphoric acid group, or a phosphonic acid group in at least one of the main chain or the side chain. According to this aspect, a polyimide resin having excellent solubility in an alkali developer can be obtained.

[Polybenzoxazole Precursor]

The polybenzoxazole precursor preferably has a crosslinkable group. According to this aspect, it is possible to form a film having excellent effects described above. Examples of the crosslinkable group include an ethylenically unsaturated bond-containing group and a cyclic ether group, and an ethylenically unsaturated bond-containing group is preferable. In a case where a polybenzoxazole precursor having an ethylenically unsaturated bond-containing group is used as the polybenzoxazole precursor, it is also possible to obtain a coloring composition having excellent pattern forming properties by a photolithography method. Examples of the crosslinkable group are as described above.

In addition, the polybenzoxazole precursor preferably includes a silicon atom. According to this aspect, it is possible to form a film having excellent effects described above. The polyimide precursor including a silicon atom is preferably a polybenzoxazole precursor including a siloxane bond. It is also preferable that the polybenzoxazole precursor including a silicon atom further has a crosslinkable group.

Examples of the polybenzoxazole precursor include precursors including a constitutional unit represented by Formula (PBO-1).

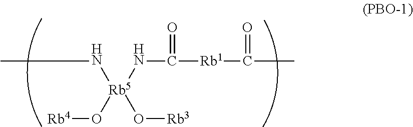

Rb¹ represents a divalent organic group, Rb⁵ represents a tetravalent organic group, and Rb³ and Rb⁴ each independently represent a hydrogen atom or a monovalent organic group.

Examples of divalent organic group represented by Rb¹ of Formula (PBO-1) include a group including an aliphatic hydrocarbon group, a group including an aromatic hydrocarbon group, and a group including a heterocyclic group. The divalent organic group represented by Rb¹ is preferably a group including a linear aliphatic hydrocarbon group having 2 to 20 carbon atoms, a branched aliphatic hydrocarbon group having 3 to 20 carbon atoms, a cyclic aliphatic hydrocarbon group having 3 to 20 carbon atoms, or an aromatic hydrocarbon group having 6 to 20 carbon atoms.

As the tetravalent organic group represented by Rb⁵ in Formula (PBO-1), a group including an aromatic ring is preferable, and the group represented by Formula (Ri⁵-1) or Formula (Ri⁵-2) described above is more preferable.

Examples of the monovalent organic group represented by Rb³ and Rb⁴ in Formula (PBO-1) include a group including a crosslinkable group, an acid-decomposable group, a hydrocarbon group, and a heterocyclic group. It is preferable that at least one of Rb³ or Rb⁴ is a group including a crosslinkable group, and it is more preferable that both are groups including a crosslinkable group. Examples of details of the group including a crosslinkable group, acid-decomposable group, hydrocarbon group, and heterocyclic group include those described in the section of monovalent organic group represented Ri¹ and Ri⁴ in Formula (PI-1), and the same applies to the preferred range.

In the polybenzoxazole precursor, the constitutional unit represented by Formula (PBO-1) may be one kind or two or more kinds. In addition, the polybenzoxazole precursor may include a structural isomer of the constitutional unit represented by Formula (PBO-1). In addition, the polybenzoxazole precursor may include other types of constitutional units in addition to the constitutional unit represented by Formula (PBO-1).

Examples of other constitutional units include a constitutional unit represented by Formula (SL-1).

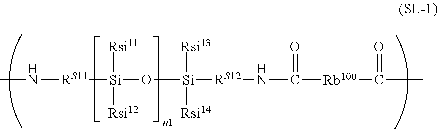

In Formula (SL-1), R^{S11} and R^{S12} each independently represent a group including an aliphatic hydrocarbon group, a group including an aromatic hydrocarbon group, or a group including a heterocyclic group, Rsi¹¹ to Rsi¹⁴ each independently represent a hydrogen atom, an alkyl group, or an aryl group, n1 represents an integer of 1 to 10, and Rb¹⁰⁰ represents a divalent organic group.

R^{S11} and R^{S12} of Formula (SL-1) are each independently preferably a group including an aliphatic hydrocarbon group or a group including an aromatic hydrocarbon group, more preferably a group including an aliphatic hydrocarbon group, and still more preferably an aliphatic hydrocarbon group.

Rsi¹¹ to Rsi¹⁴ of Formula (SL-1) are each independently preferably an alkyl group or an aryl group, and more preferably an alkyl group.

The alkyl group represented by Rsi¹¹ to Rsi¹⁴ preferably has 1 to 10 carbon atoms, more preferably has 1 to 5 carbon atoms, and still more preferably 1 to 3 carbon atoms.

The aryl group represented by Rsi¹¹ to Rsi¹⁴ preferably has 6 to 22 carbon atoms, more preferably has 6 to 18 carbon atoms, and still more preferably 6 to 10 carbon atoms.

n1 in Formula (SL-1) represents an integer of 1 to 10, and is preferably an integer of 1 or 5, more preferably 1 or 2, and still more preferably 1.

Examples of the divalent organic group represented by Rb¹⁰⁰ include a group including an aliphatic hydrocarbon group, a group including an aromatic hydrocarbon group, and a group including a heterocyclic group. The divalent organic group represented by Rb¹⁰⁰ is preferably a group including a linear aliphatic hydrocarbon group having 2 to 20 carbon atoms, a branched aliphatic hydrocarbon group having 3 to 20 carbon atoms, a cyclic aliphatic hydrocarbon group having 3 to 20 carbon atoms, or an aromatic hydrocarbon group having 6 to 20 carbon atoms.

A weight-average molecular weight (Mw) of the polybenzoxazole precursor is preferably 2000 to 500000, more preferably 5000 to 100000, and still more preferably 10000 to 50000. In addition, a number-average molecular weight (Mn) thereof is preferably 800 to 250000, more preferably 2000 to 50000, and still more preferably 4000 to 25000.

A degree of dispersion of the molecular weight of the polybenzoxazole precursor is preferably 1.5 to 3.5 and more preferably 2.0 to 3.0.

[Polybenzoxazole Resin]

Examples of the polybenzoxazole resin include a resin having a benzoxazole ring. Examples thereof include a resin obtained by cyclizing a polybenzoxazole precursor. Examples of the polybenzoxazole precursor include those described above.

The polybenzoxazole resin preferably has a crosslinkable group. According to this aspect, it is easy to form a film having excellent effects described above. Examples of the crosslinkable group are as described above.

In addition, the polybenzoxazole resin preferably includes a silicon atom, and more preferably includes a siloxane bond. According to this aspect, it is easy to form a film having excellent effects described above.

In addition, it is also preferable that the polybenzoxazole resin has at least one group selected from a carboxyl group, a sulfo group, a phosphoric acid group, or a phosphonic acid group in at least one of the main chain or the side chain. According to this aspect, a polybenzoxazole resin having excellent solubility in an alkali developer can be obtained.

[Polysiloxane Resin]

Examples of the polysiloxane resin include a resin having a repeating unit including a siloxane bond. In the polysiloxane resin, the repeating unit including a siloxane bond may be included in the main chain or the side chain. Examples of the polysiloxane resin include an epoxy-modified polysiloxane resin, a polyester-modified polysiloxane resin, an alkyd-modified polysiloxane resin, a urethane-modified polysiloxane resin, and an acrylic-modified polysiloxane resin, and from the reason that it is easy to form a film having excellent effects described above, an epoxy-modified polysiloxane resin or a polyester-modified polysiloxane resin is preferable, and an epoxy-modified polysiloxane resin is more preferable.

In addition, from the reason that the effects of the present invention are more remarkably exhibited, the polysiloxane resin preferably has at least one group selected from an alkylsilyl group or an alkoxysilyl group, and more preferably has an alkoxysilyl group.

In addition, it is also preferable that the polysiloxane resin has a crosslinkable group. According to this aspect, it is possible to form a film having excellent effects described above. Examples of the crosslinkable group include an ethylenically unsaturated bond-containing group and a cyclic ether group. Examples of the crosslinkable group are as described above.

A weight-average molecular weight (Mw) of the polysiloxane resin is preferably 500 to 1000000, more preferably 1000 to 100000, and still more preferably 2000 to 20000.

Examples of one aspect of the polysiloxane resin include a reactant of a compound having a hydroxy group and an epoxy group with a silsesquioxane compound containing an epoxy group and an alkoxy group. The polysiloxane resin of this embodiment preferably has an epoxy group. In addition, an epoxy equivalent of the polysiloxane resin of this embodiment is preferably 150 to 500 g/eq. In addition, with regard to the polysiloxane resin of this embodiment, the ratio of the number of moles of epoxy groups derived from the compound having a hydroxy group and an epoxy group and the number of moles of epoxy groups derived from the silsesquioxane compound containing an epoxy group and an alkoxy group ((number of moles of epoxy groups derived from the compound having a hydroxy group and an epoxy group)/(number of moles of epoxy groups derived from the silsesquioxane compound containing an epoxy group and an alkoxy group)) is preferably 0.1 to 3. In addition, it is also preferable that the polysiloxane resin of this embodiment has an alkoxy group. An amount of the alkoxy group included in the polysiloxane resin is preferably 150 to 3000 g/eq.

Examples of the above-described compound having a hydroxy group and an epoxy group include bisphenol-type epoxy resins such as a bisphenol A-type epoxy resin, a bisphenol F-type epoxy resin, and a bisphenol S-type epoxy resin, a hydrogenated bisphenol type epoxy resin with nuclear hydrogenated benzene ring of epoxy resin, a phenolic novolac-type epoxy resin, a cresol novolac-type epoxy resin, a biphenol-type epoxy resin, and a naphthalene-type epoxy resin.

The average number of hydroxy groups included in the compound having a hydroxy group and an epoxy group is preferably 0.3 to 5.

Examples of the above-described silsesquioxane compound having an epoxy group and an alkoxy group include a compound obtained by hydrolyzing and condensing a compound represented by Formula (Si-1).

Rs¹Si(ORs²)₃ (Si-1)

(in the formula, Rs¹ represents a hydrocarbon group having 3 to 8 carbon atoms, which has an epoxy group, and Rs² represents a hydrogen atom or a hydrocarbon group having 1 to 4 carbon atoms)

Specific examples of the compound represented by Formula (Si-1) include glycydoxypropyltrialkoxysilanes such as 3-glycidoxypropyltrimethoxysilane, 3-glycidoxypropyltriethoxysilane, and 3-glycidoxypropyltripropoxysilane; and (epoxycyclohexyl)ethyltrialkoxysilanes such as 2-(3,4-epoxycyclohexyl)ethyltrimethoxysilane, 2-(3,4-epoxycyclohexyl)ethyltriethoxysilane, and 2-(3,4-epoxycyclohexyl)ethyltripropoxysilane.

In addition to the above-described compound represented by Formula (Si-1), metal alkoxides which do not contain an epoxy group, such as trialkylalkoxysilanes such as trimethylmethoxysilane, trimethylethoxysilane, triethylmethoxysilane, triethylethoxysilane, triphenylmethoxysilane, and triphenylethoxysilane; dialkyldialkoxysilanes such as dimethyldimethoxysilane, dimethyldiethoxysilane, diethyldiethoxysilane, diethyldiethoxysilane, diphenyldimethoxysilane, diphenyldiethoxysilane, methylphenyldimethoxysilane, methylphenyldiethoxysilane, and 3-mercaptopropylmethyldimethoxysilane; alkyltrialkoxysilanes such as methyltrimethoxysilane, methyltriethoxysilane, ethyltrimethoxysilane, ethyltriethoxysilane, phenyltrimethoxysilane, and phenyltriethoxysilane; tetraalkoxysilanes such as tetramethoxysilane, tetraethoxysilane, tetrapropoxysilane, and tetrabutoxysilane; tetraalkoxytitaniums such as tetramethoxytitanium, tetraethoxytitanium, tetrapropoxytitanium, and tetrabutoxytitanium; and tetraalkoxyzirconiums such as tetraethoxyzirconium, tetrapropoxyzirconium, and tetrabutoxyzirconium, may be further used in combination.

(Total of the number of moles of alkoxy groups included in the compound represented by Formula (Si-1) and the number of moles of alkoxy groups included in the metal alkoxides)/(total of the number of moles of the compound represented by Formula (Si-1) and the number of moles of the metal alkoxides) is preferably 2.5 to 3.5 and more preferably 2.7 to 3.2.

By hydrolyzing and condensing the compound represented by Formula (Si-1) or a mixture of the compound represented by Formula (Si-1) and the above-described metal alkoxides, the silsesquioxane compound containing an epoxy group and an alkoxy group is obtained. By the hydrolysis reaction, the alkoxy group included in the compound represented by Formula (Si-1) and the above-described metal alkoxides forms a silanol group, and an alcohol is by-produced. As an amount of water required for the hydrolysis reaction, (number of moles of water used for the hydrolysis reaction)/(total number of moles of each alkoxy group included in the compound represented by Formula (Si-1) and the metal alkoxides) is preferably 0.2 to 1 and more preferably 0.3 to 0.7.

In reacting the compound having a hydroxy group and an epoxy group with the silsesquioxane compound having an epoxy group and an alkoxy group to obtain a polysiloxane resin which is a reactant thereof, the proportion of use of the compound having a hydroxy group and an epoxy group and the silsesquioxane compound having an epoxy group and an alkoxy group is preferably 20 to 800 parts by mass of the silsesquioxane compound having an epoxy group and an alkoxy group, and more preferably 50 to 500 parts by mass of the silsesquioxane compound having an epoxy group and an alkoxy group with respect to 100 parts by mass of the compound having a hydroxy group and an epoxy group.

Specific examples of the polysiloxane resin include compounds having the following structures.

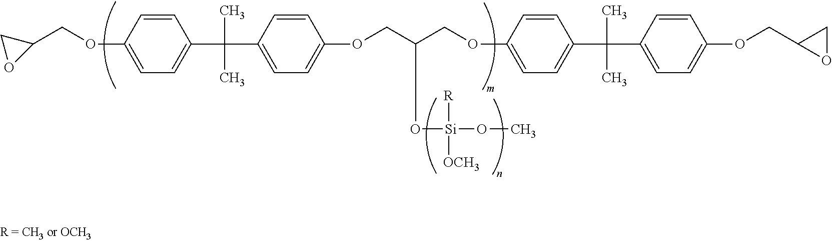

Examples of a commercially available product of the polysiloxane resin include KR-5230, RK-5234, and KR-5235 (all of which are manufactured by Shin-Etsu Silicone Co., Ltd.), and COMPOCERAN E103A, E103D, and E203 (all of which are manufactured by Arakawa Chemical Industries, Ltd.).

(Other Resins)

The coloring composition according to the embodiment of the present invention can further include a resin other than the specific resin described above (hereinafter, also referred to other resins). The other resins may be a resin as a binder or a resin as a dispersant.

A weight-average molecular weight (Mw) of the other resins is preferably a value exceeding 3000. The upper limit of the weight-average molecular weight (Mw) is preferably 1000000 or less and more preferably 500000 or less. The lower limit of the weight-average molecular weight (Mw) is preferably 3500 or more, more preferably 4000 or more, and still more preferably 5000 or more.

Examples of the other resins include a (meth)acrylic resin, a (meth)acrylamide resin, an epoxy resin, an ene-thiol resin, a polycarbonate resin, a polyether resin, a polyarylate resin, a polysulfone resin, a polyethersulfone resin, a polyphenylene resin, a polyarylene ether phosphine oxide resin, a polyolefin resin, a cyclic olefin resin, a polyester resin, a styrene resin, and a polyimine resin.

The other resins is also preferably a resin having an acid group. Examples of the acid group include a carboxyl group, a phosphoric acid group, a sulfo group, and a phenolic hydroxy group. The resin having an acid group can also be used as an alkali-soluble resin or a dispersant. An acid value of the resin having an acid group is preferably 30 to 500 mgKOH/g. The lower limit is more preferably 50 mgKOH/g or more and still more preferably 70 mgKOH/g or more. The upper limit is more preferably 400 mgKOH/g or less, still more preferably 200 mgKOH/g or less, even still more preferably 150 mgKOH/g or less, and most preferably 120 mgKOH/g or less.

The other resins are also preferably a resin including a repeating unit derived from a compound represented by Formula (ED1) and/or a compound represented by Formula (ED2) (hereinafter, these compounds will also be referred to as an “ether dimer”).

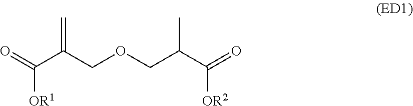

In Formula (ED1), R¹ and R² each independently represent a hydrogen atom or a hydrocarbon group having 1 to 25 carbon atoms, which may have a substituent.

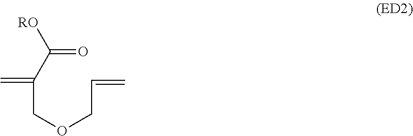

In Formula (ED2), R represents a hydrogen atom or an organic group having 1 to 30 carbon atoms. Specific examples of Formula (ED2) can be found in the description of JP2010-168539A.

Specific examples of the ether dimer can be found in paragraph No. 0317 of JP2013-029760A, the contents of which are incorporated herein by reference.

The other resins are also preferably a resin having an ethylenically unsaturated bond-containing group. Examples of the ethylenically unsaturated bond-containing group include a vinyl group, a vinylphenyl group, a (meth)allyl group, a (meth)acryloyl group, a (meth)acryloyloxy group, and a (meth)acryloylamide group. Among these, a (meth)allyl group, a (meth)acryloyl group, or a (meth)acryloyloxy group is preferable, and a (meth)acryloyloxy group is more preferable.

The other resins also preferably include a resin including a repeating unit derived from a compound represented by Formula (X).

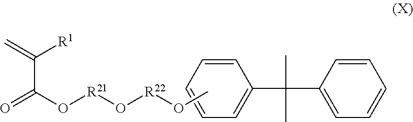

In the formula, R¹ represents a hydrogen atom or a methyl group, R²¹ and R²² each independently represent an alkylene group, and n represents an integer of 0 to 15. The number of carbon atoms in the alkylene group represented by R²¹ and R²² is preferably 1 to 10, more preferably 1 to 5, still more preferably 1 to 3, and particularly preferably 2 or 3. n represents an integer of 0 to 15, and is preferably an integer of 0 or 5, more preferably an integer of 0 to 4, and still more preferably an integer of 0 to 3.

Examples of the compound represented by Formula (X) include ethylene oxide- or propylene oxide-modified (meth)acrylate of para-cumylphenol. Examples of a commercially available product thereof include ARONIX M-110 (manufactured by TOAGOSEI CO., LTD.).

The other resin may be a resin as a dispersant. Examples of the dispersant include an acidic dispersant (acidic resin) and a basic dispersant (basic resin). Here, the acidic dispersant (acidic resin) represents a resin in which the amount of the acid group is larger than the amount of the basic group. The acidic dispersant (acidic resin) is preferably a resin in which the amount of the acid group occupies 70 mol % or more in a case where the total amount of the acid group and the basic group is 100 mol %, and more preferably a resin substantially consisting of only an acid group. The acid group included in the acidic dispersant (acidic resin) is preferably a carboxyl group. An acid value of the acidic dispersant (acidic resin) is preferably 10 to 105 mgKOH/g. In addition, the basic dispersant (basic resin) represents a resin in which the amount of the basic group is larger than the amount of the acid group. The basic dispersant (basic resin) is preferably a resin in which the amount of the basic group is more than 50 mol % in a case where the total amount of the acid group and the basic group is 100 mol %. The basic group included in the basic dispersant is preferably an amino group.

The resin used as a dispersant preferably includes a repeating unit having an acid group. In a case where the resin used as a dispersant includes a repeating unit having an acid group, the generation of the development residue can be further suppressed in the formation of a pattern by a photolithography method.

It is also preferable that the resin used as a dispersant is a graft resin. With regard to details of the graft resin, reference can be made to the description in paragraph Nos. 0025 to 0094 of JP2012-255128A, the contents of which are incorporated herein by reference.

It is also preferable that the resin used as a dispersant is a polyimine-based dispersant including a nitrogen atom in at least one of the main chain or the side chain. As the polyimine-based dispersant, a resin having a main chain which has a partial structure having a functional group of pKa 14 or less, and a side chain which has 40 to 10000 atoms, in which at least one of the main chain or the side chain has a basic nitrogen atom, is preferable. The basic nitrogen atom is not particularly limited as long as it is a nitrogen atom exhibiting basicity. With regard to the polyimine-based dispersant, reference can be made to the description in paragraph Nos. 0102 to 0166 of JP2012-255128A, the contents of which are incorporated herein by reference.

It is also preferable that the resin used as a dispersant is a resin having a structure in which a plurality of polymer chains are bonded to a core portion. Examples of such a resin include dendrimers (including star polymers). In addition, specific examples of the dendrimer include polymer compounds C-1 to C-31 described in paragraph Nos. 0196 to 0209 of JP2013-043962A.

A commercially available product is also available as the dispersant, and specific examples thereof include DISPERBYK series (for example, DISPERBYK-111, 2001, and the like) manufactured by BYK-Chemie, Solsperse series (for example, Solsperse 20000, 76500, and the like) manufactured by Lubrizol Japan Ltd., and AJISPER series manufactured by Ajinomoto Fine-Techno Co., Inc. In addition, products described in paragraph No. 0129 of JP2012-137564A and products described in paragraph No. 0235 of JP2017-194662A can also be used as the dispersant.

In addition, as the other resins, the resin described in JP6349629B can also be used. In addition, as the resin as a dispersant or the alkali-soluble resin, a resin in which an acid anhydride is reacted with a hydroxy group generated by an epoxy ring opening to introduce an acid group may be used.

A content of the resin in the total solid content of the coloring composition is preferably 5% to 80% by mass. The lower limit is preferably 10% by mass or more, more preferably 15% by mass or more, and still more preferably 20% by mass or more. The upper limit is preferably 70% by mass or less and more preferably 60% by mass or less.

A content of the specific resin in the total solid content of the coloring composition is preferably 5% to 80% by mass. The lower limit is preferably 10% by mass or more, more preferably 15% by mass or more, and still more preferably 20% by mass or more. The upper limit is preferably 70% by mass or less and more preferably 60% by mass or less.

The total content of the polyimide resin, the polyimide precursor, the polybenzoxazole resin, and the polybenzoxazole precursor in the total solid content of the coloring composition is preferably 5% to 80% by mass. The lower limit is preferably 10% by mass or more, more preferably 15% by mass or more, and still more preferably 20% by mass or more. The upper limit is preferably 70% by mass or less and more preferably 60% by mass or less.

A content of the specific resin in the resin included in the coloring composition is preferably 5% to 100% by mass, more preferably 10% to 100% by mass, and still more preferably 20% to 100% by mass. The upper limit may be 90% by mass or less or 80% by mass or less.

The total content of the polyimide resin, the polyimide precursor, the polybenzoxazole resin, and the polybenzoxazole precursor in the specific resin is preferably 20% to 100% by mass, more preferably 30% to 100% by mass, and still more preferably 50% to 100% by mass.

The total content of the polyimide resin and the polyimide precursor in the specific resin is preferably 20% to 100% by mass, more preferably 30% to 100% by mass, and still more preferably 50% to 100% by mass.

A proportion of the specific resin and the pigment A is preferably 10 to 1500 parts by mass of the pigment A, more preferably 20 to 1200 parts by mass of the pigment A, and still more preferably 50 to 1000 parts by mass of the pigment A with respect to 100 parts by mass of the specific resin.

<<Polymerizable Monomer>>

It is preferable that the coloring composition according to the embodiment of the present invention contains a polymerizable monomer. Examples of the polymerizable monomer include a compound having an ethylenically unsaturated bond-containing group. Examples of the ethylenically unsaturated bond-containing group include a vinyl group, a vinylphenyl group, a (meth)allyl group, a (meth)acryloyl group, a (meth)acryloyloxy group, and a (meth)acryloylamide group. Among these, a (meth)allyl group, a (meth)acryloyl group, or a (meth)acryloyloxy group is preferable, and a (meth)acryloyloxy group is more preferable. The polymerizable monomer used in the present invention is preferably a radically polymerizable monomer.

A molecular weight of the polymerizable monomer is preferably 100 to 3000. The upper limit is more preferably 2000 or less and still more preferably 1500 or less. The lower limit is more preferably 150 or more and still more preferably 250 or more.

An ethylenically unsaturated bond-containing group value (hereinafter, referred to as a C═C value) of the polymerizable monomer is preferably 90 to 300 g/mol. The lower limit is preferably 93 g/mol or more and particularly preferably 96 g/mol or more. The upper limit is preferably 250 g/mol or less and particularly preferably 200 g/mol or less. The C═C value of the polymerizable monomer is calculated by dividing the molecular weight of the polymerizable monomer by the number of ethylenically unsaturated bond groups included in one molecule of the polymerizable monomer.

The polymerizable monomer is preferably a compound including 3 or more ethylenically unsaturated bond-containing groups, more preferably a compound including 3 to 15 ethylenically unsaturated bond-containing groups, and still more preferably a compound including 3 to 6 ethylenically unsaturated bond-containing groups. In addition, the polymerizable monomer is preferably a trifunctional to pentadecafunctional (meth)acrylate compound and more preferably a trifunctional to hexafunctional (meth)acrylate compound. Specific examples of the polymerizable monomer include the compounds described in paragraph Nos. 0095 to 0108 of JP2009-288705A, paragraph No. 0227 of JP2013-029760A, paragraph Nos. 0254 to 0257 of JP2008-292970A, paragraph Nos. 0034 to 0038 of JP2013-253224A, paragraph No. 0477 of JP2012-208494A, JP2017-048367A, JP6057891B, JP6031807B, and JP2017-194662A, the contents of which are incorporated herein by reference.

As the polymerizable monomer, dipentaerythritol tri(meth)acrylate (as a commercially available product, KAYARAD D-330 manufactured by Nippon Kayaku Co., Ltd.), dipentaerythritol tetra(meth)acrylate (as a commercially available product, KAYARAD D-320 manufactured by Nippon Kayaku Co., Ltd.), dipentaerythritol penta(meth)acrylate (as a commercially available product, KAYARAD D-310 manufactured by Nippon Kayaku Co., Ltd.), dipentaerythritol hexa(meth)acrylate (as a commercially available product, KAYARAD DPHA manufactured by Nippon Kayaku Co., Ltd., NK ESTER A-DPH-12E manufactured by Shin-Nakamura Chemical Co., Ltd.), or a compound having a structure in which these (meth)acryloyl groups are bonded through an ethylene glycol and/or a propylene glycol residue (for example, SR454 and SR499 which are commercially available products from Sartomer Company Inc.) is preferable. In addition, as the polymerizable monomer, diglycerin ethylene oxide (EO)-modified (meth)acrylate (as a commercially available product, M-460 manufactured by TOAGOSEI CO., LTD.), pentaerythritol tetraacrylate (NK ESTER A-TMMT manufactured by Shin-Nakamura Chemical Co., Ltd.), 1,6-hexanediol diacrylate (KAYARAD HDDA manufactured by Nippon Kayaku Co., Ltd.), RP-1040 (manufactured by Nippon Kayaku Co., Ltd.), ARONIX TO-2349 (manufactured by TOAGOSEI CO., LTD.), NK OLIGO UA-7200 (manufactured by Shin-Nakamura Chemical Co., Ltd.), 8UH-1006 and 8UH-1012 (manufactured by Taisei Fine Chemical Co., Ltd.), Light Acrylate POB-A0 (manufactured by KYOEISHA CHEMICAL Co., Ltd.), and the like can also be used.

As the polymerizable monomer, it is also preferable to use a trifunctional (meth)acrylate compound such as trimethylolpropane tri(meth)acrylate, trimethylolpropane propyleneoxide-modified tri(meth)acrylate, trimethylolpropane ethyleneoxide-modified tri(meth)acrylate, isocyanuric acid ethyleneoxide-modified tri(meth)acrylate, and pentaerythritol tri(meth)acrylate. Examples of a commercially available product of the trifunctional (meth)acrylate compound include ARONIX M-309, M-310, M-321, M-350, M-360, M-313, M-315, M-306, M-305, M-303, M-452, and M-450 (manufactured by TOAGOSEI CO., LTD.), NK ESTER A9300, A-GLY-9E, A-GLY-20E, A-TMM-3, A-TMM-3L, A -TMM-3LM-N, A-TMPT, and TMPT (manufactured by Shin-Nakamura Chemical Co., Ltd.), and KAYARAD GPO-303, TMPTA, THE-330, TPA-330, and PET-30 (manufactured by Nippon Kayaku Co., Ltd.).

As the polymerizable monomer, a polymerizable monomer having an acid group can also be used. By using a polymerizable monomer having an acid group, a coloring composition in a non-exposed portion is easily removed during development and the generation of the development residue can be suppressed. Examples of the acid group include a carboxyl group, a sulfo group, and a phosphoric acid group, and a carboxyl group is preferable. Examples of a commercially available product of the polymerizable monomer having an acid group include ARONIX M-305, M-510, M-520, and ARONIX TO-2349 (manufactured by TOAGOSEI CO., LTD). An acid value of the polymerizable monomer having an acid group is preferably 0.1 to 40 mgKOH/g and more preferably 5 to 30 mgKOH/g.

As the polymerizable monomer, a polymerizable monomer having a caprolactone structure can also be used. Examples of the polymerizable monomer having a caprolactone structure include DPCA-20, DPCA-30, DPCA-60, and DPCA-120, each of which is commercially available as KAYARAD DPCA series from Nippon Kayaku Co., Ltd.

As the polymerizable monomer, a polymerizable monomer having an alkyleneoxy group can also be used. The polymerizable monomer having an alkyleneoxy group is preferably a polymerizable monomer having an ethyleneoxy group and/or a propyleneoxy group, more preferably a polymerizable monomer having an ethyleneoxy group, and still more preferably a trifunctional to hexafunctional (meth)acrylate compound having 4 to 20 ethyleneoxy groups. Examples of a commercially available product of the polymerizable monomer having an alkyleneoxy group include SR-494 manufactured by Sartomer Company Inc., which is a tetrafunctional (meth)acrylate having 4 ethyleneoxy groups, and KAYARAD TPA-330 manufactured by Nippon Kayaku Co., Ltd., which is a trifunctional (meth)acrylate having 3 isobutyleneoxy groups.

As the polymerizable monomer, a polymerizable monomer having a fluorene skeleton can also be used. Examples of a commercially available product of the polymerizable monomer having a fluorene skeleton include OGSOL EA-0200 and EA-0300 (manufactured by Osaka Gas Chemicals Co., Ltd., a (meth)acrylate monomer having a fluorene skeleton).

As the polymerizable monomer, it is also preferable to use a compound which does not substantially include environmentally regulated substances such as toluene. Examples of a commercially available product of such a compound include KAYARAD DPHA LT and KAYARAD DPEA-12 LT (manufactured by Nippon Kayaku Co., Ltd.).

The urethane acrylates described in JP1973-041708B (JP-S48-041708B), JP1976-037193A (JP-S51-037193A), JP1990-032293B (JP-H02-032293B), or JP1990-016765B (JP-H02-016765B), or the urethane compounds having an ethylene oxide skeleton described in JP1983-049860B (JP-S58-049860B), JP1981-017654B (JP-S56-017654B), JP1987-039417B (JP-S62-039417B), or JP1987-039418B (JP-S62-039418B) are also suitable as the polymerizable monomer. In addition, the polymerizable monomers having an amino structure or a sulfide structure in the molecule, described in JP1988-277653A (JP-S63-277653A), JP1988-260909A (JP-S63-260909A), or JP1989-105238A (JP-H01-105238A), are also preferably used. In addition, as the polymerizable monomer, commercially available products such as UA-7200 (manufactured by Shin-Nakamura Chemical Co., Ltd.), DPHA-40H (manufactured by Nippon Kayaku Co., Ltd.), and UA-306H, UA-306T, UA-306I, AH-600, T-600, AI-600, and LINC-202UA (manufactured by KYOEISHA CHEMICAL Co., Ltd.) can also be used.

The polymerizable monomer used in the coloring composition according to the embodiment of the present invention preferably includes a tri- or lower functional polymerizable monomer C1 having 2 or 3 ethylenically unsaturated bond-containing groups and a tetra- or higher functional polymerizable monomer C2 having 4 or more ethylenically unsaturated bond-containing groups. According to this aspect, the effects of the present invention are more remarkably exhibited. In a case where the polymerizable monomer C1 and the polymerizable monomer C2 are used in combination, a proportion of both is preferably 10 to 1000 parts by mass, more preferably 30 to 300 parts by mass, and still more preferably 50 to 200 parts by mass of the polymerizable monomer C2 with respect to 100 parts by mass of the polymerizable monomer C1. In addition, a C═C value of the polymerizable monomer C1 is preferably 90 to 300 g/mol. The lower limit is preferably 93 g/mol or more and particularly preferably 96 g/mol or more. The upper limit is preferably 250 g/mol or less and particularly preferably 200 g/mol or less. In addition, a C═C value of the polymerizable monomer C2 is preferably 90 to 300 g/mol. The lower limit is preferably 93 g/mol or more and particularly preferably 96 g/mol or more. The upper limit is preferably 250 g/mol or less and particularly preferably 200 g/mol or less.

A content of the polymerizable monomer in the total solid content of the coloring composition is preferably more than 0% by mass and 30% by mass or less. The lower limit is preferably 0.1% by mass or more and more preferably 0.5% by mass or more. The upper limit is preferably 20% by mass or less, more preferably 15% by mass or less, and still more preferably 10% by mass or less.

<<Polymerization Initiator>>

It is preferable that the coloring composition according to the embodiment of the present invention includes a photopolymerization initiator. As the polymerization initiator, a photopolymerization initiator is preferable. The photopolymerization initiator is not particularly limited, and can be appropriately selected from known photopolymerization initiators. For example, a compound having photosensitivity to light in a range from an ultraviolet range to a visible range is preferable. The photopolymerization initiator is preferably a photoradical polymerization initiator.

Examples of the photopolymerization initiator include a halogenated hydrocarbon derivative (for example, a compound having a triazine skeleton, a compound having an oxadiazole skeleton, a compound having an imidazole skeleton, or the like), an acylphosphine compound, a hexaarylbiimidazole, an oxime compound, an organic peroxide, a thio compound, a ketone compound, an aromatic onium salt, an α-hydroxyketone compound, and an α-aminoketone compound. From the viewpoint of exposure sensitivity, as the photopolymerization initiator, a biimidazole compound, a trihalomethyltriazine compound, a benzyldimethylketal compound, an α-hydroxyketone compound, an α-aminoketone compound, an acylphosphine compound, a phosphine oxide compound, a metallocene compound, an oxime compound, a triarylimidazole dimer, an onium compound, a benzothiazole compound, a benzophenone compound, an acetophenone compound, a cyclopentadiene-benzene-iron complex, a halomethyl oxadiazole compound, or a 3-aryl-substituted coumarin compound is preferable, a compound selected from a biimidazole compound, an oxime compound, an α-hydroxyketone compound, an α-aminoketone compound, or an acylphosphine compound is more preferable, a compound selected from an oxime compound, an α-hydroxyketone compound, an α-aminoketone compound, or an acylphosphine compound is still more preferable, and an oxime compound is particularly preferable. In addition, as the photopolymerization initiator, compounds described in paragraphs 0065 to 0111 of JP2014-130173A, compounds described in JP6301489B, peroxide-based photopolymerization initiators described in MATERIAL STAGE, p. 37 to 60, vol. 19, No. 3, 2019, photopolymerization initiators described in WO2018/221177A, photopolymerization initiators described in WO2018/110179A, photopolymerization initiators described in JP2019-043864A, and photopolymerization initiators described in JP2019-044030A, the contents of which are incorporated herein by reference.

Examples of the biimidazole compound include 2,2-bis(2-chlorophenyl)-4,4′,5, 5′-tetraphenylbiimidazole, 2,2′-bis(o-chlorophenyl)-4,4′, 5, 5-tetrakis(3,4,5-trimethoxyphenyl)-1,2′-biimidazole, 2,2′-bis(2,3-dichlorophenyl)-4,4′,5,5′-tetraphenylbiimidazole, and 2,2′-bis (o-chlorophenyl)-4,4,5,5′-tetraphenyl-1,2′-biimidazole. Examples of a commercially available product of the α-hydroxyketone compound include Omnirad 184, Omnirad 1173, Omnirad 2959, and Omnirad 127 (all of which are manufactured by IGM Resins RV), Irgacure 184, Irgacure 1173, Irgacure 2959, and Irgacure 127 (all of which are manufactured by BASF SE). Examples of a commercially available product of the α-aminoketone compound include Omnirad 907, Omnirad 369, Omnirad 369E, and Omnirad 379EG (all of which are manufactured by IGM Resins B.V.), Irgacure 907, Irgacure 369, Irgacure 369E, and Irgacure 379EG (all of which are manufactured by BASF SE). Examples of a commercially available product of the acylphosphine compound include Omnirad 819 and Omnirad TPO (both of which are manufactured by IGM Resins B.V.), Irgacure 819 and Irgacure TPO (both of which are manufactured by BASF SE).

Examples of the oxime compound include the compounds described in JP2001-233842A, the compounds described in JP2000-080068A, the compounds described in J. C. S. Perkin II (1979, pp. 1653 to 1660), the compounds described in J. C. S. Perkin II (1979, pp. 156 to 162), the compounds described in Journal of Photopolymer Science and Technology (1995, pp. 202 to 232), the compounds described in JP2000-066385A, the compounds described in JP2004-534797A, the compounds described in JP2006-342166A, the compounds described in JP2017-019766A, the compounds described in JP6065596B, the compounds described in WO2015/152153A, the compounds described in WO2017/051680A, the compounds described in JP2017-198865A, the compounds described in paragraph Nos. 0025 to 0038 of WO2017/164127A, and the compounds described in WO2013/167515A. Specific examples of the oxime compound include 3-benzoyloxyiminobutane-2-one, 3-acetoxyiminobutane-2-one, 3-propionyloxyiminobutane-2-one, 2-acetoxyiminopentane-3-one, 2-acetoxyimino-1-phenylpropane-1-one, 2-benzoyloxyimino-1-phenylpropane-1-one, 3-(4-toluenesulfonyloxy)iminobutane-2-one, and 2-ethoxycarbonyloxyimino-1-phenylpropane-1-one. Examples of a commercially available product thereof include Irgacure OXE01, Irgacure OXE02, Irgacure OXE03, and Irgacure OXE04 (all of which are manufactured by BASF SE), TR-PBG-304 (manufactured by TRONLY), and ADEKA OPTOMER N-1919 (manufactured by ADEKA Corporation; photopolymerization initiator 2 described in JP2012-014052A). In addition, as the oxime compound, it is also preferable to use a compound having no colorability or a compound having high transparency and being resistant to discoloration. Examples of a commercially available product include ADEKA ARKLS NCI-730, NCI-831, and NCI-930 (all of which are manufactured by ADEKA Corporation).

An oxime compound having a fluorene ring can also be used as the photopolymerization initiator. Specific examples of the oxime compound having a fluorene ring include the compounds described in JP2014-137466A.

As the photopolymerization initiator, an oxime compound having a skeleton in which at least one benzene ring of a carbazole ring is a naphthalene ring can also be used. Specific examples of such an oxime compound include the compounds described in WO2013/083505A.

An oxime compound having a fluorine atom can also be used as the photopolymerization initiator. Specific examples of the oxime compound having a fluorine atom include the compounds described in JP2010-262028A, the compounds 24, and 36 to 40 described in JP2014-500852A, and the compound (C-3) described in JP2013-164471A.

An oxime compound having a nitro group can be used as the photopolymerization initiator. The oxime compound having a nitro group is also preferably used in the form of a dimer. Specific examples of the oxime compound having a nitro group include the compounds described in paragraph Nos. 0031 to 0047 of JP2013-114249A and paragraph Nos. 0008 to 0012 and 0070 to 0079 of JP2014-137466A, the compounds described in paragraph Nos. 0007 to 0025 of JP4223071B, and ADEKA ARKLS NCI-831 (manufactured by ADEKA Corporation).

An oxime compound having a benzofuran skeleton can also be used as the photopolymerization initiator. Specific examples thereof include OE-01 to OE-75 described in WO2015/036910A.

In the present invention, as the photopolymerization initiator, an oxime compound in which a substituent having a hydroxy group is bonded to a carbazole skeleton can also be used. Examples of such a photopolymerization initiator include compounds described in WO2019/088055A.

Specific examples of the oxime compound which are preferably used in the present invention are shown below, but the present invention is not limited thereto.

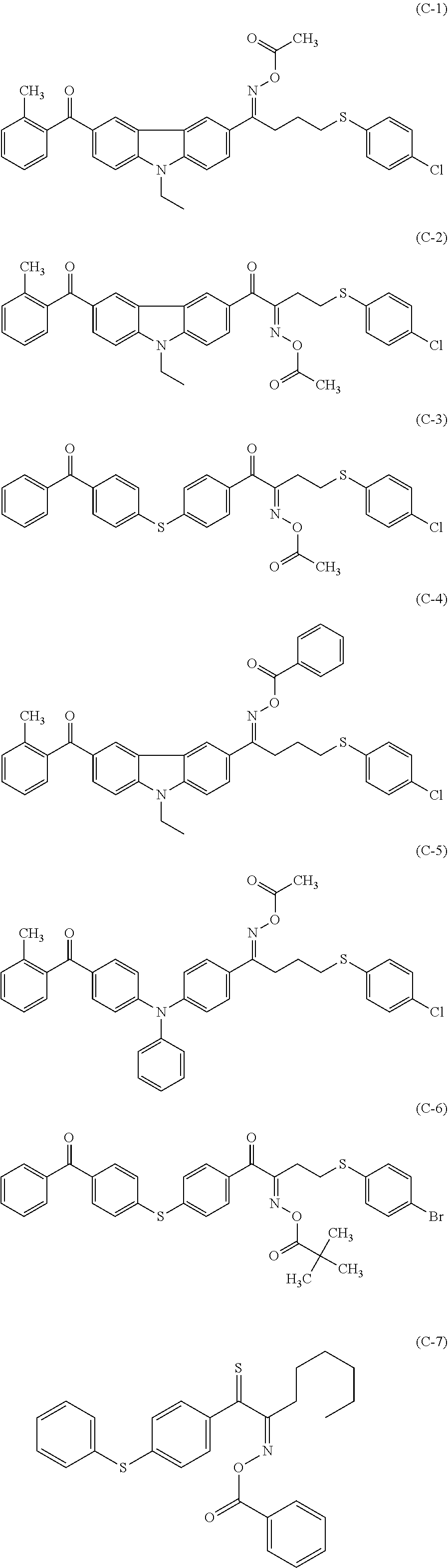

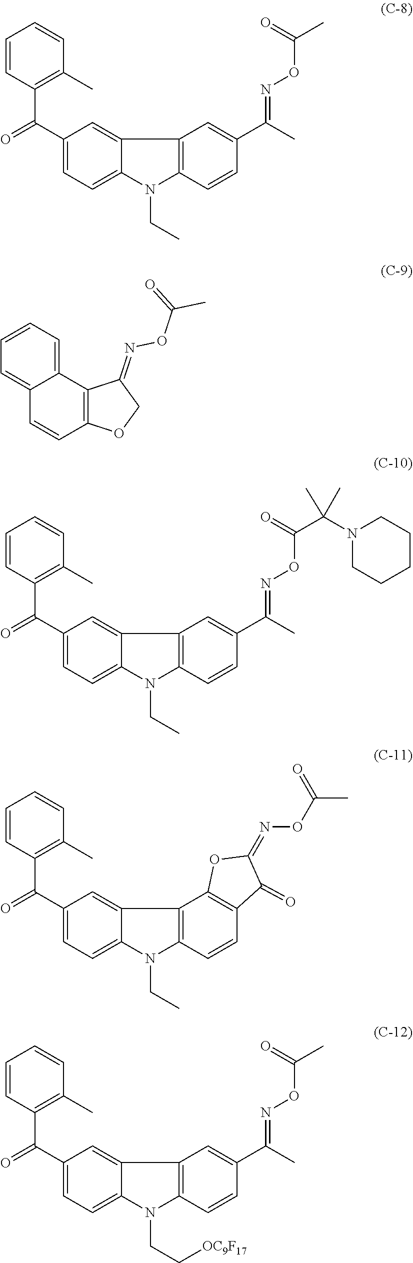

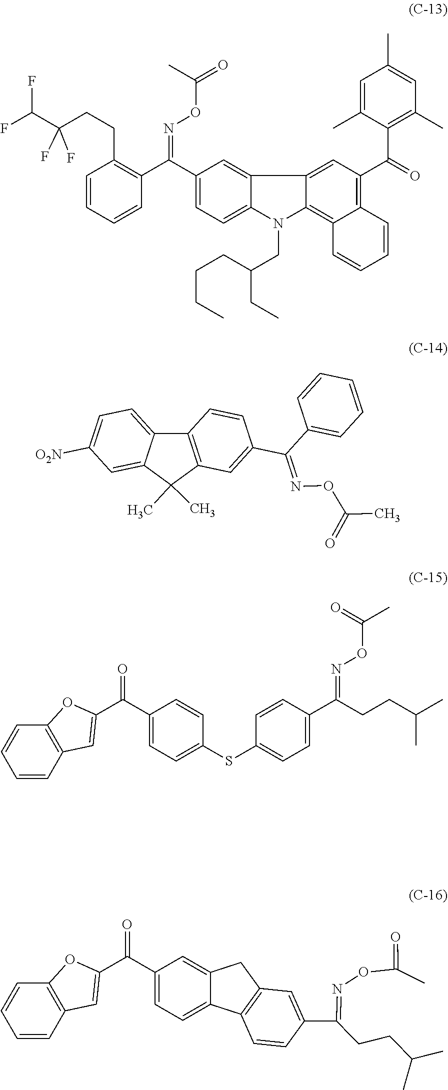 [SMILES: CCCCC(CC)Cn1c2ccc(/C(=N\OC(C)=O)c3ccccc3CCC(F)(F)C(F)F)cc2c2cc(C(=O)c3c(C)cc(C)cc3C)c3ccccc3c21 ; CC(=O)O/N=C(\c1ccccc1)c1ccc2c(c1)C(C)(C)c1cc([N+](=O)[O-])ccc1-2 ; CC(=O)O/N=C(\CCC(C)C)c1ccc(Sc2ccc(C(=O)c3cc4ccccc4o3)cc2)cc1 ; CC(=O)O/N=C(\CCC(C)C)c1ccc2c(c1)Cc1cc(C(=O)c3cc4ccccc4o3)ccc1-2]

The oxime compound is preferably a compound having a maximal absorption wavelength in a wavelength range of 350 to 500 nm and more preferably a compound having a maximal absorption wavelength in a wavelength range of 360 to 480 nm. In addition, from the viewpoint of sensitivity, a molar absorption coefficient of the oxime compound at a wavelength of 365 nm or 405 nm is preferably high, more preferably 1000 to 300000, still more preferably 2000 to 300000, and particularly preferably 5000 to 200000. The molar absorption coefficient of a compound can be measured using a known method. For example, the molar absorption coefficient is preferably measured by a spectrophotometer (Cary-5 spectrophotometer, manufactured by Varian Medical Systems, Inc.) using an ethyl acetate solvent at a concentration of 0.01 g/L.

As the photopolymerization initiator, a bifunctional or tri- or higher functional photoradical polymerization initiator may be used. By using such a photoradical polymerization initiator, two or more radicals are generated from one molecule of the photoradical polymerization initiator, and as a result, good sensitivity is obtained. In addition, in a case of using a compound having an asymmetric structure, crystallinity is reduced so that solubility in a solvent or the like is improved, precipitation is to be difficult over time, and temporal stability of the coloring composition can be improved. Specific examples of the bifunctional or tri- or higher functional photoradical polymerization initiator include dimers of the oxime compounds described in JP2010-527339A, JP2011-524436A, WO2015/004565A, paragraph Nos. 0407 to 0412 of JP2016-532675A, and paragraph Nos. 0039 to 0055 of WO2017/033680A; the compound (E) and compound (G) described in JP2013-522445A; Cmpd 1 to 7 described in WO2016/034963A; the oxime ester photoinitiators described in paragraph No. 0007 of JP2017-523465A; the photoinitiators described in paragraph Nos. 0020 to 0033 of JP2017-167399A; the photopolymerization initiator (A) described in paragraph Nos. 0017 to 0026 of JP2017-151342A; and the oxime ester photoinitiators described in JP6469669B.

A content of the polymerization initiator in the total solid content of the coloring composition is preferably 0.1% to 20% by mass. The lower limit is preferably 0.5% by mass or more and more preferably 1% by mass or more. The upper limit is preferably 10% by mass or less, more preferably 7.5% by mass or less, and still more preferably 5% by mass or less. The polymerization initiator may be used singly or in a combination of two or more kinds thereof. In a case where two or more kinds thereof are used in combination, the total thereof is preferably within the above-described range.

In addition, a content of the photopolymerization initiator in the total solid content of the coloring composition is preferably 0.1% to 20% by mass. The lower limit is preferably 0.5% by mass or more and more preferably 1% by mass or more. The upper limit is preferably 10% by mass or less, more preferably 7.5% by mass or less, and still more preferably 5% by mass or less. The photopolymerization initiator may be used singly or in a combination of two or more kinds thereof. In a case where two or more kinds thereof are used in combination, the total thereof is preferably within the above-described range.

<<Compound having Cyclic Ether Group>>

The coloring composition according to the embodiment of the present invention can contain a compound having a cyclic ether group. Examples of the cyclic ether group include an epoxy group and an oxetanyl group. It is preferable that the compound having a cyclic ether group is a compound having an epoxy group (hereinafter, also referred to as an “epoxy compound”). Examples of the epoxy compound include a compound having one or more epoxy groups in one molecule, and a compound having two or more epoxy groups in one molecule is preferable. The epoxy compound is preferably a compound having 1 to 100 epoxy groups in one molecule. The upper limit of the number of epoxy groups included in the epoxy compound may be, for example, 10 or less or 5 or less. The lower limit of the epoxy group included in the epoxy compound is preferably 2 or more. As the epoxy compound, the compounds described in paragraph Nos. 0034 to 0036 of JP2013-011869A, paragraph Nos. 0147 to 0156 of JP2014-043556A, and paragraph Nos. 0085 to 0092 of JP2014-089408A, and the compounds described in JP2017-179172A can also be used. The contents of the publications are incorporated herein by reference.

The epoxy compound may be a low-molecular-weight compound (for example, having a molecular weight of less than 2000, and further, a molecular weight of less than 1000) or a high-molecular-weight compound (macromolecule) (for example, having a molecular weight of 1000 or more, and in a case of a polymer, having a weight-average molecular weight of 1000 or more). A weight-average molecular weight of the compound having an epoxy group is preferably 200 to 100000 and more preferably 500 to 50000. The upper limit of the weight-average molecular weight is still more preferably 10000 or less, particularly preferably 5000 or less, and even more preferably 3000 or less.

Examples of a commercially available product of the compound having a cyclic ether group include EHPE 3150 (manufactured by Daicel Corporation), EPICLON N-695 (manufactured by DIC Corporation), and MARPROOF G-0150M, G-0105SA, G-0130SP, G-0250SP, G-1005S, G-1005SA, G-1010S, G-2050M, G-01100, and G-01758 (all of which are manufactured by NOF Corporation., an epoxy group-containing polymer).

In a case where the coloring composition according to the embodiment of the present invention contains a compound having a cyclic ether group, the content of the compound having a cyclic ether group in the total solid content of the coloring composition is preferably 0.1% to 20% by mass. The lower limit is, for example, more preferably 0.5% by mass or more and still more preferably 1% by mass or more. The upper limit is, for example, more preferably 15% by mass or less and still more preferably 10% by mass or less. The compound having a cyclic ether group may be used singly or in a combination of two or more kinds thereof. In a case where two or more kinds thereof are used, the total amount thereof is preferably within the above-described range.

<<Silane Coupling Agent>>

The coloring composition according to the embodiment of the present invention can contain a silane coupling agent. According to this aspect, adhesiveness of a film to be obtained with a support can be further improved. In the present specification, the silane coupling agent means a silane compound having a hydrolyzable group and other functional groups. In addition, the hydrolyzable group refers to a substituent directly linked to a silicon atom and capable of forming a siloxane bond due to at least one of a hydrolysis reaction or a condensation reaction. Examples of the hydrolyzable group include a halogen atom, an alkoxy group, and an acyloxy group, and an alkoxy group is preferable. That is, it is preferable that the silane coupling agent is a compound having an alkoxysilyl group. Examples of the functional group other than the hydrolyzable group include a vinyl group, a (meth)allyl group, a (meth)acryloyl group, a mercapto group, an epoxy group, an oxetanyl group, an amino group, a ureide group, a sulfide group, an isocyanate group, and a phenyl group, and an amino group, a (meth)acryloyl group, or an epoxy group is preferable. Specific examples of the silane coupling agent include N-β-aminoethyl-γ-aminopropyl methyldimethoxysilane (trade name: KBM-602, manufactured by Shin-Etsu Chemical Co., Ltd.), N-β-aminoethyl-γ-aminopropyl trimethoxysilane (trade name: KBM-603, manufactured by Shin-Etsu Chemical Co Ltd.), N-β-aminoethyl-γ-aminopropyl triethoxysilane (trade name: KBE-602, manufactured by Shin-Etsu Chemical Co., Ltd.), γ-aminopropyl trimethoxysilane (trade name: KBM-903, manufactured by Shin-Etsu Chemical Co., Ltd.), γ-aminopropyl triethoxysilane (trade name: KBE-903, manufactured by Shin-Etsu Chemical Co., Ltd.), 3-methacryloxypropylmethyl dimethoxysilane (trade name: KBM-502, manufactured by Shin-Etsu Chemical Co., Ltd.), and 3-methacryloxypropyl trimethoxysilane (trade name: KBM-503, manufactured by Shin-Etsu Chemical Co., Ltd.). In addition, specific examples of the silane coupling agent include the compounds described in paragraph Nos. 0018 to 0036 of JP2009-288703A and the compounds described in paragraph Nos. 0056 to 0066 of JP2009-242604A, the contents of which are incorporated herein by reference.

A content of the silane coupling agent in the total solid content of the coloring composition is preferably 0.1% to 5% by mass. The upper limit is more preferably 3% by mass or less and still more preferably 2% by mass or less. The lower limit is more preferably 0.5% by mass or more and still more preferably 1% by mass or more. The silane coupling agent may be used singly or in a combination of two or more kinds thereof. In a case where two or more kinds thereof are used, the total amount thereof is preferably within the above-described range.

<<Surfactant>>

The coloring composition according to the embodiment of the present invention can contain a surfactant. As the surfactant, various surfactants such as a fluorine-based surfactant, a nonionic surfactant, a cationic surfactant, an anionic surfactant, and a silicon-based surfactant can be used. Examples of the surfactant include surfactants described in paragraph Nos. 0238 to 0245 of WO2015/166779A, the contents of which are incorporated herein by reference.

It is preferable that the surfactant is a fluorine-based surfactant. By containing a fluorine-based surfactant in the coloring composition, liquid characteristics (particularly, fluidity) are further improved, and liquid saving properties can be further improved. In addition, it is possible to form a film with a small thickness unevenness.

A fluorine content in the fluorine-based surfactant is suitably 3% to 40% by mass, and more preferably 5% to 30% by mass and particularly preferably 7% to 25% by mass. The fluorine-based surfactant in which the fluorine content is within the above-described range is effective in terms of the evenness of the thickness of the coating film or liquid saving properties and the solubility of the surfactant in the coloring composition is also good.

Examples of the fluorine-based surfactant include surfactants described in paragraph Nos. 0060 to 0064 of JP2014-041318A (paragraph Nos. 0060 to 0064 of the corresponding WO2014/017669A) and the like, and surfactants described in paragraph Nos. 0117 to 0132 of JP2011-132503A, the contents of which are incorporated herein by reference. Examples of a commercially available product of the fluorine-based surfactant include: MEGAFACE F171, F172, F173, F176, F177, F141, F142, F143, F144, R30, F437, F475, F479, F482, F554, F780, EXP, and MFS-330 (all of which are manufactured by DIC Corporation); FLUORAD FC430, FC431, and FC171 (all of which are manufactured by Sumitomo 3M Ltd.); SURFLON S-382, SC-101, SC-103, SC-104, SC-105, SC-1068, SC-381, SC-383, S-393, and KH-40 (all of which are manufactured by Asahi Glass Co., Ltd.); and POLYFOX PF636, PF656, PF6320, PF6520, and PF7002 (all of which are manufactured by OMNOVA Solutions Inc.).

In addition, as the fluorine-based surfactant, an acrylic compound, which has a molecular structure having a functional group containing a fluorine atom and in which, by applying heat to the molecular structure, the functional group containing a fluorine atom is broken to volatilize a fluorine atom, can also be suitably used. Examples of such a fluorine-based surfactant include MEGAFACE DS series manufactured by DIC Corporation (The Chemical Daily, February 22, 2016; Nikkei Business Daily, Feb. 23, 2016) such as MEGAFACE DS-21.

In addition, it is also preferable that a polymer of a fluorine atom-containing vinyl ether compound having a fluorinated alkyl group or a fluorinated alkylene ether group, and a hydrophilic vinyl ether compound is used as the fluorine-based surfactant. Examples of such a fluorine-based surfactant include fluorine-based surfactants described in JP2016-216602A, the contents of which are incorporated herein by reference.

A block polymer can also be used as the fluorine-based surfactant. As the fluorine-based surfactant, a fluorine-containing polymer compound including a repeating unit derived from a (meth)acrylate compound having a fluorine atom and a repeating unit derived from a (meth)acrylate compound having 2 or more (preferably 5 or more) alkyleneoxy groups (preferably ethyleneoxy groups or propyleneoxy groups) can also be preferably used. In addition, fluorine-containing surfactants described in paragraph Nos. 0016 to 0037 of JP2010-032698A, or the following compounds are also exemplified as the fluorine-based surfactant used in the present invention.

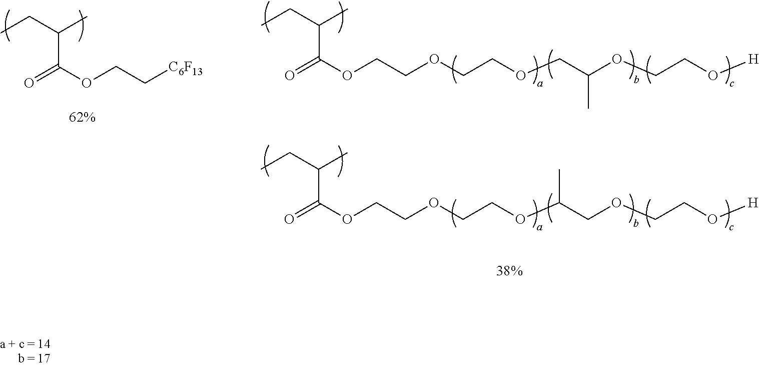

A weight-average molecular weight of the compound is preferably 3000 to 50000 and, for example, 14000. In the compound, “%” representing the proportion of a repeating unit is mol %.

In addition, as the fluorine-based surfactant, a fluorine-containing polymer having an ethylenically unsaturated bond-containing group in the side chain can be used. Specific examples thereof include compounds described in paragraph Nos. 0050 to 0090 and paragraph Nos. 0289 to 0295 of JP2010-164965A, and MEGAFACE RS-101, RS-102, RS-718K, and RS-72-K manufactured by DIC Corporation. In addition, as the fluorine-based surfactant, compounds described in paragraph Nos. 0015 to 0158 of JP2015-117327A can also be used.

A content of the surfactant in the total solid content of the coloring composition is preferably 0.001% by mass to 5.0% by mass and more preferably 0.005% to 3.0% by mass. The surfactant may be used singly or in a combination of two or more kinds thereof. In a case where two or more kinds thereof are used, the total amount thereof is preferably within the above-described range.

<<Ultraviolet Absorber>>

The coloring composition according to the embodiment of the present invention can contain an ultraviolet absorber. As the ultraviolet absorber, a conjugated diene compound, an aminodiene compound, a salicylate compound, a benzophenone compound, a benzotriazole compound, an acrylonitrile compound, a hydroxyphenyltriazine compound, an indole compound, a triazine compound, or the like can be used. Examples of such a compound include compounds described in paragraph Nos. 0038 to 0052 of JP2009-217221A, paragraph Nos. 0052 to 0072 of JP2012-208374A, paragraph Nos. 0317 to 0334 of JP2013-068814A, and paragraph Nos. 0061 to 0080 of JP2016-162946A, the contents of which are incorporated herein by reference. Examples of a commercially available product of the ultraviolet absorber include UV-503 (manufactured by Daito Chemical Co., Ltd). In addition, examples of the benzotriazole compound include MYUA series manufactured by Miyoshi Oil & Fat Co., Ltd. (The Chemical Daily, February 1, 2016). In addition, as the ultraviolet absorber, compounds described in paragraph Nos. 0049 to 0059 of JP6268967B can also be used. A content of the ultraviolet absorber in the total solid content of the coloring composition is preferably 0.01% to 10% by mass and more preferably 0.01% to 5% by mass. The ultraviolet absorber may be used singly or in a combination of two or more kinds thereof. In a case where two or more kinds thereof are used, the total amount thereof is preferably within the above-described range.

<<Antioxidant>>

The coloring composition according to the embodiment of the present invention can contain an antioxidant. Examples of the antioxidant include a phenol compound, a phosphite ester compound, and a thioether compound. As the phenol compound, any phenol compound which is known as a phenol-based antioxidant can be used. Preferred examples of the phenol compound include a hindered phenol compound. A compound having a substituent at a site (ortho position) adjacent to a phenolic hydroxy group is preferable. As the substituent, a substituted or unsubstituted alkyl group having 1 to 22 carbon atoms is preferable. In addition, as the antioxidant, a compound having a phenol group and a phosphite ester group in the same molecule is also preferable. In addition, as the antioxidant, a phosphorus antioxidant can also be suitably used. In addition, as the antioxidant, compounds described in KR10-2019-0059371A can also be used. A content of the antioxidant in the total solid content of the coloring composition is preferably 0.01% to 20% by mass and more preferably 0.3% to 15% by mass. The antioxidant may be used singly or in a combination of two or more kinds thereof. In a case of using two or more kinds thereof, the total amount thereof is preferably within the above-described range.

<<Polymerization Inhibitor>>

The coloring composition according to the embodiment of the present invention can contain a polymerization inhibitor. Examples of the polymerization inhibitor include hydroquinone, p-methoxyphenol, di-tert-butyl-p-cresol, pyrogallol, tert-butyl catechol, benzoquinone, 4,4′-thiobis(3-methyl-6-tert-butylphenol), 2,2′-methylenebis(4-methyl-6-t-butylphenol), and an N-nitrosophenylhydroxylamine salt (an ammonium salt, a cerous salt, or the like). Among these, p-methoxyphenol is preferable. A content of the polymerization inhibitor in the total solid content of the coloring composition is preferably 0.0001% to 5% by mass. The polymerization inhibitor may be used singly or in a combination of two or more kinds thereof. In a case of two or more kinds thereof, the total amount thereof is preferably within the above-described range.

<<Solvent>>

The coloring composition according to the embodiment of the present invention can contain a solvent. As the solvent, an organic solvent is preferable. Basically, the organic solvent is not particularly limited as long as it satisfies solubility of the respective components and coating properties of the coloring composition. Examples of the organic solvent include an ester-based solvent, a ketone-based solvent, an alcohol-based solvent, an amide-based solvent, an ether-based solvent, and a hydrocarbon-based solvent. The details of the organic solvent can be found in paragraph No. 0223 of WO2015/166779A, the content of which is incorporated herein by reference. In addition, an ester-based solvent in which a cyclic alkyl group is substituted or a ketone-based solvent in which a cyclic alkyl group is substituted can also be preferably used. Specific examples of the organic solvent include polyethylene glycol monomethyl ether, dichloromethane, methyl 3-ethoxypropionate, ethyl 3-ethoxypropionate, ethyl cellosolve acetate, ethyl lactate, diethylene glycol dimethyl ether, butyl acetate, methyl 3-methoxypropionate, 2-heptanone, cyclohexanone, cyclohexyl acetate, cyclopentanone, ethyl carbitol acetate, butyl carbitol acetate, propylene glycol monomethyl ether, propylene glycol monomethyl ether acetate, 3-methoxy-N,N-dimethylpropanamide, and 3-butoxy-N,N-dimethylpropanamide. In this case, it may be preferable that the content of aromatic hydrocarbons (such as benzene, toluene, xylene, and ethylbenzene) as the organic solvent is low (for example, 50 parts per million (ppm) by mass or less, 10 ppm by mass or less, or 1 ppm by mass or less with respect to the total amount of the organic solvent) in consideration of environmental aspects and the like.

A content of the solvent in the coloring composition is preferably 10% to 95% by mass. The upper limit is preferably 92.5% by mass or less and more preferably 90% by mass or less. From the viewpoint of coating properties, the lower limit is preferably 20% by mass or more, more preferably 30% by mass or more, still more preferably 50% by mass or more, and even more preferably 75% by mass or more.

<<Other Components>>

In the present invention, optionally, the coloring composition may further contain a sensitizer, a curing accelerator, a filler, a thermal curing accelerator, a plasticizer, and other auxiliary agents (for example, conductive particles, a filling agent, an antifoaming agent, a flame retardant, a leveling agent, a peeling accelerator, an aromatic chemical, a surface tension adjuster, or a chain transfer agent). By appropriately containing these components, properties such as film properties can be adjusted. The details of the components can be found in, for example, paragraph No. 0183 of JP2012-003225A (corresponding to paragraph No. 0237 of US2013/0034812A) and paragraph Nos. 0101 to 0104 and 0107 to 0109 of JP2008-250074A, the contents of which are incorporated herein by reference. In addition, optionally, the coloring composition according to the embodiment of the present invention may contain a potential antioxidant. Examples of the potential antioxidant include a compound in which a site functioning as an antioxidant is protected by a protective group, and the protective group is eliminated by heating the compound at 100° C. to 250° C. or heating the compound at 80° C. to 200° C. in the presence of an acid or base catalyst so that the compound functions as an antioxidant. Examples of the potential antioxidant include compounds described in WO2014/021023A, WO2017/030005A, and JP2017-008219A. Examples of a commercially available product of the potential antioxidant include ADEKA ARKLS GPA-5001 (manufactured by ADEKA Corporation).

<Storage Container>

A storage container for the coloring composition is not particularly limited, and a known storage container can be used. In addition, as the storage container, it is also preferable to use a multilayer bottle having an interior wall constituted with six layers from six kinds of resins or a bottle having a 7-layer structure from 6 kinds of resins for the purpose of suppressing infiltration of impurities into raw materials or coloring compositions. Examples of such a container include the containers described in JP2015-123351A. In addition, for the purpose of preventing metal elution from the container interior wall, improving storage stability of the coloring composition, and suppressing the alteration of components, it is also preferable that the container interior wall is formed of glass, stainless steel, or the like.

<Method of Preparing Coloring Composition>

The coloring composition according to the embodiment of the present invention can be prepared by mixing the above-described components with each other. In the preparation of the coloring composition, all the components may be dissolved and/or dispersed at the same time in a solvent to prepare the coloring composition, or the respective components may be appropriately left in two or more solutions or dispersion liquids and mixed to prepare the coloring composition upon use (during coating), as desired.

In addition, in the preparation of the coloring composition, a process of dispersing the pigment is preferably included. In the process for dispersing the pigment, examples of a mechanical force which is used for dispersing the pigment include compression, pressing, impact, shear, and cavitation. Specific examples of these processes include a beads mill, a sand mill, a roll mill, a ball mill, a paint shaker, a microfluidizer, a high-speed impeller, a sand grinder, a flow jet mixer, high-pressure wet atomization, and ultrasonic dispersion. In addition, in the pulverization of the pigment in a sand mill (beads mill), it is preferable to perform a treatment under the condition for increasing a pulverization efficiency by using beads having small diameters; increasing the filling rate of the beads; or the like. Incidentally, it is preferable to remove coarse particles by filtration, centrifugation, or the like after the pulverization treatment. In addition, as the process and the dispersing machine for dispersing the pigment, the process and the dispersing machine described in “Dispersion Technology Comprehension, published by Johokiko Co., Ltd., Jul. 15, 2005”, “Actual comprehensive data collection on dispersion technology and industrial application centered on suspension (solid/liquid dispersion system), published by Publication Department, Management Development Center, Oct. 10, 1978”, and paragraph No. 0022 of JP2015-157893A can be suitably used. In addition, in the process for dispersing the pigment, a refining treatment of particles in a salt milling step may be performed. With regard to the materials, equipment, treatment conditions, and the like used in the salt milling step, reference can be made to, for example, the description in JP2015-194521A and JP2012-046629A.

During the preparation of the coloring composition, it is preferable that the coloring composition is filtered through a filter, for example, in order to remove foreign matter or to reduce defects. As the filter, any filters that have been used in the related art for filtration use and the like may be used without particular limitation. Examples of a material of the filter include: a fluororesin such as polytetrafluoroethylene (PTFE) and polyvinylidene fluoride (PVDF); a polyamide resin such as nylon (for example, nylon-6 or nylon-6,6); and a polyolefin resin (including a polyolefin resin having a high density and an ultrahigh molecular weight) such as polyethylene or polypropylene (PP). Among these materials, polypropylene (including a high-density polypropylene) and nylon are preferable.

The pore size of the filter is preferably 0.01 to 7.0 μm, more preferably 0.01 to 3.0 μm, and still more preferably 0.05 to 0.5 μm. In a case where the pore size of the filter is within the above-described range, fine foreign matters can be reliably removed. With regard to the pore size value of the filter, reference can be made to a nominal value of filter manufacturers. As the filter, various filters provided by Nihon Pall Corporation (DFA4201NXEY, DFA4201NAEY, DFA4201J006P, and the like), Toyo Roshi Kaisha., Ltd., Nihon Entegris K.K. (formerly Nippon Microlith Co., Ltd.), Kitz Micro Filter Corporation, and the like can be used.

In addition, it is preferable that a fibrous filter material is used as the filter. Examples of the fibrous filter material include a polypropylene fiber, a nylon fiber, and a glass fiber. Examples of a commercially available product include SBP type series (SBP008 and the like), TPR type series (TPR002, TPR005, and the like), or SHPX type series (SHPX003 and the like), all manufactured by Roki Techno Co., Ltd.

In a case of using a filter, different filters (for example, a first filter, a second filter, and the like) may be combined. In this case, the filtration with each of the filters may be performed once or may be performed twice or more times. In addition, filters having different pore sizes within the above-described range may be combined. In addition, the filtration through the first filter may be performed with only a dispersion liquid, the other components may be mixed therewith, and then the filtration through the second filter may be performed.

<Film>

A film according to an embodiment of the present invention is a film obtained from the above-described coloring composition according to the embodiment of the present invention. A thickness of the film according to the embodiment of the present invention can be adjusted according to the purpose. For example, the film thickness is preferably 20 μm or less, more preferably 10 μm or less, and still more preferably 5 μm or less. The lower limit of the film thickness is preferably 0.1 μm or more, more preferably 0.2 μm or more, and still more preferably 0.3 μm or more.

The film according to the embodiment of the present invention can be used a color filter, an infrared transmitting filter, and the like. The film according to the embodiment of the present invention can be preferably used as a colored pixel of a color filter, and more preferably used as a red pixel of a color filter. In addition, the film according to the embodiment of the present invention can also be as a red color filter.

<Method for Producing Film>

The film according to the embodiment of the present invention can be manufactured through a step of applying the coloring composition according to the embodiment of the present invention on a support. The method for manufacturing the film according to the embodiment of the present invention preferably further includes a step of forming a pattern (pixel). Examples of a method for forming the pattern (pixel) include a photolithography method and a dry etching method, and a photolithography method is preferable.

(Photolithography Method)

First, a case of forming the pattern by a photolithography method to manufacture a film will be described. Pattern formation by a photolithography method preferably includes a step of forming a coloring composition layer on a support using the coloring composition according to the embodiment of the present invention, a step of exposing the coloring composition layer in a patterned manner, and a step of removing a non-exposed portion of the coloring composition layer by development to form a pattern (pixel). A step (pre-baking step) of baking the coloring composition layer and a step (post-baking step) of baking the developed pattern (pixel) may be provided, optionally.

In the step of forming a coloring composition layer, the coloring composition layer is formed on a support, using the coloring composition. The support is not particularly limited, and can be appropriately selected depending on applications. Examples thereof include a glass substrate and a silicon substrate, and a silicon substrate is preferable. In addition, a charge coupled device (CCD), a complementary metal-oxide semiconductor (CMOS), a transparent conductive film, or the like may be formed on the silicon substrate. In some cases, a black matrix for isolating each pixel is formed on the silicon substrate. In addition, a base layer may be provided on the silicon substrate so as to improve adhesiveness to an upper layer, prevent the diffusion of materials, or planarize the surface of the substrate. A surface contact angle of the base layer is preferably 20° to 70° in a case of being measured with diiodomethane. In addition, the surface contact angle of the base layer is preferably 30° to 80° in a case of being measured with water. In a case where the surface contact angle of the base layer is within the above-described range, coating property of the coloring composition is good. The surface contact angle of the base layer can be adjusted by, for example, adding a surfactant.

As a method of applying the coloring composition, a known method can be used. Examples thereof include a dropping method (drop casting); a slit coating method; a spray method; a roll coating method; a spin coating method (spin coating); a cast coating method; a slit and spin method; a pre-wet method (for example, a method described in JP2009-145395A), various printing methods such as an ink jet (for example, on-demand type, piezo type, thermal type), a discharge printing such as nozzle jet, a flexo printing, a screen printing, a gravure printing, a reverse offset printing, and a metal mask printing; a transfer method using molds and the like; and a nanoimprinting method. A method for applying the ink jet is not particularly limited, and examples thereof include a method described in “Extension of Use of Ink Jet -Infinite Possibilities in Patent-” (February, 2005, S. B. Research Co., Ltd.) (particularly pp. 115 to 133) and methods described in JP2003-262716A, JP2003-185831A, JP2003-261827A, JP2012-126830A, and JP2006-169325A. In addition, with regard to the method for applying the coloring composition, reference can be made to the description in WO2017/030174A and WO2017/018419A, the contents of which are incorporated herein by reference.

The coloring composition layer formed on the support may be dried (pre-baked). In a case of producing a film by a low-temperature process, pre-baking may not be performed. In a case of performing the pre-baking, the pre-baking temperature is preferably 150° C. or lower, more preferably 120° C. or lower, and still more preferably 110° C. or lower. The lower limit may be set to, for example, 50° C. or higher, or to 80° C. or higher. The pre-baking time is preferably 10 to 300 seconds, more preferably 40 to 250 seconds, and still more preferably 80 to 220 seconds. The pre-baking can be performed using a hot plate, an oven, or the like.

Next, the coloring composition layer is exposed in a patterned manner (exposing step). For example, the coloring composition layer can be exposed in a patterned manner using a stepper exposure device or a scanner exposure device through a mask having a predetermined mask pattern. Thus, the exposed portion can be cured.

Examples of the radiation (light) which can be used during the exposure include g-rays and i-rays. In addition, light (preferably light having a wavelength of 180 to 300 nm) having a wavelength of 300 nm or less can be used. Examples of the light having a wavelength of 300 nm or less include KrF-rays (wavelength: 248 nm) and ArF-rays (wavelength: 193 nm), and KrF-rays (wavelength: 248 nm) are preferable. In addition, a long-wave light source of 300 nm or more can be used.

In addition, in a case of exposure, the photosensitive composition layer may be irradiated with light continuously to expose the photosensitive composition layer, or the photosensitive composition layer may be irradiated with light in a pulse to expose the photosensitive composition layer (pulse exposure). The pulse exposure refers to an exposing method in which light irradiation and resting are repeatedly performed in a short cycle (for example, millisecond-level or less).

The irradiation amount (exposure amount) is, for example, preferably 0.03 to 2.5 J/cm² and more preferably 0.05 to 1.0 J/cm². The oxygen concentration during the exposure can be appropriately selected, and the exposure may also be performed, for example, in a low-oxygen atmosphere having an oxygen concentration of 19% by volume or less (for example, 15% by volume, 5% by volume, and substantially oxygen-free) or in a high-oxygen atmosphere having an oxygen concentration of more than 21% by volume (for example, 22% by volume, 30% by volume, and 50% by volume), in addition to an atmospheric air. In addition, the exposure illuminance can be appropriately set, and can be usually selected from a range of 1000 W/m² to 100000 W/m² (for example, 5000 W/m², 15000 W/m², or 35000 W/m²). Appropriate conditions of each of the oxygen concentration and the exposure illuminance may be combined, and for example, a combination of the oxygen concentration of 10% by volume and the illuminance of 10000 W/m², a combination of the oxygen concentration of 35% by volume and the illuminance of 20000 W/m², or the like is available.

Next, the non-exposed portion of the coloring composition layer is removed by development to form a pattern (pixel). The non-exposed portion of the coloring composition layer can be removed by development using a developer. Thus, the coloring composition layer of the non-exposed portion in the exposing step is eluted into the developer, and as a result, only a photocured portion remains. The temperature of the developer is preferably, for example, 20° C. to 30° C. The development time is preferably 20 to 180 seconds. In addition, in order to improve residue removing properties, a step of removing the developer by shaking off per 60 seconds and supplying a fresh developer may be repeated multiple times.

Examples of the developer include an organic solvent and an alkali developer, and an alkali developer is preferably used. As the alkali developer, an alkaline aqueous solution (alkali developer) in which an alkali agent is diluted with pure water is preferable. Examples of the alkali agent include organic alkaline compounds such as ammonia, ethylamine, diethylamine, dimethylethanolamine, diglycol amine, di ethanolamine, hydroxyamine, ethylenediamine, tetramethylammonium hydroxide, tetraethylammonium hydroxide, tetrapropylammonium hydroxide, tetrabutylammonium hydroxide, ethyltrimethylammonium hydroxide, benzyltrimethylammonium hydroxide, dimethylbis(2-hydroxyethyl)ammonium hydroxide, choline, pyrrole, piperidine, and 1,8-diazabicyclo[5.4.0]-7-undecene, and inorganic alkaline compounds such as sodium hydroxide, potassium hydroxide, sodium carbonate, sodium hydrogen carbonate, sodium silicate, and sodium metasilicate. In consideration of environmental aspects and safety aspects, the alkali agent is preferably a compound having a high molecular weight. The concentration of the alkali agent in the alkaline aqueous solution is preferably 0.001% to 10% by mass and more preferably 0.01% to 1% by mass. In addition, the developer may further contain a surfactant. Examples of the surfactant include the surfactants described above, and the surfactant is preferably a nonionic surfactant. From the viewpoint of transportation, storage, and the like, the developer may be first produced as a concentrated solution and then diluted to a concentration required upon the use. The dilution ratio is not particularly limited, and can be set to, for example, a range of 1.5 to 100 times. In addition, it is also preferable to wash (rinse) with pure water after development. In addition, it is preferable that the rinsing is performed by supplying a rinsing liquid to the coloring composition layer after development while rotating the support on which the coloring composition layer after development is formed. In addition, it is preferable that the rinsing is performed by moving a nozzle discharging the rinsing liquid from a center of the support to a peripheral edge of the support. In this case, in the movement of the nozzle from the center of the support to the peripheral edge of the support, the nozzle may be moved while gradually decreasing the moving speed of the nozzle. By performing rinsing in this manner, in-plane variation of rinsing can be suppressed. In addition, the same effect can be obtained by gradually decreasing the rotating speed of the support while moving the nozzle from the center of the support to the peripheral edge of the support.

After the development, it is preferable to carry out an additional exposure treatment or a heating treatment (post-baking) after carrying out drying. The additional exposure treatment or the post-baking is a curing treatment after development in order to complete curing. The heating temperature in the post-baking is preferably, for example, 100° C. to 240° C. and more preferably 200° C. to 240° C. The film after development is post-baked continuously or batchwise using a heating unit such as a hot plate, a convection oven (hot air circulation dryer), and a high-frequency heater under the above-described conditions. In a case of performing the additional exposure treatment, light used for the exposure is preferably light having a wavelength of 400 nm or less. In addition, the additional exposure treatment may be carried out by the method described in KR10-2017-0122130A.

In this way, the pixel can be formed. A film thickness of the formed pixel can be adjusted according to the purpose. For example, the film thickness is preferably 10 μm or less, more preferably 5 μm or less, still more preferably 1 μm or less, and even more preferably 0.5 μm or less. The lower limit of the film thickness is preferably 0.1 μm or more, more preferably 0.2 μm or more, and still more preferably 0.3 μm or more.

A line width (size) of the formed pixel can be adjusted according to the purpose. For example, the line width is preferably 5 μm or less, more preferably 3 μm or less, and still more preferably 1.5 μm or less. The lower limit of the line width is preferably 0.1 μm or more, more preferably 0.2 μm or more, and still more preferably 0.3 μm or more.

(Dry Etching Method)

Pattern formation by a dry etching method preferably includes a step of forming a coloring composition layer on a support using the coloring composition according to the embodiment of the present invention and curing the entire coloring composition layer to form a cured composition layer, a step of forming a photoresist layer on the cured composition layer, a step of exposing the photoresist layer in a patterned manner and then developing the photoresist layer to form a resist pattern, and a step of dry-etching the cured composition layer through this resist pattern as a mask and using an etching gas. It is preferable that pre-baking treatment is further performed in order to form the photoresist layer. In particular, as the forming process of the photoresist layer, it is desirable that a heating treatment after exposure and a heating treatment after development (post-baking treatment) are performed. The details of the pattern formation by the dry etching method can be found in paragraph Nos. 0010 to 0067 of JP2013-064993A, the content of which is incorporated herein by reference.

<Optical Filter>

An optical filter according to an embodiment of the present invention has the above-described film according to the embodiment of the present invention. Examples of the type of the optical filter include a color filter and an infrared transmitting filter. The color filter preferably includes the film according to the embodiment of the present invention as a colored pixel thereof, and more preferably includes the film according to the embodiment of the present invention as a red pixel.

In the optical filter, a protective layer may be provided on the surface of the film according to the embodiment of the present invention. By providing the protective layer, various functions such as oxygen shielding, low reflection, hydrophilicity/hydrophobicity, and shielding of light (ultraviolet rays, near-infrared rays, and the like) having a specific wavelength can be imparted. The thickness of the protective layer is preferably 0.01 to 10 μm and more preferably 0.1 to 5 μm. Examples of a method for forming the protective layer include a method of forming the protective layer by applying a resin composition dissolved in an organic solvent, a chemical vapor deposition method, and a method of attaching a molded resin with an adhesive. Examples of components constituting the protective layer include a (meth)acrylic resin, an ene-thiol resin, a polycarbonate resin, a polyether resin, a polyarylate resin, a polysulfone resin, a polyethersulfone resin, a polyphenylene resin, a polyarylene ether phosphine oxide resin, a polyimide resin, a polyamidoimide resin, a polyolefin resin, a cyclic olefin resin, a polyester resin, a styrene resin, a polyol resin, a polyvinylidene chloride resin, a melamine resin, a urethane resin, an aramid resin, a polyamide resin, an alkyd resin, an epoxy resin, a modified silicone resin, a fluororesin, a polyacrylonitrile resin, a cellulose resin, Si, C, W, Al₂O₃, Mo, SiO₂, and Si₂N₄, and two or more kinds of these components may be contained. For example, in a case of a protective layer for oxygen shielding, it is preferable that the protective layer contains a polyol resin, SiO₂, and Si₂N₄. In addition, in a case of a protective layer for low reflection, it is preferable that the protective layer contains a (meth)acrylic resin and a fluororesin.

In a case of forming the protective layer by applying a resin composition, as a method for applying the resin composition, a known method such as a spin coating method, a casting method, a screen printing method, and an ink jet method can be used. As the organic solvent included in the resin composition, a known organic solvent (for example, propylene glycol 1-monomethyl ether 2-acetate, cyclopentanone, ethyl lactate, and the like) can be used. In a case of forming the protective layer by a chemical vapor deposition method, as the chemical vapor deposition method, a known chemical vapor deposition method (thermochemical vapor deposition method, plasma chemical vapor deposition method, and photochemical vapor deposition method) can be used.

The protective layer may contain, as desired, an additive such as organic or inorganic fine particles, an absorber of light (for example, ultraviolet rays, near-infrared rays, and the like) having a specific wavelength, a refractive index adjusting agent, an antioxidant, an adhesive agent, and a surfactant. Examples of the organic or inorganic fine particles include polymer fine particles (for example, silicone resin fine particles, polystyrene fine particles, and melamine resin fine particles), titanium oxide, zinc oxide, zirconium oxide, indium oxide, aluminum oxide, titanium nitride, titanium oxynitride, magnesium fluoride, hollow silica, silica, calcium carbonate, and barium sulfate. As the absorber of light having a specific wavelength, a known absorber can be used. The content of these additives can be appropriately adjusted, but is preferably 0.1% to 70% by mass and still more preferably 1% to 60% by mass with respect to the total mass of the protective layer.

In addition, as the protective layer, the protective layers described in paragraph Nos. 0073 to 0092 of JP2017-151176A can also be used.

The optical filter may have a structure in which each pixel is embedded in a space partitioned in, for example, a lattice form by a partition wall.

<Solid-State Imaging Element>

A solid-state imaging element according to an embodiment of the present invention has the film according to the embodiment of the present invention. The configuration of the solid-state imaging element according to the embodiment of the present invention is not particularly limited as long as the solid-state imaging element is configured to include the film according to the embodiment of the present invention and functions as a solid-state imaging element. Examples of the configuration include the following configurations.

The solid-state imaging element is configured to have a plurality of photodiodes constituting a light receiving area of the solid-state imaging element (a charge coupled device (CCD) image sensor, a complementary metal-oxide semiconductor (CMOS) image sensor, or the like), and a transfer electrode formed of polysilicon or the like on a substrate; have a light-shielding film having openings only over the light receiving section of the photodiodes on the photodiodes and the transfer electrodes; have a device-protective film formed of silicon nitride or the like, which is formed to coat the entire surface of the light-shielding film and the light receiving section of the photodiodes, on the light-shielding film; and have a color filter on the device-protective film. Further, the solid-state imaging element may also be configured, for example, such that it has a light collecting unit (for example, a microlens, which is the same hereinafter) on a device-protective film under a color filter (a side closer to the substrate), or has a light collecting unit on a color filter. In addition, the color filter may have a structure in which each colored pixel is embedded in a space partitioned in, for example, a lattice form by a partition wall. The partition wall in this case preferably has a low refractive index for each colored pixel. Examples of an imaging device having such a structure include the devices described in JP2012-227478A, JP2014-179577A, and WO2018/043654A. In addition, as described in JP2019-211559A, an ultraviolet absorbing layer may be provided in the structure of the solid-state imaging element to improve light resistance. An imaging device including the solid-state imaging element according to the embodiment of the present invention can also be used as a vehicle camera or a surveillance camera, in addition to a digital camera or electronic apparatus (mobile phones or the like) having an imaging function.

<Image Display Device>

An image display device according to an embodiment of the present invention has the film according to the embodiment of the present invention. Examples of the image display device include a liquid crystal display device or an organic electroluminescent display device. The definitions of image display devices or the details of the respective image display devices are described in, for example, “Electronic Display Device (Akio Sasaki, Kogyo Chosakai Publishing Co., Ltd., published in 1990)”, “Display Device (Sumiaki Ibuki, Sangyo Tosho Co., Ltd.)”, and the like. In addition, the liquid crystal display device is described in, for example, “Liquid Crystal Display Technology for Next Generation (edited by Tatsuo Uchida, Kogyo Chosakai Publishing Co., Ltd., published in 1994)”. The liquid crystal display device to which the present invention can be applied is not particularly limited, and can be applied to, for example, liquid crystal display devices employing various systems described in the “Liquid Crystal Display Technology for Next Generation”.

### Examples

Hereinafter, the present invention will be described in more detail with reference to Examples. The materials, the amounts of materials to be used, the proportions, the treatment details, the treatment procedure, or the like shown in the examples below may be modified appropriately as long as the modifications do not depart from the spirit of the present invention. Therefore, the scope of the present invention is not limited to the specific examples shown below.

<Evaluation of Resin>

(Weight-Average Molecular Weight (Mw))

A weight-average molecular weight (Mw) of a resin was measured by gel permeation chromatography (GPC) equipped with a differential refractometer (RI) detector. HLC-8220GPC (manufactured by Tosoh Corporation) was used as a device. Two separation columns were connected in series, and “TSK-GEL SUPER HZM-N” was connected in two to both separation columns. The oven temperature was set to 40° C., tetrahydrofuran was used as an eluent, and the measurement was performed at a flow rate of 0.35 ml/min. A sample was dissolved in a solvent consisting of 1% by mass of the above-described eluent and injected in 20 μL. All molecular weights are values in terms of polystyrene.

(Acid Value of Resin)

The acid value of a resin was a value expressed in terms of solid contents of an acid value (mgKOH/g) measured according to a potentiometric titration method of JIS K 0070.

<Production of Miniaturization Pigment>

100 parts by mass of a pigment shown in the table below, 1200 parts by mass of sodium chloride, and 120 parts by mass of diethylene glycol were charged into a 1-gallon stainless steel kneader (manufactured by INOUE MFG., INC.) and kneaded at 60° C. for 4 hours. The obtained kneading composition was put into 3000 parts by mass of warm water and stirred for 1 hour to form a slurry, and the slurry was filtered and washed with water repeatedly to remove sodium chloride and diethylene glycol, and dried at 80° C. for 24 hours to obtain a miniaturization pigment.

TABLE 1

| Miniaturization | |
|---|---|
| pigment | Pigment as raw material |
| (PR254M) | C. I. Pigment Red 254 (red pigment) |
| | (“B-CF” manufactured by BASF SE) |
| (PR177M) | C. I. Pigment Red 177 (red pigment) |
| | (“B-CF” manufactured by BASF SE) |
| (PR264M) | Pigment A1 (red pigment) |
| (PR272M) | C. I. Pigment Red 272 (red pigment) |
| | (“Cromophtal DPP Red FP” manufactured by BASF |
| | SE) |
| (PR-1M) | Pigment A2 (red pigment) |
| (PR-2M) | Pigment A3 (red pigment) |
| (PY139M) | C. I. Pigment Yellow 139 (yellow pigment) |
| | (“Paliotol Yellow L 2146HD” manufactured by |
| | BASF SE) |
| (PY150M) | C. I. Pigment Yellow 150 (yellow pigment) |
| | (“E-4GN” manufactured by Lanxess) |
| (PY185M) | C. I. Pigment Yellow 185 (yellow pigment) |
| | (“Paliotol Yellow L 1155” manufactured by BASF |
| | SE) |
| (PY215M) | C. I. Pigment Yellow 215 (yellow pigment) |
| (PY-1M) | Quinophthalone compound described in Synthesis |
| | Example 3 of paragraph No. 0061 of JP6607427B |
| | (yellow pigment) |
| (PG63M) | C. I. Pigment Green 63 (green pigment) |
| | (“Optlion Green 8890” manufactured by |
| | TOYOCOLOR CO., LTD.) |
| (PG62M) | C. I. Pigment Green 62 (green pigment) |
| | (“Optlion Green 8880” manufactured by |
| | TOYOCOLOR CO., LTD.) |
| (PG58M) | C. I. Pigment Green 58 (green pigment) |
| | (“FASTOGEN GREEN A110” manufactured by |
| | DIC CORPORATION) |
| (PG36M) | C. I. Pigment Green 36 (green pigment) |
| | (“Green8G” manufactured by CLARIANT) |
| (PG7M) | C. I. Pigment Green 7 (green pigment) |
| | (“GreenGNX” manufactured by CLARIANT) |
| (PB15:6M) | C. I. Pigment Blue 15:6 (blue pigment) |
| | (“LIONOL BLUE ES” manufactured by |
| | TOYOCOLOR CO., LTD.) |
| (PB15:3M) | C. I. PigmentBlue 15:3 (blue pigment) |
| (PB15:4M) | C. I. PigmentBlue 15:4 (blue pigment) |
| (PB16M) | C. I. PigmentBlue 16 (blue pigment) |
| (PV23M) | C. I. Pigment Violet 23 (violet pigment) |
| | (“LIONOGEN VIOLET RL” manufactured by |
| | TOYOCOLOR CO., LTD.) |
| (PO71M) | C. I. Pigment Orange 71 (orange pigment) |
| (IR coloring agent) | Near-infrared absorber 1 |
| (PBk32) | C. I. Pigment Black 32 (perylene-based pigment) |

In the above table, the pigment A1 is a compound (C. I. Pigment Red 264) having a structure represented by Formula (X-1). The pigment A2 is a compound having a structure represented by Formula (X-2), and the pigment A3 is a compound having a structure represented by Formula (X-3). All of the pigments A1 to A3 are the pigment A having a structure represented by Formula (X1). In addition, the near-infrared absorber 1 is a compound having a structure represented by Formula (IR1).

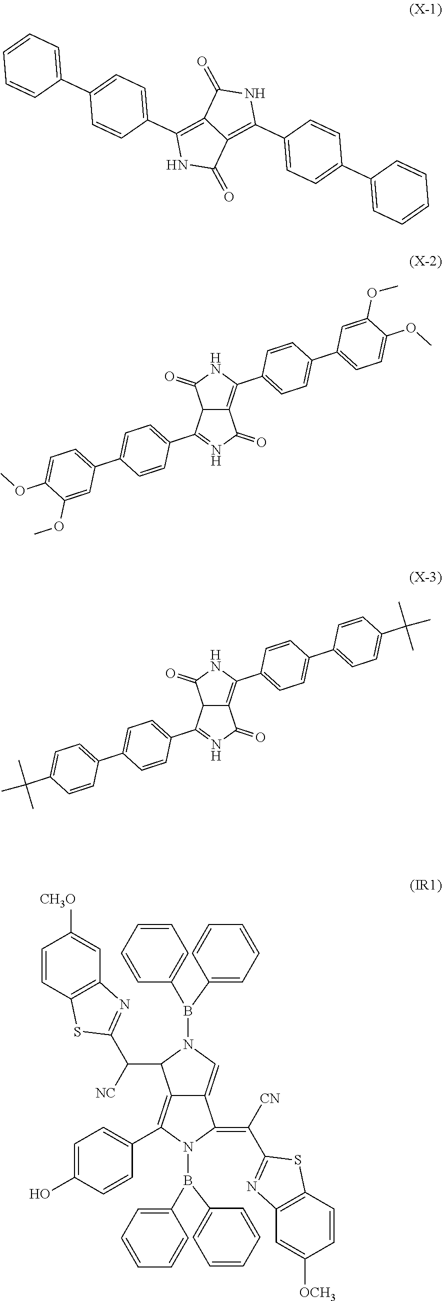

<Production of Pigment Dispersion Liquid>

Materials shown below were mixed by the parts by mass shown below, and then using zirconia beads having a diameter of 0.5 mm, the mixture was dispersed for 3 hours with an Eiger mill (“Mini Model M-250 MKII” manufactured by Eiger Japan Co., Ltd.). Thereafter, the obtained mixture was filtered through a filter having a pore size of 5.0 μm to produce a pigment dispersion liquid. In the following, the value of the blending amount of the dispersant and the resin is a value in a case of being converted to 100% of concentration of solid contents. The value of the blending amount of the solvent is a value obtained by totaling the amount of solvents included in the dispersant and the resin.

TABLE 2

| | Miniaturization | | Pigment | | | | | | | |
|---|---|---|---|---|---|---|---|---|---|---|
| Pigment | pigment | | derivative | | Dispersant | | Resin | | Solvent | |
| dispersion | | Part by | | Part by | | Part by | | Part by | | Part by |
| liquid | Type | mass | Type | mass | Type | mass | Type | mass | Type | mass |
| (RB-1) | (PR264M) | 11.0 | Derivative 1 | 0.6 | (D-2) | 1.5 | Resin 1 | 2.0 | PGMEA | 84.9 |
| (RB-2) | (PR264M) | 11.0 | Derivative 1 | 0.6 | (D-2) | 1.5 | Resin 2 | 2.0 | PGMEA | 84.9 |
| (RB-3) | (PR264M) | 11.0 | Derivative 1 | 0.6 | (D-3) | 1.5 | Resin 3 | 2.0 | PGMEA | 84.9 |
| (RB-4) | (PR264M) | 11.0 | Derivative 1 | 0.6 | (D-2) | 1.5 | Resin 4 | 2.0 | PGMEA | 84.9 |
| (RB-5) | (PR264M) | 11.0 | Derivative 1 | 0.6 | (D-1) | 1.5 | Resin 5 | 2.0 | PGMEA | 84.9 |
| (RB-6) | (PR264M) | 11.0 | Derivative 1 | 0.6 | (D-1) | 1.5 | Resin 6 | 2.0 | PGMEA | 84.9 |
| (RB-7) | (PR264M) | 11.0 | Derivative 1 | 0.6 | (D-1) | 1.5 | Resin 7 | 2.0 | PGMEA | 84.9 |
| (RB-8) | (PR264M) | 11.0 | Derivative 1 | 0.6 | (D-1) | 0.6 | Resin 1 | 2.9 | PGMEA | 84.9 |
| (RB-9) | (PR264M) | 11.0 | Derivative 1 | 0.6 | (D-3) | 2.9 | Resin 1 | 0.6 | PGMEA | 84.9 |
| (RB-10) | (PR264M) | 11.0 | Derivative 1 | 0.6 | (D-3) | 3.5 | — | — | PGMEA | 84.9 |
| (RB-11) | (PR177M) | 11.0 | Derivative 1 | 0.6 | (D-2) | 1.5 | Resin 1 | 2.0 | PGMEA | 84.9 |
| (RB-12) | (PR177M) | 11.0 | Derivative 1 | 0.6 | (D-2) | 1.5 | Resin 2 | 2.0 | PGMEA | 84.9 |
| (RB-13) | (PR177M) | 11.0 | Derivative 1 | 0.6 | (D-2) | 1.5 | Resin 3 | 2.0 | PGMEA | 84.9 |
| (RB-14) | (PR254M) | 11.0 | Derivative 1 | 0.6 | (D-1) | 1.5 | Resin 1 | 2.0 | PGMEA | 84.9 |
| (RB-15) | (PR254M) | 11.0 | Derivative 1 | 0.6 | (D-1) | 1.5 | Resin 2 | 2.0 | PGMEA | 84.9 |
| (RB-16) | (PR254M) | 11.0 | Derivative 1 | 0.6 | (D-2) | 1.5 | Resin 3 | 2.0 | PGMEA | 84.9 |
| (RB-17) | (PR272M) | 11.0 | Derivative 1 | 0.6 | (D-1) | 1.5 | Resin 1 | 2.0 | PGMEA | 84.9 |
| (RB-18) | (PR272M) | 11.0 | Derivative 1 | 0.6 | (D-1) | 1.5 | Resin 2 | 2.0 | PGMEA | 84.9 |
| (RB-19) | (PR272M) | 11.0 | Derivative 1 | 0.6 | (D-3) | 1.5 | Resin 3 | 2.0 | PGMEA | 84.9 |
| (RB-20) | (PR-1M) | 11.0 | Derivative 1 | 0.6 | (D-1) | 2.9 | Resin 1 | 0.6 | PGMEA | 84.9 |
| (RB-21) | (PR-2M) | 11.0 | Derivative 1 | 0.6 | (D-3) | 2.9 | Resin 1 | 0.6 | PGMEA | 84.9 |
| (GB-1) | (PG36M) | 11.0 | Derivative 1 | 0.6 | (D-3) | 1.5 | Resin 1 | 2.0 | PGMEA | 84.9 |
| (GB-2) | (PG36M) | 11.0 | Derivative 1 | 0.6 | (D-3) | 1.5 | Resin 2 | 2.0 | PGMEA | 84.9 |
| (GB-3) | (PG36M) | 11.0 | Derivative 1 | 0.6 | (D-2) | 1.5 | Resin 3 | 2.0 | PGMEA | 84.9 |
| (GB-4) | (PG7M) | 11.0 | Derivative 1 | 0.6 | (D-2) | 1.5 | Resin 1 | 2.0 | PGMEA | 84.9 |
| (GB-5) | (PG7M) | 11.0 | Derivative 1 | 0.6 | (D-1) | 1.5 | Resin 2 | 2.0 | PGMEA | 84.9 |
| (GB-6) | (PG7M) | 11.0 | Derivative 1 | 0.6 | (D-3) | 1.5 | Resin 3 | 2.0 | PGMEA | 84.9 |
| (GB-7) | (PG58M) | 11.0 | Derivative 1 | 0.6 | (D-1) | 1.5 | Resin 1 | 2.0 | PGMEA | 84.9 |
| (GB-8) | (PG58M) | 11.0 | Derivative 1 | 0.6 | (D-3) | 1.5 | Resin 2 | 2.0 | PGMEA | 84.9 |
| (GB-9) | (PG58M) | 11.0 | Derivative 1 | 0.6 | (D-2) | 1.5 | Resin 3 | 2.0 | PGMEA | 84.9 |
| (GB-10) | (PG62M) | 11.0 | Derivative 1 | 0.6 | (D-3) | 1.5 | Resin 1 | 2.0 | PGMEA | 84.9 |
| (GB-11) | (PG62M) | 11.0 | Derivative 1 | 0.6 | (D-1) | 1.5 | Resin 2 | 2.0 | PGMEA | 84.9 |
| (GB-12) | (PG62M) | 11.0 | Derivative 1 | 0.6 | (D-2) | 1.5 | Resin 3 | 2.0 | PGMEA | 84.9 |

TABLE 3

| | Miniaturization | | Pigment | | | | | | | |
|---|---|---|---|---|---|---|---|---|---|---|
| Pigment | pigment | | derivative | | Dispersant | | Resin | | Solvent | |
| dispersion | | Part by | | Part by | | Part by | | Part by | | Part by |
| liquid | Type | mass | Type | mass | Type | mass | Type | mass | Type | mass |
| (YB-1) | (PY139M) | 11.0 | Derivative 1 | 0.6 | (D-1) | 1.5 | Resin 1 | 2.0 | PGMEA | 84.9 |
| (YB-2) | (PY139M) | 11.0 | Derivative 1 | 0.6 | (D-3) | 1.5 | Resin 2 | 2.0 | PGMEA | 84.9 |
| (YB-3) | (PY139M) | 11.0 | Derivative 1 | 0.6 | (D-1) | 1.5 | Resin 3 | 2.0 | PGMEA | 84.9 |
| (YB-4) | (PY150M) | 11.0 | Derivative 1 | 0.6 | (D-2) | 1.5 | Resin 1 | 2.0 | PGMEA | 84.9 |
| (YB-5) | (PY150M) | 11.0 | Derivative 1 | 0.6 | (D-3) | 1.5 | Resin 2 | 2.0 | PGMEA | 84.9 |
| (YB-6) | (PY150M) | 11.0 | Derivative 1 | 0.6 | (D-1) | 1.5 | Resin 3 | 2.0 | PGMEA | 84.9 |
| (YB-7) | (PY185M) | 11.0 | Derivative 1 | 0.6 | (D-2) | 1.5 | Resin 1 | 2.0 | PGMEA | 84.9 |
| (YB-8) | (PY185M) | 11.0 | Derivative 1 | 0.6 | (D-1) | 1.5 | Resin 2 | 2.0 | PGMEA | 84.9 |
| (YB-9) | (PY185M) | 11.0 | Derivative 1 | 0.6 | (D-1) | 1.5 | Resin 3 | 2.0 | PGMEA | 84.9 |
| (YB-10) | (PY215M) | 11.0 | Derivative 1 | 0.6 | (D-3) | 1.5 | Resin 1 | 2.0 | PGMEA | 84.9 |
| (YB-11) | (PY215M) | 11.0 | Derivative 1 | 0.6 | (D-3) | 1.5 | Resin 2 | 2.0 | PGMEA | 84.9 |
| (YB-12) | (PY215M) | 11.0 | Derivative 1 | 0.6 | (D-1) | 1.5 | Resin 3 | 2.0 | PGMEA | 84.9 |
| (YB-13) | (PY-1M) | 11.0 | Derivative 1 | 0.6 | (D-3) | 1.5 | Resin 1 | 2.0 | PGMEA | 84.9 |
| (YB-14) | (PY-1M) | 11.0 | Derivative 1 | 0.6 | (D-3) | 1.5 | Resin 2 | 2.0 | PGMEA | 84.9 |
| (YB-15) | (PY-1M) | 11.0 | Derivative 1 | 0.6 | (D-2) | 1.5 | Resin 3 | 2.0 | PGMEA | 84.9 |
| (BB-1) | (PB15:6M) | 11.0 | Derivative 2 | 0.6 | (D-3) | 1.5 | Resin 1 | 2.0 | PGMEA | 84.9 |
| (BB-2) | (PB15:6M) | 11.0 | Derivative 2 | 0.6 | (D-3) | 1.5 | Resin 2 | 2.0 | PGMEA | 84.9 |
| (BB-3) | (PB15:6M) | 11.0 | Derivative 2 | 0.6 | (D-3) | 1.5 | Resin 3 | 2.0 | PGMEA | 84.9 |
| (BB-4) | (PB15:3M) | 11.0 | Derivative 2 | 0.6 | (D-2) | 1.5 | Resin 1 | 2.0 | PGMEA | 84.9 |
| (BB-5) | (PB15:3M) | 11.0 | Derivative 2 | 0.6 | (D-2) | 1.5 | Resin 2 | 2.0 | PGMEA | 84.9 |
| (BB-6) | (PB15:3M) | 11.0 | Derivative 2 | 0.6 | (D-1) | 1.5 | Resin 3 | 2.0 | PGMEA | 84.9 |
| (BB-7) | (PB15:4M) | 11.0 | Derivative 2 | 0.6 | (D-3) | 1.5 | Resin 1 | 2.0 | PGMEA | 84.9 |
| (BB-8) | (PB15:4M) | 11.0 | Derivative 2 | 0.6 | (D-1) | 1.5 | Resin 2 | 2.0 | PGMEA | 84.9 |
| (BB-9) | (PB15:4M) | 11.0 | Derivative 2 | 0.6 | (D-1) | 1.5 | Resin 3 | 2.0 | PGMEA | 84.9 |
| (BB-10) | (PB16M) | 11.0 | Derivative 2 | 0.6 | (D-2) | 1.5 | Resin 1 | 2.0 | PGMEA | 84.9 |
| (BB-11) | (PB16M) | 11.0 | Derivative 2 | 0.6 | (D-2) | 1.5 | Resin 2 | 2.0 | PGMEA | 84.9 |
| (BB-12) | (PB16M) | 11.0 | Derivative 2 | 0.6 | (D-3) | 1.5 | Resin 3 | 2.0 | PGMEA | 84.9 |
| (VB-1) | (PV23M) | 11.0 | Derivative 3 | 0.6 | (D-1) | 1.5 | Resin 1 | 2.0 | PGMEA | 84.9 |
| (VB-2) | (PV23M) | 11.0 | Derivative 3 | 0.6 | (D-1) | 1.5 | Resin 2 | 2.0 | PGMEA | 84.9 |
| (VB-3) | (PV23M) | 11.0 | Derivative 3 | 0.6 | (D-2) | 1.5 | Resin 3 | 2.0 | PGMEA | 84.9 |
| (OB-1) | (PO71M) | 11.0 | Derivative 1 | 0.6 | (D-3) | 1.5 | Resin 1 | 2.0 | PGMEA | 84.9 |
| (OB-2) | (PO71M) | 11.0 | Derivative 1 | 0.6 | (D-1) | 1.5 | Resin 2 | 2.0 | PGMEA | 84.9 |
| (OB-3) | (PO71M) | 11.0 | Derivative 1 | 0.6 | (D-1) | 1.5 | Resin 3 | 2.0 | PGMEA | 84.9 |
| (KB-1) | (TiB) | 11.0 | Derivative 1 | 0.6 | (D-2) | 1.5 | Resin 1 | 2.0 | PGMEA | 84.9 |
| (KB-2) | (TiB) | 11.0 | Derivative 1 | 0.6 | (D-2) | 1.5 | Resin 2 | 2.0 | PGMEA | 84.9 |
| (KB-3) | (TiB) | 11.0 | Derivative 1 | 0.6 | (D-2) | 1.5 | Resin 3 | 2.0 | PGMEA | 84.9 |
| (KB-4) | (PBk32) | 11.0 | Derivative 1 | 0.6 | (D-3) | 1.5 | Resin 1 | 2.0 | PGMEA | 84.9 |
| (IRB-1) | (IR coloring | 11.0 | Derivative 4 | 0.6 | (D-1) | 1.5 | Resin 2 | 2.0 | PGMEA | 84.9 |
| | agent) | | | | | | | | | |
| (BB-c1) | (PB15:6M) | 11.0 | Derivative 1 | 0.6 | (D-1) | 1.5 | Resin c1 | 2.0 | PGMEA | 84.9 |
| (BB-c2) | (PB16M) | 11.0 | Derivative 1 | 0.6 | (D-2) | 1.5 | Resin c2 | 2.0 | PGMEA | 84.9 |
| (RB-c1) | (PR264M) | 11.0 | Derivative 1 | 0.6 | (D-3) | 1.5 | Resin c1 | 2.0 | PGMEA | 84.9 |
| (RB-c2) | (PR264M) | 11.0 | Derivative 1 | 0.6 | (D-2) | 1.5 | Resin c2 | 2.0 | PGMEA | 84.9 |
| (YB-c1) | (PY139M) | 11.0 | Derivative 1 | 0.6 | (D-2) | 1.5 | Resin c1 | 2.0 | PGMEA | 84.9 |
| (YB-c2) | (PY150M) | 11.0 | Derivative 1 | 0.6 | (D-3) | 1.5 | Resin c2 | 2.0 | PGMEA | 84.9 |

The dispersion liquids (RB-1) to (RB-10), (RB-20), (RB-21), (RB-c1), and (RB-c2) are a dispersion liquid including the pigment A having a structure represented by Formula (X1). That is, these dispersion liquids are a dispersion liquid including any of the pigment A1 (miniaturization pigment (PR264M)), the pigment A2 (miniaturization pigment (PR-1M)), or the pigment A3 (miniaturization pigment (PR-2M)). On the other hand, dispersion liquids other than the dispersion liquids (RB-1) to (RB-10), (RB-20), (RB-21), (RB-c1), and (RB-c2) are a dispersion liquid not including the pigment A having a structure represented by Formula (X1).

In the above tables, among the materials listed in the column of miniaturization pigment, materials other than TiB are the above-described miniaturization pigments. In addition, TiB is titanium oxynitride particles (manufactured by Mitsubishi Materials Electronic Chemicals Co., Ltd., black pigment). In addition, details of the materials indicated by the abbreviations described in the columns of the pigment derivative, the dispersant, the resin, and the solvent are as follows.

(Pigment Derivative)

Derivative 1: compound having the following structure

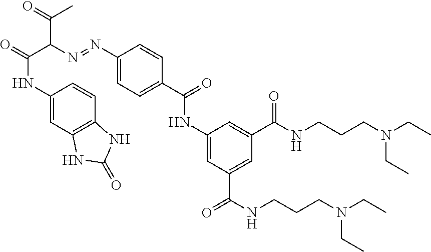 [SMILES: CCN(CC)CCCNC(=O)c1cc(NC(=O)c2ccc(/N=N/C(C(C)=O)C(=O)Nc3ccc4[nH]c(=O)[nH]c4c3)cc2)cc(C(=O)NCCCN(CC)CC)c1]

Derivative 2: compound having the following structure

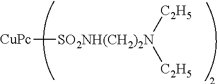

CuPc: copper phtalocyanine residue

Derivative 3: compound having the following structure

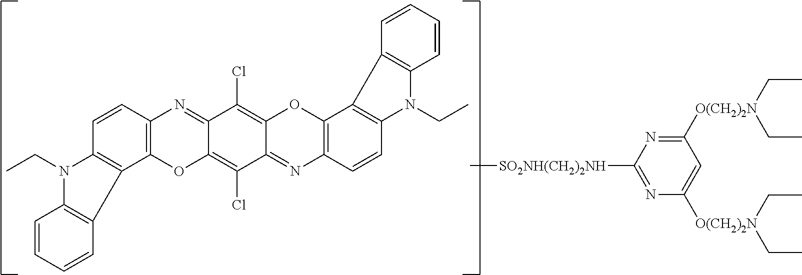

Derivative 4: compound having the following structure (in the following structural formula, Me represents a methyl group and Ph represents a phenyl group)

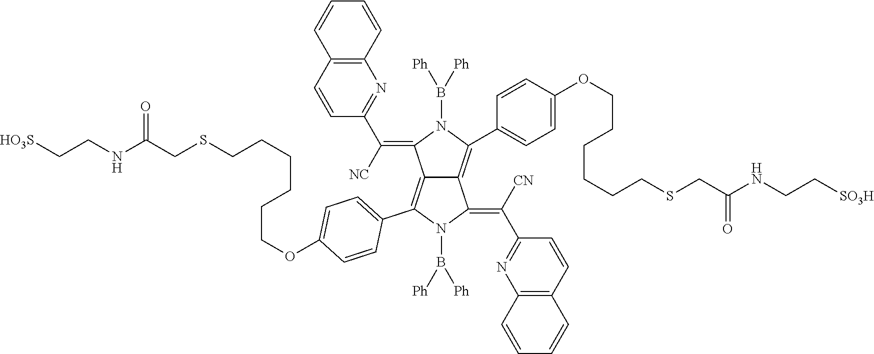 [SMILES: N#C/C(c1ccc2ccccc2n1)=c1\c2c(-c3ccc(OCCCCCCSCC(=O)NCCS(=O)(=O)O)cc3)n(B(c3ccccc3)c3ccccc3)/c(=C(/C#N)c3ccc4ccccc4n3)c2c(-c2ccc(OCCCCCCSCC(=O)NCCS(=O)(=O)O)cc2)n1B(c1ccccc1)c1ccccc1]

(Dispersant)

(D-1): resin having the following structure (a numerical value added to the main chain represents a molar ratio of a repeating unit, and a numerical value added to the side chain represents the number of repeating units; weight-average molecular weight: 20000)

(D-2): resin having the following structure (a numerical value added to the main chain represents a molar ratio of a repeating unit, and a numerical value added to the side chain represents the number of repeating units; weight-average molecular weight: 26000)

(D-3): resin having the following structure (a numerical value added to the main chain represents a molar ratio of a repeating unit, and a numerical value added to the side chain represents the number of repeating units; weight-average molecular weight: 14000)

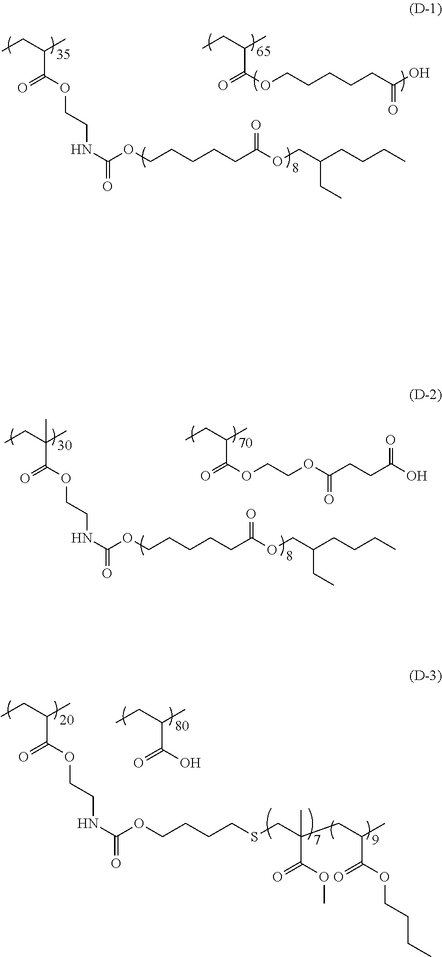

(Resin)

Resin 1: resin consisting of a constitutional unit represented by Formula (1-1), a constitutional unit represented by Formula (1-2), and a constitutional unit represented by Formula (1-3) (polyimide precursor, weight-average molecular weight: 24000)

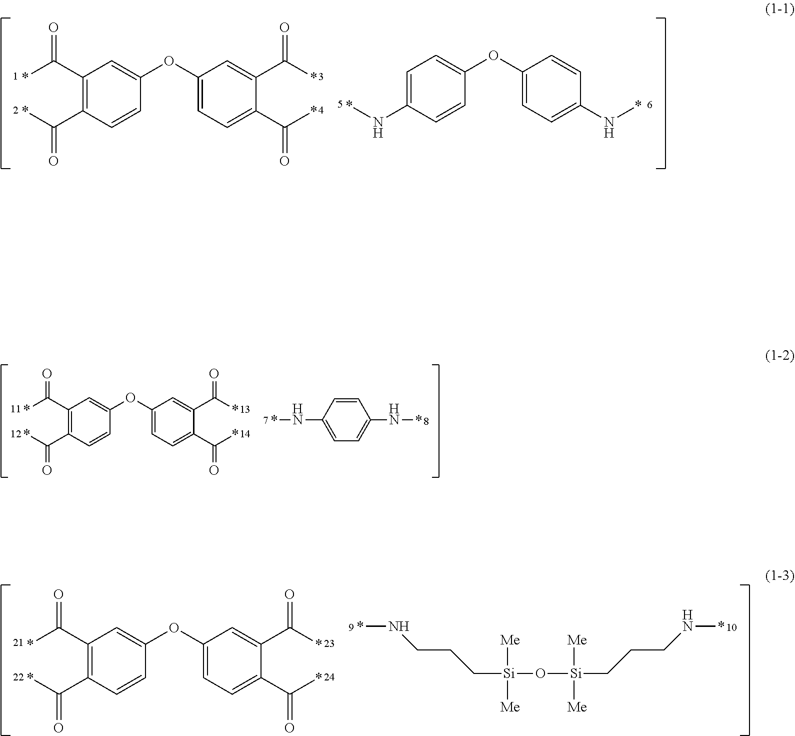

In the formulae, one of *3 and *4 is bonded to *5 to form a main chain of the polyimide precursor, and the other bonded to an OH group or —NH—(CH₂)₂—O—(C═O)—C(CH₃)═CH₂; and one of *1 and *2 is bonded to an OH group or —NH—(CH₂)₂—O—(C═O)—C(CH₃)═CH₂, and the other is bonded to any one of *6, *8, or *10 to form the main chain of the polyimide precursor;

one of *13 and *14 is bonded to *7 to form a main chain of the polyimide precursor, and the other bonded to an OH group or —NH—(CH₂)₂—O—(C═O)—C(CH₃)═CH₂; and one of *11 and *12 is bonded to an OH group or —NH—(CH₂)₂—O—(C═O)—C(CH₃)═CH₂, and the other is bonded to any one of *6, *8, or *10 to form the main chain of the polyimide precursor;

one of *23 and *24 is bonded to *9 to form a main chain of the polyimide precursor, and the other bonded to an OH group or —NH—(CH₂)₂—O—(C═O)—C(CH₃)═CH₂; and one of *21 and *22 is bonded to an OH group or —NH—(CH₂)₂—O—(C═O)—C(CH₃)═CH₂, and the other is bonded to any one of *6, *8, or *10 to form the main chain of the polyimide precursor.

Resin 2: resin having the following structure (polybenzoxazole precursor, weight-average molecular weight: 21000)

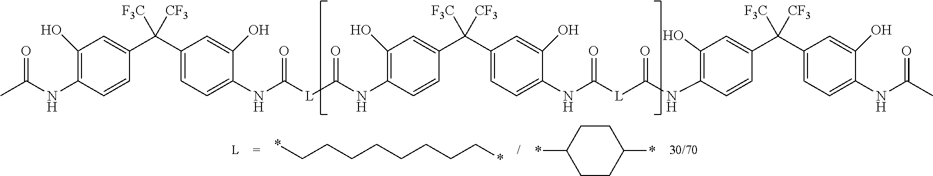

Resin 3: resin having the following structure (epoxy-modified polysiloxane resin, COMPOCERAN E103D, manufactured by Arakawa Chemical Industries, Ltd.)

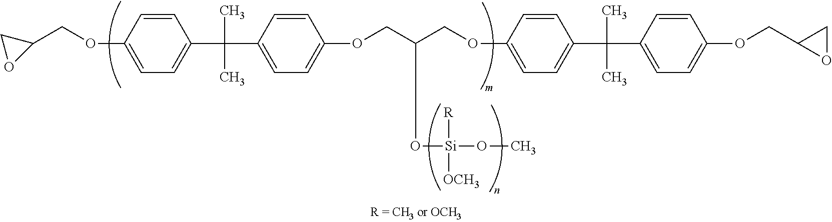

Resin c1: resin having the following structure ((meth)acrylic resin; a numerical value added to the main chain represents a molar ratio of a repeating unit; weight-average molecular weight: 12000)

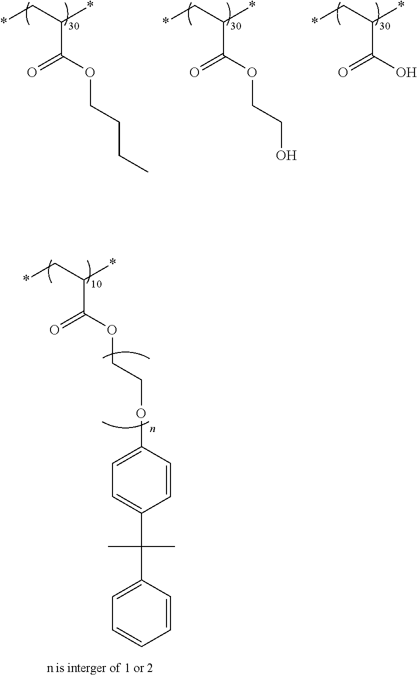

Resin c2: resin having the following structure ((meth)acrylic-maleimide copolymer; a numerical value added to the main chain represents a molar ratio of a repeating unit; weight-average molecular weight: 10000)

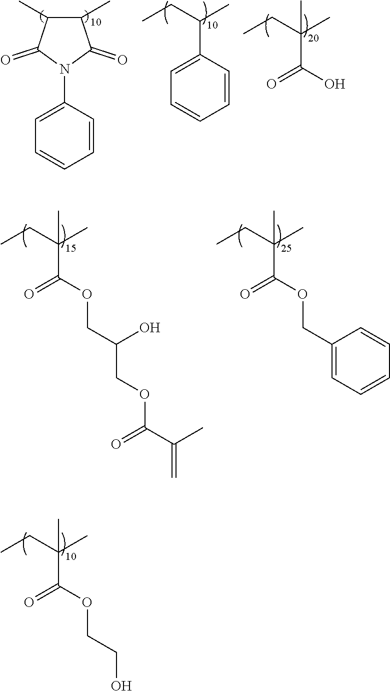

(Solvent)

PGMEA: propylene glycol monomethyl ether acetate

<Production of Coloring Composition>

Materials shown in the tables below were mixed by the parts by mass shown in the tables below, and then filtered through a filter having a pore size of 1 μm to produce a coloring composition.

TABLE 4

| | | Pigment | | Pigment | | Pigment | | Pigment | | | | | |
|---|---|---|---|---|---|---|---|---|---|---|---|---|---|
| | | dispersion | | dispersion | | dispersion | | dispersion | | | | Polymerizable | |
| | Coloring | liquid 1 | | liquid 2 | | liquid 3 | | liquid 4 | | Resin | | monomer | |
| | composi- | | Part by | | Part by | | Part by | | Part by | | Part by | | Part by |
| | tion | Type | mass | Type | mass | Type | mass | Type | mass | Type | mass | Type | mass |
| Example 1 | (RR-1) | (RB-1) | 38.2 | (YB-1) | 17.3 | | | | | Resin 2 | 3.0 | (M-1) | 0.6 |
| Example 2 | (RR-2) | (RB-5) | 38.2 | (YB-5) | 17.3 | | | | | Resin 6 | 3.0 | (M-1) | 0.6 |
| Example 3 | (RR-3) | (RB-2) | 38.2 | (YB-7) | 17.3 | | | | | Resin 6 | 3.0 | (M-1) | 0.6 |
| Example 4 | (RR-3) | (RB-2) | 38.2 | (YB-7) | 17.3 | | | | | Resin 6 | 3.0 | (M-1) | 0.6 |
| Example 5 | (RR-3) | (RB-2) | 38.2 | (YB-7) | 17.3 | | | | | Resin 6 | 3.0 | (M-1) | 0.6 |
| Example 6 | (RR-3) | (RB-2) | 38.2 | (YB-7) | 17.3 | | | | | Resin 6 | 3.0 | (M-1) | 0.6 |
| Example 7 | (RR-3) | (RB-2) | 38.2 | (YB-7) | 17.3 | | | | | Resin 6 | 3.0 | (M-1) | 0.6 |
| Example 8 | (RR-4) | (RB-20) | 38.2 | (YB-7) | 17.3 | | | | | Resin 6 | 3.0 | (M-1) | 0.6 |
| Example 9 | (RR-5) | (RB-21) | 38.2 | (YB-7) | 17.3 | | | | | Resin 1 | 3.0 | (M-1) | 0.6 |
| Example 10 | (RR-6) | (RB-3) | 55.8 | (RB-11) | 25.8 | | | | | Resin 3 | 4.6 | (M-1) | 4.1 |
| Example 11 | (RR-7) | (RB-4) | 55.8 | (RB-13) | 25.8 | | | | | Resin 1 | 4.6 | (M-1) | 4.1 |
| Example 12 | (RR-8) | (RB-3) | 55.8 | (RB-16) | 25.8 | | | | | Resin 5 | 4.6 | (M-1) | 4.1 |
| Example 13 | (RR-9) | (RB-1) | 20.2 | (YB-2) | 18.0 | (YB-4) | 17.3 | | | Resin 7 | 3.0 | (M-1) | 0.6 |
| Example 14 | (RR-10) | (RR-2) | 20.2 | (YB-6) | 18.0 | (YB-9) | 17.3 | | | Resin 5 | 3.0 | (M-1) | 0.6 |
| Example 15 | (RR-11) | (RB-4) | 20.2 | (YB-11) | 18.0 | (YB-15) | 17.3 | | | Resin 3 | 3.0 | (M-1) | 0.6 |
| Example 16 | (RR-12) | (RB-3) | 22.8 | (RB-21) | 15.4 | (YB-3) | 17.3 | | | Resin 5 | 3.0 | (M-1) | 0.6 |
| Example 17 | (RR-13) | (RB-2) | 22.8 | (RB-12) | 15.4 | (YB-12) | 17.3 | | | Resin 3 | 3.0 | (M-1) | 0.6 |
| Example 18 | (RR-14) | (RB-3) | 22.8 | (RB-13) | 15.4 | (YB-8) | 17.3 | | | Resin 5 | 3.0 | (M-1) | 0.6 |
| Example 19 | (RR-15) | (RB-2) | 22.8 | (RB-18) | 15.4 | (YB-4) | 17.3 | | | Resin 5 | 3.0 | (M-1) | 0.6 |
| Example 20 | (RR-16) | (RB-3) | 22.8 | (OB-1) | 15.4 | (YB-12) | 17.3 | | | Resin 2 | 3.0 | (M-1) | 0.6 |
| Example 21 | (RR-17) | (RB-2) | 22.8 | (RB-18) | 4.4 | (OB-2) | 11.0 | (YB-12) | 17.3 | Resin 3 | 3.0 | (M-1) | 0.6 |
| Example 22 | (KR-1) | (RB-7) | 31.8 | (BB-1) | 20.9 | (YB-12) | 4.5 | | | Resin 7 | 6.6 | (M-1) | 1.6 |
| Example 23 | (KR-2) | (RB-6) | 42.9 | (BB-5) | 28.2 | (YB-12) | 6.1 | | | Resin 1 | 4.9 | (M-1) | 1.2 |
| Example 24 | (KR-3) | (RB-2) | 49.3 | (BB-10) | 32.4 | | | | | Resin 3 | 4.3 | (M-1) | 1.0 |
| Example 25 | (KR-4) | (RB-5) | 31.8 | (BB-11) | 20.9 | (YB-13) | 4.5 | | | Resin 1 | 6.6 | (M-1) | 1.6 |

TABLE 5

| | | Photopolymerization | | Ultraviolet | | | | | | | |
|---|---|---|---|---|---|---|---|---|---|---|---|
| | Coloring | initiator | | absorber | | Additive | | Surfactant | | Solvent | |
| | composi- | | Part by | | Part by | | Part by | | Part by | | Part by |
| | tion | Type | mass | Type | mass | Type | mass | Type | mass | Type | mass |
| Example 1 | (RR-1) | (1-1) | 0.3 | (U-1) | 0.4 | (F-1) | 0.4 | (S-1) | 4.2 | PGMEA | 35.6 |
| Example 2 | (RR-2) | (1-1) | 0.3 | (U-1) | 0.4 | (F-1) | 0.4 | (S-1) | 4.2 | PGMEA | 35.6 |
| Example 3 | (RR-3) | (1-1) | 0.3 | (U-1) | 0.4 | (F-1) | 0.4 | (S-1) | 4.2 | PGMEA | 35.6 |
| Example 4 | (RR-3) | (1-5) | 0.3 | (U-1) | 0.4 | (F-1) | 0.4 | (S-1) | 4.2 | PGMEA | 35.6 |
| Example 5 | (RR-3) | (1-6) | 0.3 | (U-1) | 0.4 | (F-1) | 0.4 | (S-1) | 4.2 | PGMEA | 35.6 |
| Example 6 | (RR-3) | (1-7) | 0.3 | (U-1) | 0.4 | (F-1) | 0.4 | (S-1) | 4.2 | PGMEA | 35.6 |
| Example 7 | (RR-3) | (1-8) | 0.3 | (U-1) | 0.4 | (F-1) | 0.4 | (S-1) | 4.2 | PGMEA | 35.6 |
| Example 8 | (RR-4) | (1-1) | 0.3 | (U-1) | 0.4 | | | (S-1) | 4.2 | PGMEA | 36.0 |
| Example 9 | (RR-5) | (1-1) | 0.3 | (U-1) | 0.4 | | | (S-1) | 4.2 | PGMEA | 36.0 |
| Example 10 | (RR-6) | (1-1) | 0.2 | (U-1) | 0.4 | | | (S-1) | 4.2 | PGMEA | 4.9 |
| Example 11 | (RR-7) | (1-1) | 0.2 | (U-1) | 0.4 | | | (S-1) | 4.2 | PGMEA | 4.9 |
| Example 12 | (RR-8) | (1-1) | 0.2 | | | (F-1) | 0.4 | (S-1) | 4.2 | PGMEA | 4.9 |
| Example 13 | (RR-9) | (1-1) | 0.3 | | | (F-1) | 0.4 | (S-1) | 4.2 | PGMEA | 36.0 |
| Example 14 | (RR-10) | (1-1) | 0.3 | (U-1) | 0.4 | (F-1) | 0.4 | (S-1) | 4.2 | PGMEA | 35.6 |
| Example 15 | (RR-11) | (1-1) | 0.3 | (U-1) | 0.4 | (F-1) | 0.4 | (S-1) | 4.2 | PGMEA | 35.6 |
| Example 16 | (RE-12) | (1-1) | 0.3 | (U-1) | 0.4 | (F-1) | 0.4 | (S-1) | 4.2 | PGMEA | 35.6 |
| Example 17 | (RR-13) | (1-1) | 0.3 | (U-1) | 0.4 | (F-1) | 0.4 | (S-1) | 4.2 | PGMEA | 35.6 |
| Example 18 | (RR-14) | (1-1) | 0.3 | (U-1) | 0.4 | | | (S-1) | 4.2 | PGMEA | 36.0 |
| Example 19 | (RR-15) | (1-1) | 0.3 | (U-1) | 0.4 | | | (S-1) | 4.2 | PGMEA | 36.0 |
| Example 20 | (RR-16) | (1-1) | 0.3 | (U-1) | 0.4 | | | (S-1) | 4.2 | PGMEA | 36.0 |
| Example 21 | (RR-17) | (1-1) | 0.3 | | | (F-1) | 0.4 | (S-1) | 4.2 | PGMEA | 36.0 |
| Example 22 | (KR-1) | (1-1) | 0.5 | (U-1) | 0.4 | | | (S-1) | 4.2 | PGMEA | 29.5 |
| Example 23 | (KR-2) | (1-1) | 0.4 | (U-1) | 0.4 | | | (S-1) | 4.2 | PGMEA | 11.7 |
| Example 24 | (KR-3) | (1-1) | 0.3 | (U-1) | 0.4 | (F-1) | 0.4 | (S-1) | 4.2 | PGMEA | 7.7 |
| Example 25 | (KR-4) | (1-1) | 0.5 | | | (F-1) | 0.4 | (S-1) | 4.2 | PGMEA | 29.5 |

TABLE 6

| | | Pigment | | Pigment | | Pigment | | Pigment | | | | | |
|---|---|---|---|---|---|---|---|---|---|---|---|---|---|
| | | dispersion | | dispersion | | dispersion | | dispersion | | | | Polymerizable | |
| | Coloring | liquid 1 | | liquid 2 | | liquid 3 | | liquid 4 | | Resin | | monomer | |
| | composi- | | Part by | | Part by | | Part by | | Part by | | Part by | | Part by |
| | tion | Type | mass | Type | mass | Type | mass | Type | mass | Type | mass | Type | mass |
| Example 26 | (KR-5) | (RB-4) | 31.8 | (BB-12) | 20.9 | (YB-14) | 4.5 | | | Resin 7 | 6.6 | (M-1) | 1.6 |
| Example 27 | (KR-6) | (RB-5) | 31.8 | (BB-7) | 20.9 | (YB-15) | 4.5 | | | Resin 1 | 6.6 | (M-1) | 1.6 |
| Example 28 | (KR-7) | (RB-2) | 31.8 | (BB-2) | 16.4 | (BB-4) | 4.5 | (YB-11) | 4.5 | Resin 5 | 6.6 | (M-1) | 1.6 |
| Example 29 | (KR-8) | (RB-9) | 31.8 | (BB-3) | 20.9 | (YB-12) | 4.5 | | | Resin 2 | 6.6 | (M-2)/ | 0.8/0.8 |
| | | | | | | | | | | | | (M-3) | |
| Example 30 | (KR-9) | (RB-5) | 31.8 | (BB-6) | 20.9 | (YB-12) | 4.5 | | | Resin 4 | 6.6 | (M-2)/ | 0.8/0.8 |
| | | | | | | | | | | | | (M-3) | |
| Example 31 | (KR-10) | (RB-6) | 31.8 | (BB-2) | 20.9 | (YB-12) | 4.5 | | | Resin 7 | 6.6 | (M-1) | 1.6 |
| Example 32 | (KR-11) | (RB-3) | 42.9 | (BB-4) | 28.2 | (YB-12) | 6.1 | | | Resin 5 | 4.9 | (M-1) | 1.2 |
| Example 33 | (KR-12) | (RB-10) | 49.3 | (BB-10) | 32.4 | | | | | Resin 2 | 4.3 | (M-1) | 1.0 |
| Example 34 | (KR-13) | (RB-6) | 31.8 | (BB-11) | 20.9 | (YB-13) | 4.5 | | | Resin 1 | 6.6 | (M-1) | 1.6 |
| Example 35 | (KR-14) | (RB-7) | 31.8 | (BB-12) | 20.9 | (YB-14) | 4.5 | | | Resin 2 | 6.6 | (M-1) | 1.6 |
| Example 36 | (KR-15) | (RB-4) | 31.8 | (GB-7) | 20.9 | (YB-15) | 4.5 | | | Resin 2 | 6.6 | (M-1) | 1.6 |
| Example 37 | (KR-16) | (RB-8) | 31.8 | (GB-1) | 16.4 | (GB-5) | 4.5 | (YB-10) | 4.5 | Resin 5 | 6.6 | (M-1) | 1.6 |
| Example 38 | (KR-17) | (RB-4) | 31.8 | (GB-3) | 20.9 | (YB-12) | 4.5 | | | Resin 7 | 6.6 | (M-2)/ | 0.8/0.8 |
| | | | | | | | | | | | | (M-3) | |
| Example 39 | (KR-18) | (RB-1) | 31.8 | (GB-8) | 20.9 | (YB-12) | 4.5 | | | Resin 1 | 6.6 | (M-2)/ | 0.8/0.8 |
| | | | | | | | | | | | | (M-3) | |
| Example 40 | (KR-19) | (RB-9) | 31.8 | (BB-8) | 16.4 | (GB-9) | 4.5 | (YB-11) | 4.5 | Resin 2 | 6.6 | (M-1) | 1.6 |
| Example 41 | (KR-20) | (RB-6) | 31.8 | (BB-9) | 16.4 | (GB-6) | 4.5 | (YB-12) | 4.5 | Resin 2 | 6.6 | (M-1) | 1.6 |
| Example 42 | (KR-21) | (RB-5) | 6.0 | (KB-1) | 30.0 | (VB-1) | 8.0 | (OB-1) | 6.0 | Resin 4 | 0.5 | (M-1) | 2.0 |
| Example 43 | (KR-22) | (RB-3) | 6.0 | (KB-2) | 30.0 | (VB-2) | 8.0 | (OB-2) | 6.0 | Resin 7 | 0.5 | (M-1) | 2.0 |
| Example 44 | (KR-23) | (RB-2) | 6.0 | (KB-3) | 30.0 | (VB-3) | 8.0 | (OB-3) | 6.0 | Resin 5 | 0.5 | (M-1) | 2.0 |
| Example 45 | (KR-24) | (RB-2) | 6.0 | (KB-4) | 30.0 | (VB-3) | 8.0 | (OB-3) | 6.0 | Resin 5 | 0.5 | (M-1) | 2.0 |
| Example 46 | (KR-25) | (RB-2) | 20.0 | (BB-3) | 22.0 | (IRB-1) | 8.0 | | | Resin 5 | 0.5 | (M-1) | 2.0 |
| Comparative | (RR-c1) | (RB-c1) | 38.2 | (YB-c1) | 17.3 | | | | | Resin c1 | 3.0 | (M-1) | 0.6 |
| Example 1 | | | | | | | | | | | | | |
| Comparative | (RR-c2) | (RB-c2) | 38.2 | (YB-c2) | 17.3 | | | | | Resin c1 | 3.0 | (M-1) | 0.6 |
| Example 2 | | | | | | | | | | | | | |
| Comparative | (RR-c3) | (RB-c1) | 38.2 | (YB-c2) | 17.3 | | | | | Resin c2 | 3.0 | (M-1) | 0.6 |
| Example 3 | | | | | | | | | | | | | |
| Comparative | (RR-c4) | (RB-15) | 38.2 | (YB-1) | 17.3 | | | | | Resin 1 | 3.0 | (M-1) | 0.6 |
| Example 4 | | | | | | | | | | | | | |
| Comparative | (KR-c1) | (RB-c1) | 31.8 | (BB-c1) | 20.9 | (YB-c1) | 4.5 | | | Resin c2 | 6.6 | (M-1) | 1.6 |
| Example 5 | | | | | | | | | | | | | |
| Comparative | (KR-c2) | (RB-c2) | 31.8 | (BB-c1) | 20.9 | (YB-c2) | 4.5 | | | Resin c1 | 6.6 | (M-1) | 1.6 |
| Example 6 | | | | | | | | | | | | | |
| Comparative | (KR-c3) | (RB-c2) | 31.8 | (BB-c2) | 20.9 | (YB-c1) | 4.5 | | | Resin c1 | 6.6 | (M-1) | 1.6 |
| Example 7 | | | | | | | | | | | | | |

TABLE 7

| | | Photopolymerization | | Ultraviolet | | | | | | | |
|---|---|---|---|---|---|---|---|---|---|---|---|
| | Coloring | initiator | | absorber | | Additive | | Surfactant | | Solvent | |
| | composi- | | Part by | | Part by | | Part by | | Part by | | Part by |
| | tion | Type | mass | Type | mass | Type | mass | Type | mass | Type | mass |
| Example 26 | (KR-5) | (1-1) | 0.5 | | | (F-1) | 0.4 | (S-1) | 4.2 | PGMEA | 29.5 |
| Example 27 | (KR-6) | (1-1) | 0.5 | | | (F-1) | 0.4 | (S-1) | 4.2 | PGMEA | 29.5 |
| Example 28 | (KR-7) | (1-1) | 0.5 | | | (F-1) | 0.4 | (S-1) | 4.2 | PGMEA | 29.5 |
| Example 29 | (KR-8) | (1-1)/(1-2) | 0.25/0.25 | | | (F-1) | 0.4 | (S-1) | 4.2 | PGMEA | 29.5 |
| Example 30 | (KR-9) | (1-1)/(1-3)/ | 0.2/0.2/ | | | (F-1) | 0.4 | (S-1) | 4.2 | PGMEA | 29.5 |
| | | (1-4) | 0.1 | | | | | | | | |
| Example 31 | (KR-10) | (1-1) | 0.5 | | | (F-1) | 0.4 | (S-1) | 4.2 | PGMEA | 29.5 |
| Example 32 | (KR-11) | (1-1) | 0.4 | (U-1) | 0.4 | (F-1) | 0.4 | (S-1) | 4.2 | PGMEA | 11.3 |
| Example 33 | (KR-12) | (1-1) | 0.3 | (U-1) | 0.4 | | | (S-1) | 4.2 | PGMEA | 8.1 |
| Example 34 | (KR-13) | (1-1) | 0.5 | (U-1) | 0.4 | | | (S-1) | 4.2 | PGMEA | 29.3 |
| Example 35 | (KR-14) | (1-1) | 0.5 | | | | | (S-1) | 4.2 | PGMEA | 29.9 |
| Example 36 | (KR-15) | (1-1) | 0.5 | | | | | (S-1) | 4.2 | PGMEA | 29.9 |
| Example 37 | (KR-16) | (1-1) | 0.5 | | | | | (S-1) | 4.2 | PGMEA | 29.9 |
| Example 38 | (KR-17) | (1-1)/(1-2) | 0.25/0.25 | | | | | (S-1) | 4.2 | PGMEA | 29.9 |
| Example 39 | (KR-18) | (1-1)/(1-3)/ | 0.2/0.2/ | | | | | (S-1) | 4.2 | PGMEA | 29.9 |
| | | (1-4) | 0.1 | | | | | | | | |
| Example 40 | (KR-19) | (1-1) | 0.5 | | | | | (S-1) | 4.2 | PGMEA | 29.9 |
| Example 41 | (KR-20) | (1-1) | 0.5 | | | | | (S-1) | 4.2 | PGMEA | 29.9 |
| Example 42 | (KR-21) | (1-1) | 0.6 | | | | | (S-1) | 4.2 | PGMEA | 42.7 |
| Example 43 | (KR-22) | (1-1) | 0.6 | | | | | (S-1) | 4.2 | PGMEA | 42.7 |
| Example 44 | (KR-23) | (1-1) | 0.6 | | | | | (S-1) | 4.2 | PGMEA | 42.7 |
| Example 45 | (KR-24) | (1-1) | 0.6 | | | | | (S-1) | 4.2 | PGMEA | 42.7 |
| Example 46 | (KR-25) | (1-1) | 0.6 | | | | | (S-1) | 4.2 | PGMEA | 42.7 |
| Comparative | (RR-c1) | (1-1) | 0.3 | (U-1) | 0.4 | | | (S-1) | 4.2 | PGMEA | |
| Example 1 | | | | | | | | | | | |
| Comparative | (RR-c2) | (1-1) | 0.3 | (U-1) | 0.4 | | | (S-1) | 4.2 | PGMEA | 36.0 |
| Example 2 | | | | | | | | | | | |
| Comparative | (RR-c3) | (1-1) | 0.3 | (U-1) | 0.4 | (F-1) | 0.4 | (S-1) | 4.2 | PGMEA | 33.6 |
| Example 3 | | | | | | | | | | | |
| Comparative | (RR-c4) | (1-1) | 0.3 | (U-1) | 0.4 | (F-1) | 0.4 | (S-1) | 4.2 | PGMEA | 35.6 |
| Example 4 | | | | | | | | | | | |
| Comparative | (KR-c1) | (1-1) | 0.5 | | | | | (S-1) | 4.2 | PGMEA | 29.9 |
| Example 5 | | | | | | | | | | | |
| Comparative | (KR-c2) | (1-1) | 0.5 | (U-1) | 0.4 | (F-1) | 0.4 | (S-1) | 4.2 | PGMEA | 29.1 |
| Example 6 | | | | | | | | | | | |
| Comparative | (KR-c3) | (1-1) | 0.5 | | | (F-1) | 0.4 | (S-1) | 4.2 | PGMEA | 29.5 |
| Example 7 | | | | | | | | | | | |

In the above tables, details of the materials shown by abbreviations other than the pigment dispersion liquid are as follows.

(Resin)

Resins 1 to 3, c1, c2: resins 1 to 3, c1, and c2 described above

Resin 4: resin consisting of a constitutional unit represented by Formula (4-1) and a constitutional unit represented by Formula (4-2) (polyimide precursor, weight-average molecular weight: 18000)

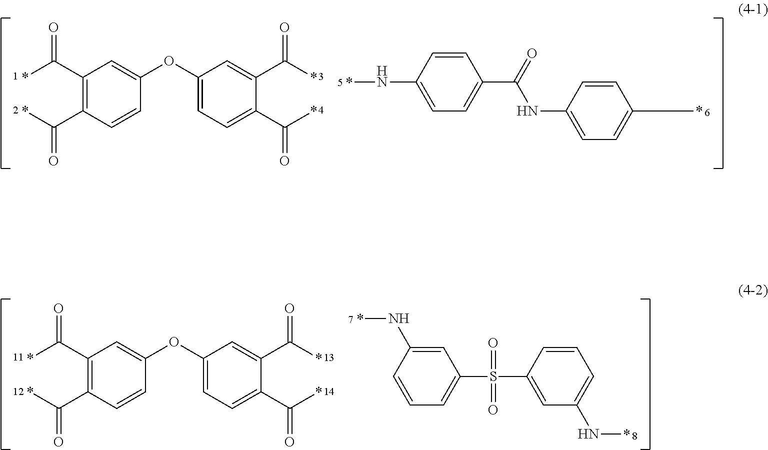

In the formulae, one of *3 and *4 is bonded to *5 to form a main chain of the polyimide precursor, and the other bonded to an OH group to form a carboxyl group; and one of *1 and *2 is bonded to an OH group to form a carboxyl group, and the other is bonded to any one of *6 or *8 to form the main chain of the polyimide precursor;

one of *13 and *14 is bonded to *7 to form a main chain of the polyimide precursor, and the other bonded to an OH group to form a carboxyl group; and one of *11 and *12 is bonded to an OH group to form a carboxyl group, and the other is bonded to any one of *6 or *8 to form the main chain of the polyimide precursor.

Resin 5: resin consisting of a constitutional unit represented by Formula (5-1) and a constitutional unit represented by Formula (5-2) (polyimide precursor, weight-average molecular weight: 20000)

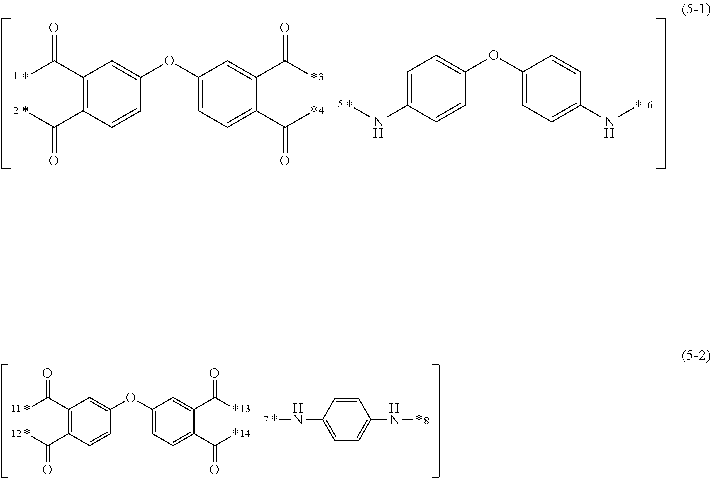

In the formulae, one of *3 and *4 is bonded to *5 to form a main chain of the polyimide precursor, and the other bonded to an OH group to form a carboxyl group; and one of *1 and *2 is bonded to an OH group to form a carboxyl group or bonded to —NH—(CH₂)₂—O—(C═O)—C(CH₃)═CH₂, and the other is bonded to any one of *6 or *8 to form the main chain of the polyimide precursor;

one of *13 and *14 is bonded to *7 to form a main chain of the polyimide precursor, and the other bonded to an OH group to form a carboxyl group; and one of *11 and *12 is bonded to an OH group to form a carboxyl group or bonded to —NH—(CH₂)₂—O—(C═O)—C(CH₃)═CH₂, and the other is bonded to any one of *6 or *8 to form the main chain of the polyimide precursor.

Resin 6: resin having the following structure (polyimide resin, a numerical value added to a constitutional unit is a molar ratio; weight-average molecular weight: 20000)

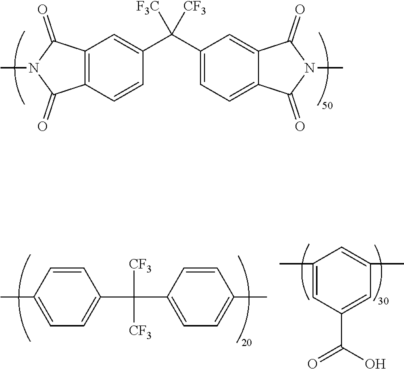

Resin 7: resin having the following structure (polyimide precursor, weight-average molecular weight: 24000)

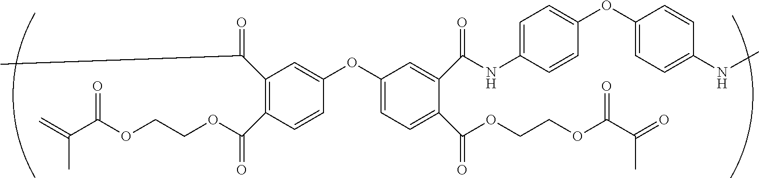

(Polymerizable Monomer)

(M-1): 7:3 mixture of dipentaerythritol hexaacrylate (DPHA) and dipentaerythritol pentaacrylate (manufactured by Nippon Kayaku Co., Ltd., KAYARAD DPHA)

(M-2): trimethylolpropane triacrylate (manufactured by Shin-Nakamura Chemical Co., Ltd., A-TMPT)

(M-3: compound having the following structure (manufactured by Shin-Nakamura Chemical Co., Ltd., A-DPH-12E)

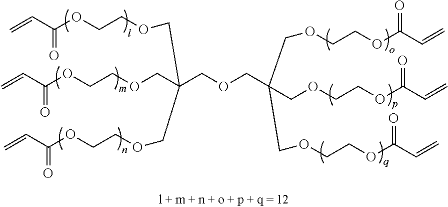

(Photopolymerization Initiator)

(I-1): Irgacure OXE-01 (manufactured by BASF SE)

(I-2): Irgacure OXE-02 (manufactured by BASF SE)

(I-3): compound having the following structure

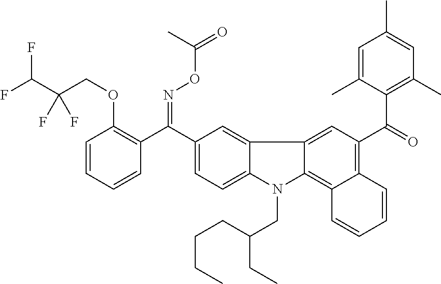 [SMILES: CCCCC(CC)Cn1c2ccc(/C(=N\OC(C)=O)c3ccccc3OCC(F)(F)C(F)F)cc2c2cc(C(=O)c3c(C)cc(C)cc3C)c3ccccc3c21]

(I-4): Omnirad 369 (manufactured by IGM Resins B.V.)

(I-5) to (I-8): compounds having the following structures

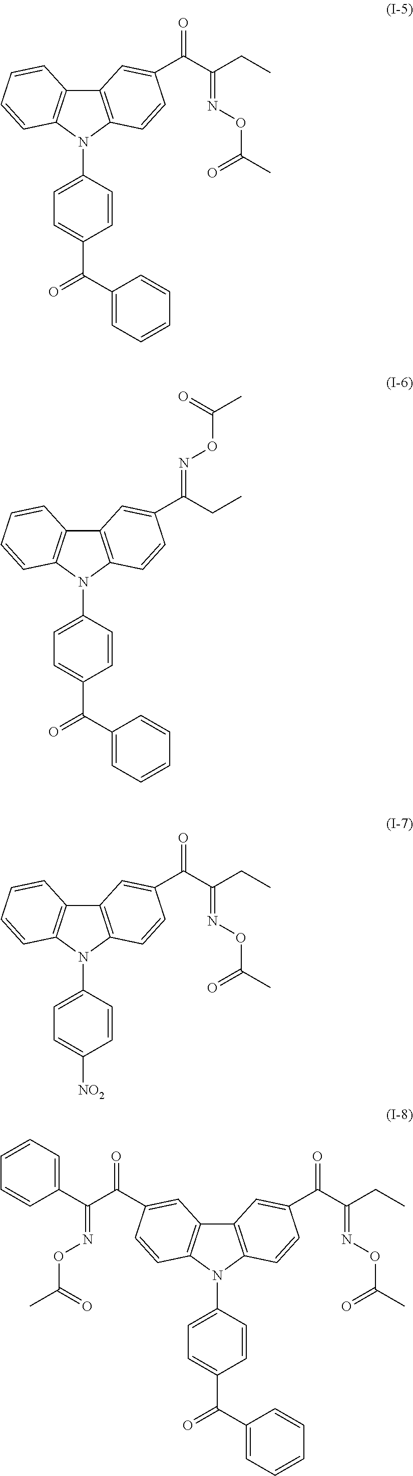 [SMILES: CC/C(=N\OC(C)=O)C(=O)c1ccc2c(c1)c1ccccc1n2-c1ccc(C(=O)c2ccccc2)cc1 ; CC/C(=N\OC(C)=O)c1ccc2c(c1)c1ccccc1n2-c1ccc(C(=O)c2ccccc2)cc1 ; CC/C(=N\OC(C)=O)C(=O)c1ccc2c(c1)c1ccccc1n2-c1ccc([N+](=O)[O-])cc1 ; CC/C(=N\OC(C)=O)C(=O)c1ccc2c(c1)c1cc(C(=O)/C(=N/OC(C)=O)c3ccccc3)ccc1n2-c1ccc(C(=O)c2ccccc2)cc1]

(Ultraviolet Absorber)

(U-1): triazine-based ultraviolet absorber “Tinuvin 477” (manufactured by BASF SE)

(Additive)

(F-1): epoxy compound (manufactured by Daicel Corporation, EHPE 3150)

(Solvent)

PGMEA: propylene glycol monomethyl ether acetate

(Surfactant)

(S-1): 1% by mass of compound having the following structure (Mw=14,000, numerical values of % indicating the ratio of repeating units is mol %) in propylene glycol monomethyl ether acetate solution

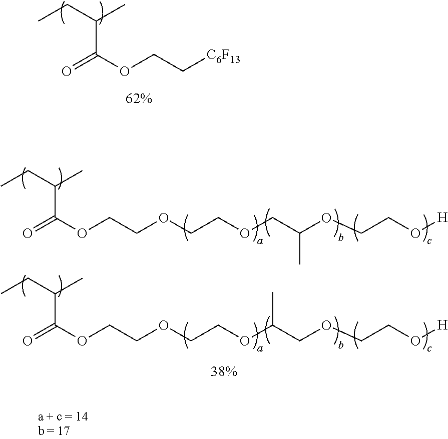

<Evaluation>

[Evaluation of Spectral Change]

In each of Examples and Comparative Examples, on a glass substrate, each coloring composition was applied to a glass substrate by spin coating, and dried (pre-baked) at 100° C. for 120 seconds using a hot plate. Thereafter, the composition was heated (post-baked) at 200° C. for 30 minutes using an oven to produce a film having a thickness of 0.60 μm. Using a spectrophotometer (Cary 5000 UV-Vis-NIR, manufactured by Agilent Technologies, Inc.), a light transmittance Trl of the obtained film at a wavelength of 450 nm was measured. Next, the obtained film was heat-treated at 300° C. for 5 hours in a nitrogen atmosphere. A light transmittance Tr2 of the film after the heating treatment at a wavelength of 450 nm was measured. An absolute value ΔT of the difference between Tr1 and Tr2 was calculated, and the spectral change was evaluated according to the following evaluation standard. It can be said that, as ΔT is smaller, the spectral change is less likely to occur, which is preferable. Both Tr1 and Tr2 were measured in a state in which the temperature and humidity were controlled to 22±5° C. and 60±20% in a laboratory, and the temperature of the substrate was adjusted to 25° C.

—Evaluation Standard—

A: ΔT was 0.1% or less.

B: ΔT was more than 0.1% and 0.5% or less.

C: ΔT was more than 0.5% and 1% or less.

D: ΔT was more than 1% and 5% or less.

E: ΔT was more than 5%.

[Evaluation of Film Shrinkage Ratio]

In each of Examples and Comparative Examples, on a glass substrate, each coloring composition was applied to a glass substrate by spin coating, and dried (pre-baked) at 100° C. for 120 seconds using a hot plate. Thereafter, the composition was heated (post-baked) at 200° C. for 30 minutes using an oven to produce a film having a thickness of 0.60 μm. The film thickness was measured by scraping a part of the film to expose a surface of the glass substrate, and measuring a level difference (film thickness of the film) between the surface of the glass substrate and the film using a stylus profilometer (DektakXT, manufactured by BRUKER). Next, the obtained film was heat-treated at 300° C. for 5 hours in a nitrogen atmosphere. The film thickness of the film after the heating treatment was measured in the same manner as described above, a film shrinkage ratio was calculated from the following expression, and the film shrinkage ratio was evaluated according to the following evaluation standard. Both T0 and T1 below were measured in a state in which the temperature and humidity were controlled to 22±5° C. and 60±20% in a laboratory, and the temperature of the substrate was adjusted to 25° C. It can be said that, as the film shrinkage ratio is smaller, the film shrinkage is more suppressed, which is a preferred result.

Film shrinkage ratio (%)=(1−(T1/T0))×100

T0: thickness of film immediately after production (=0.60 μm)

T1: thickness of film after the heating treatment at 300° C. for 5 hours in a nitrogen atmosphere

—Evaluation Standard—

A: film shrinkage ratio was 1% or less.

B: film shrinkage ratio was more than 1% and 5% or less.

C: film shrinkage ratio was more than 5% and 10% or less.

D: film shrinkage ratio was more than 10% and 30% or less.

E: film shrinkage ratio was more than 30%.

[Evaluation of Cracks]

In each of Examples and Comparative Examples, on a glass substrate, each coloring composition was applied to a glass substrate by spin coating, and dried (pre-baked) at 100° C. for 120 seconds using a hot plate. Thereafter, the composition was heated (post-baked) at 200° C. for 30 minutes using an oven to produce a film having a thickness of 0.60 μm. Next, SiO₂ was laminated at 200 nm on the surface of the obtained film by a sputtering method to form an inorganic film. The obtained film in which the inorganic film was formed on the surface was heat-treated at 300° C. for 5 hours in a nitrogen atmosphere. The surface of the inorganic film after the heating treatment was observed with an optical microscope, the number of cracks per 1 cm² was counted, and the presence or absence of cracks was evaluated according to the following evaluation standard.

—Evaluation Standard—

A: number of cracks per 1 cm² was 0.

B: number of cracks per 1 cm² was 1 to 10.

C: number of cracks per 1 cm² was 11 to 50.

D: number of cracks per 1 cm² was 51 to 100.

E: number of cracks per 1 cm² was 101 or more.

[Evaluation of Surface]

In each of Examples and Comparative Examples, on a glass substrate, each coloring composition was applied to a glass substrate by spin coating, and dried (pre-baked) at 100° C. for 120 seconds using a hot plate. Thereafter, the composition was heated (post-baked) at 200° C. for 30 minutes using an oven to produce a film having a thickness of 0.60 μm. Next, the obtained film was heat-treated at 300° C. for 5 hours in a nitrogen atmosphere. The surface of the film after the heating treatment was observed with an optical microscope, and the presence or absence of precipitation of crystals was evaluated.

—Evaluation Standard—

A: no precipitation of crystals was observed.

B: precipitation of crystals was observed.

The results of each evaluation are shown in the table below. In addition, the column of “Content of colorant” in the following table indicates a value of the content of the colorant in the total solid content of the coloring composition. In addition, the type of the pigment A (pigment A having a structure represented by Formula (X1)) included in the coloring composition is indicated in the column of “Type of pigment A” in the following table. In addition, the presence or absence of the polyimide resin, the polyimide precursor, the polybenzoxazole resin, the polybenzoxazole precursor, and the polysiloxane resin in the coloring composition is indicated in the column of “Presence or absence of specific resin” in the following table.

TABLE 8

| | Coloring composition | | | | | | | |
|---|---|---|---|---|---|---|---|---|
| | | | Content of | Presence or | | Film | | |
| | | Type of | colorant (% | absence of | Spectral | shrinkage | | |
| | Type | pigment A | by mass) | specific resin | change | ratio | Cracks | Surface |
| Example 1 | (RR-1) | Pigment A1 | 46.5 | Presence | B | A | A | A |
| Example 2 | (RR-2) | Pigment A1 | 46.5 | Presence | B | A | A | A |
| Example 3 | (RR-3) | Pigment A1 | 46.5 | Presence | A | A | A | A |
| Example 4 | (RR-3) | Pigment A1 | 46.5 | Presence | A | A | A | A |
| Example 5 | (RR-3) | Pigment A1 | 46.5 | Presence | A | A | A | A |
| Example 6 | (RR-3) | Pigment A1 | 46.5 | Presence | A | A | A | A |
| Example 7 | (RR-3) | Pigment A1 | 46.5 | Presence | A | A | A | A |
| Example 8 | (RR-4) | Pigment A2 | 48.0 | Presence | A | A | A | A |
| Example 9 | (RR-5) | Pigment A3 | 48.0 | Presence | B | B | A | A |
| Example 10 | (RR-6) | Pigment A1 | 41.4 | Presence | B | A | A | A |
| Example 11 | (RR-7) | Pigment A1 | 41.4 | Presence | B | A | A | A |
| Example 12 | (RR-8) | Pigment A1 | 41.4 | Presence | B | B | A | A |
| Example 13 | (RR-9) | Pigment A1 | 48.0 | Presence | B | C | A | A |
| Example 14 | (RR-10) | Pigment A1 | 46.5 | Presence | B | C | A | A |
| Example 15 | (RR-11) | Pigment A1 | 46.5 | Presence | B | A | A | A |
| Example 16 | (RR-12) | Pigment A1 | 46.5 | Presence | A | B | A | A |
| Example 17 | (RR-13) | Pigment A1 | 46.5 | Presence | A | A | A | A |
| Example 18 | (RR-14) | Pigment A1 | 48.0 | Presence | A | A | A | A |
| Example 19 | (RR-15) | Pigment A1 | 48.0 | Presence | A | A | A | A |
| Example 20 | (RR-16) | Pigment A1 | 48.0 | Presence | A | A | A | A |
| Example 21 | (RR-17) | Pigment A1 | 48.0 | Presence | A | A | A | A |
| Example 22 | (KR-1) | Pigment A1 | 35.4 | Presence | B | B | A | A |
| Example 23 | (KR-2) | Pigment A1 | 45.8 | Presence | B | B | A | A |
| Example 24 | (KR-3) | Pigment A1 | 47.8 | Presence | B | B | A | A |
| Example 25 | (KR-4) | Pigment A1 | 35.4 | Presence | B | B | A | A |
| Example 26 | (KR-5) | Pigment A1 | 35.4 | Presence | B | A | A | A |
| Example 27 | (KR-6) | Pigment A1 | 35.4 | Presence | A | A | A | A |
| Example 28 | (KR-7) | Pigment A1 | 35.4 | Presence | A | A | A | A |
| Example 29 | (KR-8) | Pigment A1 | 35.4 | Presence | A | A | A | A |
| Example 30 | (KR-9) | Pigment A1 | 35.4 | Presence | A | A | A | A |
| Example 31 | (KR-10) | Pigment A1 | 35.4 | Presence | A | A | A | A |
| Example 32 | (KR-11) | Pigment A1 | 44.8 | Presence | A | A | A | A |
| Example 33 | (KR-12) | Pigment A1 | 48.9 | Presence | A | A | A | A |
| Example 34 | (KR-13) | Pigment A1 | 35.4 | Presence | A | A | A | A |
| Example 35 | (KR-14) | Pigment A1 | 36.2 | Presence | A | B | A | A |
| Example 36 | (KR-15) | Pigment A1 | 36.2 | Presence | A | B | A | A |
| Example 37 | (KR-16) | Pigment A1 | 36.2 | Presence | A | B | A | A |
| Example 38 | (KR-17) | Pigment A1 | 36.2 | Presence | B | A | A | A |
| Example 39 | (KR-18) | Pigment A1 | 36.2 | Presence | B | A | A | A |
| Example 40 | (KR-19) | Pigment A1 | 36.2 | Presence | B | A | A | A |
| Example 41 | (KR-20) | Pigment A1 | 36.2 | Presence | B | A | A | A |
| Example 42 | (KR-21) | Pigment A1 | 51.4 | Presence | B | B | A | A |
| Example 43 | (KR-22) | Pigment A1 | 51.4 | Presence | B | B | A | A |
| Example 44 | (KR-23) | Pigment A1 | 51.4 | Presence | A | A | A | A |
| Example 45 | (KR-24) | Pigment A1 | 51.4 | Presence | A | A | A | A |
| Example 46 | (KR-25) | Pigment A1 | 51.4 | Presence | A | A | A | A |
| Comparative | (RR-c1) | Pigment A1 | 48.0 | Absence | C | E | D | B |
| Example 1 | | | | | | | | |
| Comparative | (RR-c2) | Pigment A1 | 48.0 | Absence | C | E | D | B |
| Example 2 | | | | | | | | |
| Comparative | (RR-c3) | Pigment A1 | 46.5 | Absence | C | E | D | B |
| Example 3 | | | | | | | | |
| Comparative | (RR-c4) | None | 46.5 | Presence | D | D | C | B |
| Example 4 | | | | | | | | |
| Comparative | (KR-c1) | Pigment A1 | 36.2 | Absence | C | D | D | B |
| Example 5 | | | | | | | | |
| Comparative | (KR-c2) | Pigment A1 | 34.6 | Absence | D | E | E | B |
| Example 6 | | | | | | | | |
| Comparative | (KR-c3) | Pigment A1 | 35.4 | Absence | C | D | D | B |
| Example 7 | | | | | | | | |

In a case where the coloring compositions of Examples were used, compared to a case of using the coloring compositions of Comparative Examples, the film shrinkage ratio after heating treatment was small and a film excellent in heat resistance could be formed. In addition, regarding the evaluations of spectral change, cracks, and surface, these evaluations of Examples were superior to those of Comparative Examples. The same results were obtained even in a case where the surfactant was removed from Example 1. The same results were obtained even in a case where the solvent of Example 1 was replaced with propylene glycol monomethyl ether acetate/propylene glycol monomethyl ether=4/1 (weight ratio).

In addition, the coloring compositions of Examples 1 to 21 could be preferably used as a coloring composition for a color filter. In addition, the coloring compositions of Examples 18 to 40 could be preferably used as a coloring composition for forming a near-infrared transmitting filter.

What is claimed is:

1. A coloring composition comprising:
a colorant; and
a resin,
wherein the colorant includes a pigment A having a structure represented by Formula (X1), and
the resin includes at least one selected from a polyimide resin, a polyimide precursor, a polybenzoxazole resin, a polybenzoxazole precursor, or a polysiloxane resin, 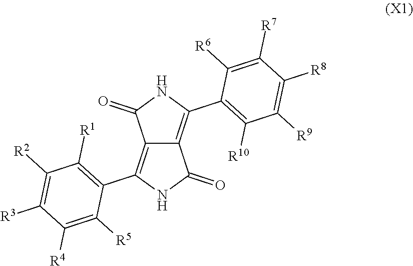
in Formula (X1), R¹ to R¹⁰ each independently represent a hydrogen atom or a group represented by Formula (X2), where at least one of R¹, . . . , or R¹⁰ is the group represented by Formula (X2), 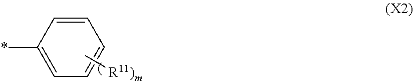
in Formula (X2), R¹¹ represents a substituent, m represents an integer of 0 to 5, and * represents a bonding position in Formula (X1).

2. The coloring composition according to claim 1,
wherein R³ and R⁸ of Formula (X1) are the groups represented by Formula (X2).

3. The coloring composition according to claim 1,
wherein R¹, R², R⁴, R⁵, R⁶, R⁷, R⁹, and R¹⁰ of Formula (X1) are hydrogen atoms.

4. The coloring composition according to claim 1,
wherein the coloring composition includes the pigment A in an amount of 10 to 1500 parts by mass with respect to 100 parts by mass of a total of the polyimide resin, the polyimide precursor, the polybenzoxazole resin, the polybenzoxazole precursor, and the polysiloxane resin.

5. The coloring composition according to claim 1,
wherein the coloring composition includes the polyimide resin, the polyimide precursor, the polybenzoxazole resin, the polybenzoxazole precursor, and the polysiloxane resin in a total amount of 5% to 80% by mass in a total solid content of the coloring composition.

6. The coloring composition according to claim 1,
wherein the colorant includes a colorant other than the pigment A, and
the colorant other than the pigment A is at least one selected from a chromatic colorant or a black colorant.

7. The coloring composition according to claim 6,
wherein the coloring composition includes the colorant other than the pigment A in an amount of 10 to 1000 parts by mass with respect to 100 parts by mass of the pigment A.

8. The coloring composition according to claim 1, further comprising:
an infrared absorber.

9. The coloring composition according to claim 1,
wherein the resin includes at least one selected from a polyimide resin or a polyimide precursor.

10. The coloring composition according to claim 1, further comprising:
a polymerizable monomer; and
a polymerization initiator.

11. The coloring composition according to claim 10,
wherein the polymerization initiator is a photopolymerization initiator.

12. The coloring composition according to claim 1,
wherein the coloring composition is used for a red color filter.

13. The coloring composition according to claim 1,
wherein the coloring composition is used for an infrared transmitting filter.

14. A film obtained from the coloring composition according to claim 1.

15. An optical filter comprising:
the film according to claim 14.

16. A solid-state imaging element comprising:
the film according to claim 14.

17. An image display device comprising:
the film according to claim 14.
